(19) United States
(12) Patent Application Publication
(10) Pub. No.: US 2019/0302617 A1
(43) Pub. Date: Oct. 3, 2019

(54) NEGATIVE PHOTOSENSITIVE RESIN COMPOSITION, CURED FILM, ELEMENT PROVIDED WITH CURED FILM, DISPLAY DEVICE PROVIDED WITH ELEMENT, AND ORGANIC EL DISPLAY

(71) Applicant: TORAY INDUSTRIES, INC., Tokyo (JP)

(72) Inventors: Shinichi MATSUKI, Otsu-shi (JP); Yugo TANIGAKI, Otsu-shi (JP); Kazuto MIYOSHI, Otsu-shi (JP)

(73) Assignee: TORAY INDUSTRIES, INC., Tokyo (JP)

(21) Appl. No.: 16/302,886

(22) PCT Filed: Jun. 27, 2017
(86) PCT No.: PCT/JP2017/023602

§ 371 Date: Nov. 19, 2018

(30) Foreign Application Priority Data
Jun. 30, 2016 (JP) 2016-129737

(51) Int. Cl. G03F 7/038; C09B 7/08

(52) U.S. Cl. CPC G03F 7/0387; H05B 33/145; C09B 7/08; G03F 7/0382

(57) ABSTRACT

The present invention provides a negative photosensitive resin composition that has high pigment dispersibility and stability and can reduce residues of unexposed portions during development. The present invention provides
a negative photosensitive resin composition containing an (A) alkali-soluble resin, a (B) dispersant having an amine value exceeding 0, a (C) benzofuranone based organic pigment having an amide structure, a (D) radical polymerizable compound, and a (E) photoinitiator. In this negative photosensitive resin composition, the (A) alkali-soluble resin contains
one or more selected from the group consisting of a (A1) polyimide, a (A2) polyimide precursor, a (A3) polybenzoxazole, and a (A4) polybenzoxazole precursor, and the (B) dispersant having an amine value exceeding 0 contains a (B1) dispersant including a repeating unit represented by general formula (2) and a repeating unit represented by general formula (3) and a (B2) dispersant that is an acrylic block copolymer having an amine value of 15 to 60 mgKOH/g and/or a (B3) dispersant having a urethane bond.

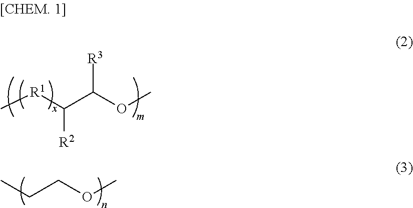

(In general formula (2), R¹ represents an alkylene group. R² and R³, which may be the same or different, each represents hydrogen, an alkyl group or a hydroxyl group. x represents an integer of 0 to 20. However, when x is 0, at least one of R² and R³ is an alkyl group. m represents an integer of 1 to 100. In general formula (3), n represents an integer of 1 to 100.)

### TECHNICAL FIELD

The present invention relates to a negative photosensitive resin composition, a cured film, an element, a display device, and an organic EL display.

### BACKGROUND ART

Recent years have seen, in display devices, such as smartphones, tablet PCs, and televisions, which include thin-type displays, development of many products that employ organic electroluminescence (hereinafter, “EL”) displays.

The organic EL display is a self-luminous element, so that incidence of external light, such as sun light outdoors, reduces visibility and contrast due to reflection of the external light. Therefore, a technology that reduces external light reflection is required. A method in which a polarizing plate, a quarter wavelength plate, reflection preventing layer, or the like is formed on the light extraction side of the light-emitting elements in order to reduce such external light reflection is known. However, in the case where a polarizing plate is formed, the polarizing plate can reduce the external light reflection but the polarizing plate will also block part of light output from the light-emitting elements, decreasing the luminance of the organic EL display. Therefore, a technology that reduces the external light reflection without using a polarizing plate or the like is required.

As a technology that shields external light, a black matrix used for a color filter of a liquid crystal display can be cited.

In general, in the organic EL display, in order to separate pixels of the light-emitting elements from each other, an insulation film called pixel-separating layer is formed between layers of transparent electrodes and metal electrodes. There is a technique that colors the pixel-separating layer and imparts light blocking property to absorb incident external light, and thus to reduce external light reflection.

Although black pigments and dyes are used to impart the light blocking property, pigments excellent in light blocking property are particularly preferably used. Further, in the organic EL display, although a TFT is formed on a substrate, in order to position a mask on the TFT, an organic pigment that allows light transmission in a near infrared or infrared region is preferably used. In this case, when the light blocking property due to the pigment becomes too high, ultraviolet rays and the like at the time of pattern exposure are also blocked. Thus, a negative photosensitive resin composition that can form a film due to efficient curing by radical polymerization is generally used.

When a pigment is used, it is necessary to make the pigment uniform during film formation by refining the pigment by various refining processing methods. However, even if the pigment is refined, the pigment in which the refining of primary particles or secondary particles has progressed generally tends to aggregate. Thus, if the refining progresses too much, a huge aggregated pigment solid matter is formed.

In addition, in the formation of the negative photosensitive resin composition, an alkaline developer is usually used; however, this is liable to lead to residues (developability) of unexposed portions, and it is difficult to achieve a negative photosensitive resin composition that can simultaneously achieve both dispersion stability and developability.

Thus, in general, a dispersant is used to keep a dispersion state good. The dispersant has a structure of a portion adsorbed to a colorant and a portion having a high affinity for a solvent as a dispersion medium, and the performance is determined by balance between the portions having the two functions. Various dispersants are used in accordance with a surface state of a pigment which is a dispersed material.

Examples of pigment dispersants suitable for a quinophthalone pigment include a dispersant having at least one of an ethylene oxide chain and a propylene oxide chain (Patent Document 1), a bisbenzofuranone-based pigment, a perylene-based pigment, and a polymer dispersant (Patent Document 2), an amine-based dispersant having a specific repeating unit (Patent Document 3), a dispersant having an ethylene oxide unit (Patent Document 4), a copolymer composed of a block having an amino group at the side chain and a block not having the amino group (Patent Document 5), a dispersant having a urethane bond in a radiation-sensitive composition for black resist (Patent Document 6), and a block copolymer having a repeating unit originating from an ethylenically unsaturated monomer having an alkylene glycol chain (Patent Document 7).

### PRIOR ART DOCUMENTS

### Patent Documents

Patent Document 1: Japanese Patent Laid-open Publication No. 2013-24934

Patent Document 2: Japanese Patent Laid-open Publication No. 2014-130173

Patent Document 3: Japanese Patent Laid-open Publication (Translation of PCT Application) No. 2013-529228

Patent Document 4: Japanese Patent No. 5079583

Patent Document 5: Japanese Patent Laid-open Publication No. 2009-25813

Patent Document 6: Japanese Patent Laid-open Publication No. 2000-227654

Patent Document 7: Japanese Patent Laid-open Publication No. 2011-232735

### SUMMARY OF THE INVENTION

### Problems to be Solved by the Invention

However, although these dispersants have some degree of pigment dispersing ability, the dispersants cannot reduce residues of unexposed portions during development.

It is an object of the present invention to provide a negative photosensitive resin composition that has high pigment dispersibility and stability and can reduce residues of unexposed portions during development.

### Solutions to the Problems

A negative photosensitive resin composition containing

an (A) alkali-soluble resin,

a (B) dispersant having an amine value exceeding 0,

a (C) benzofuranone based organic pigment having an amide structure,

a (D) radical polymerizable compound, and

a (E) photoinitiator. In this negative photosensitive resin composition, the (A) alkali-soluble resin contains one or more selected from the group consisting of a (A1) polyimide, a (A2) polyimide precursor, a (A3) polybenzoxazole, and a (A4) polybenzoxazole precursor, and the (B) dispersant having an amine value exceeding 0 includes a (B1) dispersant including a repeating unit represented by general formula (2) and a repeating unit represented by general formula (3) and a (B2) dispersant that is an acrylic block copolymer having an amine value of 15 to 60 mgKOH/g and/or a (B3) dispersant having a urethane bond.

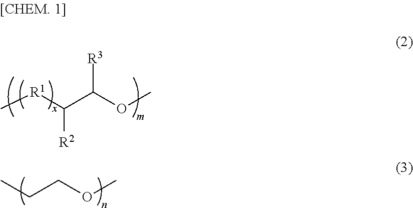

(In general formula (2), R¹ represents an alkylene group. R² and R³, which may be the same or different, each represents hydrogen, an alkyl group or a hydroxyl group. x represents an integer of 0 to 20. However, when x is 0, at least one of R² and R³ is an alkyl group. m represents an integer of 1 to 100. In general formula (3), n represents an integer of 1 to 100.)

### Effects of the Invention

The present invention can provide a negative photosensitive resin composition that has high pigment dispersion stability and can reduce residues of unexposed portions during development.

### BRIEF DESCRIPTION OF THE DRAWINGS

FIG. 1 is a process diagram illustrating a production process for an organic EL display that uses a cured film of a negative photosensitive resin composition of the present invention.

FIG. 2 is a process diagram illustrating a production process for a flexible organic EL display that uses a cured film of a negative photosensitive resin composition of the present invention.

FIG. 3 is a schematic diagram of an organic EL display device used for light emission characteristic evaluation.

FIG. 4 is a schematic diagram of an organic EL display having no polarizing layer.

### EMBODIMENTS OF THE INVENTION

The present invention provides a negative photosensitive resin composition containing

an (A) alkali-soluble resin,

a (B) dispersant having an amine value exceeding 0,

a (C) benzofuranone based organic pigment having an amide structure,

a (D) radical polymerizable compound, and

a (E) photoinitiator. In this negative photosensitive resin composition, the (A) alkali-soluble resin contains one or more selected from the group consisting of a (A1) polyimide, a (A2) polyimide precursor, a (A3) polybenzoxazole, and a (A4) polybenzoxazole precursor, and the (B) dispersant having an amine value exceeding 0 includes a (B1) dispersant including a repeating unit represented by general formula (2) and a repeating unit represented by general formula (3) and a (B2) dispersant that is an acrylic block copolymer having an amine value of 15 to 60 mgKOH/g and/or a (B3) dispersant having a urethane bond.

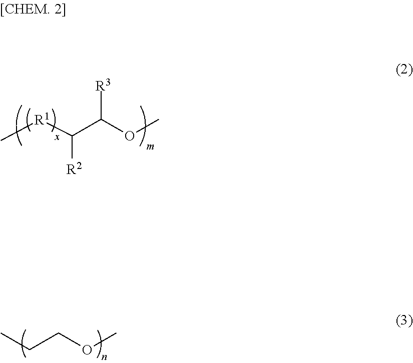

(In general formula (2), R¹ represents an alkylene group. R² and R³, which may be the same or different, each represents hydrogen, an alkyl group or a hydroxyl group. x represents an integer of 0 to 20. However, when x is 0, at least one of R² and R³ is an alkyl group. m represents an integer of 1 to 100. In general formula (3), n represents an integer of 1 to 100.)

<Alkali-Soluble Resin>

The negative photosensitive resin composition of the present invention contains an (A) alkali-soluble resin. The (A) alkali-soluble resin is generally used for a negative resist and has solubility in an alkaline aqueous solution. From the viewpoint of heat resistance, the (A) alkali-soluble resin includes one or more selected from a (A1) polyimide, a (A2) polyimide precursor, a (A3) polybenzoxazole, and a (A4) polybenzoxazole precursor.

<(A1) Polyimide and (A2) Polyimide Precursor>

As the (A1) polyimide, for example, those obtained by dehydrating cyclization of polyamic acid, polyamic acid ester, polyamic acid amide, or polyisoimide due to heating or reaction using an acid or a base can be cited. The (A1) polyimide has a tetracarboxylic acid and/or its derivative residue and has a diamine and/or its derivative residue.

As the (A2) polyimide precursor, for example, those obtained by reacting tetracarboxylic acid, corresponding tetracarboxylic dianhydride, corresponding tetracarboxylic acid diester dichloride, or the like with diamine, a corresponding diisocyanate compound, corresponding trimethylsilylated diamine, or the like can be cited. The (A2) polyimide precursor has a tetracarboxylic acid and/or its derivative residue and also has a diamine and/or its derivative residue. As the (A2) polyimide precursor, for example, polyamic acid, polyamic acid ester, polyamic acid amide, or polyisoimide can be cited.

The (A2) polyimide precursor is a thermosetting resin and, when subjected to high-temperature thermosetting and therefore dehydrating cyclization, forms high heat-resistant imide bonds, thus providing a (A1) polyimide. Therefore, containing in the resin composition the (A1) polyimide having high heat-resistant imide bonds can conspicuously improve the heat resistance of the cured film obtained. Therefore, the resin composition is suitable in the case where the cured film is used for uses that require high heat resistance of the film, and the like cases. Furthermore, since the (A2) polyimide precursor is a resin that improves in heat resistance after dehydrating cyclization, the resin composition is suitable in the case where the resin composition is used for uses in which it is desired to achieve both favorable characteristics of the precursor structure prior to the dehydrating cyclization and favorable heat resistance of the cured film, and the like cases.

The (A1) polyimide and the (A2) polyimide precursor have imide bonds and/or amide bonds as polar bonds. Thus, when an aftermentioned (C) benzofuranone based organic pigment having an amide structure is contained, these polar bonds strongly interact with the (C) benzofuranone based organic pigment having an amide structure, so that it is possible to improve the dispersion stability of the (C) benzofuranone based organic pigment having an amide structure.

As the (A1) polyimide used in the present invention, it is preferable to contain a structural unit represented by general formula (3a) from the viewpoint of improving the heat resistance of the cured film.

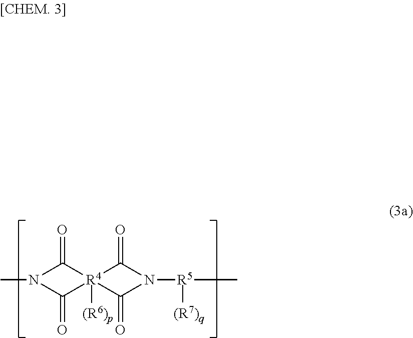

(In general formula (3a), R⁴ represents an organic group having a valence of 4 to 10, and R⁵ represents an organic group having a valence of 2 to 10. R⁶ and R⁷ each independently represent a phenolic hydroxyl group, a sulfonic acid group, a mercapto group, or a substituent represented by the following general formula (4) or the following general formula (5). p represents an integer of 0 to 6, and q represents an integer of 0 to 8.)

R⁴ in general formula (3a) represents tetracarboxylic acid and/or its derivative residue, and R⁵ represents diamine and/or its derivative residue. As a tetracarboxylic acid derivative, for example, tetracarboxylic dianhydride, tetracarboxylic acid dichloride or tetracarboxylic acid active diester can be cited. As a diamine derivative, diisocyanate compounds or trimethylsilylated diamine can be cited.

In general formula (3a), it is preferable that R⁴ be an organic group having a valence of 4 to 10 that has one or more species selected from an aliphatic structure having a carbon number of 2 to 20, an alicyclic structure having a carbon number of 4 to 20, and an aromatic structure having a carbon number of 6 to 30, and it is more preferable that R⁴ be an organic group having a valence of 4 to 10 that has one or more species selected from an aliphatic structure having a carbon number of 4 to 15, an alicyclic structure having a carbon number of 4 to 15, and an aromatic structure having a carbon number of 6 to 25. Furthermore, it is preferable that R⁵ be an organic group having a valence of 2 to 10 that has one or more species selected from an aliphatic structure having a carbon number of 2 to 20, an alicyclic structure having a carbon number of 4 to 20, and an aromatic structure having a carbon number of 6 to 30, and it is more preferable that R⁵ be an organic group having a valence of 2 to 10 that has one or more species selected from an aliphatic structure having a carbon number of 4 to 15, an alicyclic structure having a carbon number of 4 to 15, and an aromatic structure having a carbon number of 6 to 25. q is preferably 1 to 8. The aliphatic structure, alicyclic structure and aromatic structure mentioned above may be either an unsubstituted product or a substitution product.

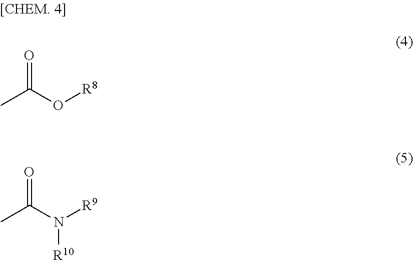

(In general formulas (4) and (5), R⁸ to R¹⁰ represent hydrogen, an alkyl group having a carbon number of 1 to 10, an acyl group having a carbon number of 2 to 6, or an aryl group having a carbon number of 6 to 15.

In general formulas (4) and (5), from the viewpoint of heat resistance, it is preferable that R⁸ to R¹⁰ be hydrogen, an alkyl group having a carbon number of 1 to 6, an acyl group having a carbon number of 2 to 4, or an aryl group having a carbon number of 6 to 10. The alkyl group, the acyl group, and the aryl group mentioned above may be either an unsubstituted product or a substitution product.

As the aliphatic structure of R⁴ and R⁵ in general formula (3a), for example, an ethane structure, an n-butane structure, an n-pentane structure, an n-hexane structure, an n-decane structure, a 3,3-dimethylpentane structure, a di-n-butyl ether structure, a di-n-butyl ketone structure or a di-n-butyl sulfone structure can be cited. As a substituent thereof, for example, a halogen atom or an alkoxy group can be cited. When the aliphatic structure is a substitution product, as R⁴ and R⁵, for example, a 3,3-bis(trifluoromethyl)pentane structure or a 3-methoxypentane structure can be cited.

As the alicyclic structure of R⁴ and R⁵ in general formula (3a), for example, a cyclobutane structure, cyclopentane, a cyclohexane structure, an ethylcyclohexane structure, a tetrahydrofuran structure, a bicyclohexyl structure, a 2,2-dicyclohexylpropane structure, a dicyclohexyl ether structure, a dicyclohexyl ketone structure, or a dicyclohexyl sulfone structure can be cited. As a substituent thereof, for example, a halogen atom or an alkoxy group can be cited. When the alicyclic structure is a substitution product, as R⁴ and R⁵, for example, a 1,1-dicyclohexyl-1,1-bis(trifluoromethyl)methane structure or a 1,1-dicyclohexyl-1-methoxymethane structure can be cited.

As the aromatic structure of R⁴ and R⁵ in general formula (3a), for example, a benzene structure, an ethylbenzene structure, a naphthalene structure, a 1,2,3,4-tetrahydronaphthalene structure, a fluorene structure, a biphenyl structure, a terphenyl structure, a 2,2-diphenylpropane structure, a diphenyl ether structure, a diphenyl ketone structure, a diphenyl sulfone structure, or a 9,9-diphenyl fluorene structure can be cited. As a substituent thereof, for example, a halogen atom or an alkoxy group can be cited. When the aromatic structure is a substitution product, as R⁴ and R⁵, for example, a 1,1-diphenyl-1,1-bis(trifluoromethyl)methane structure or a 1,1-diphenyl-1-methoxymethane structure can be cited.

As the (A1) polyimide, it is preferable to contain a structural unit, represented by general formula (3a), as a main component, and the content ratio of the structural unit represented by general formula (3a) in a structural unit originating from the entire carboxylic acids and its derivative in the (A1) polyimide is preferably within the range of 50 to 100 mol %, more preferably within the range of 60 to 100 mol %, and further preferably within the range of 70 to 100 mol %. When the content ratio thereof is within the range mentioned above, the heat resistance of the cured film can be improved.

As the (A2) polyimide precursor used in the present invention, it is preferable to contain a structural unit represented by general formula (6) from the viewpoint of improving the heat resistance of the cured film and improving the resolution after development.

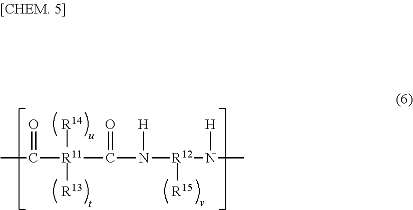

(In general formula (6), R¹¹ represents an organic group having a valence of 4 to 10, and R¹² represents an organic group having a valence of 2 to 10. R¹³ represents a substituent represented by general formula (4) or general formula (5), R¹⁴ represents a phenolic hydroxyl group, a sulfonic acid group or a mercapto group, and R¹⁵ represents a phenolic hydroxyl group, a sulfonic acid group, a mercapto group or a substituent represented by general formula (4) or general formula (5) mentioned above. t represents an integer of 2 to 8, u represents an integer of 0 to 6, v represents an integer of 0 to 8, and 2≤t+u≤8.)

R¹¹ in general formula (6) represents tetracarboxylic acid and/or its derivative residue, and R¹² represents diamine and/or its derivative residue. As a tetracarboxylic acid derivative, for example, tetracarboxylic dianhydride, tetracarboxylic acid dichloride or tetracarboxylic acid active diester can be cited. As a diamine derivative, diisocyanate compounds or trimethylsilylated diamine can be cited.

In general formula (6), it is preferable that R¹¹ be an organic group having a valence of 4 to 10 that has one or more species selected from an aliphatic structure having a carbon number of 2 to 20, an alicyclic structure having a carbon number of 4 to 20, and an aromatic structure having a carbon number of 6 to 30, and it is more preferable that R¹¹ be an organic group having a valence of 4 to 10 that has one or more species selected from an aliphatic structure having a carbon number of 4 to 15, an alicyclic structure having a carbon number of 4 to 15, and an aromatic structure having a carbon number of 6 to 25. Furthermore, it is preferable that R¹² be an organic group having a valence of 2 to 10 that has one or more species selected from an aliphatic structure having a carbon number of 2 to 20, an alicyclic structure having a carbon number of 4 to 20, and an aromatic structure having a carbon number of 6 to 30, and it is more preferable that R¹² be an organic group having a valence of 2 to 10 that has one or more species selected from an aliphatic structure having a carbon number of 4 to 15, an alicyclic structure having a carbon number of 4 to 15, and an aromatic structure having a carbon number of 6 to 25. v is preferably 1 to 8. The aliphatic structure, alicyclic structure and aromatic structure mentioned above may be either an unsubstituted product or a substitution product.

As the aliphatic structure of R¹¹ and R¹² in general formula (6), for example, an ethane structure, an n-butane structure, an n-pentane structure, an n-hexane structure, an n-decane structure, a 3,3-dimethylpentane structure, a di-n-butyl ether structure, a di-n-butyl ketone structure or a di-n-butyl sulfone structure can be cited. As a substituent thereof, for example, a halogen atom or an alkoxy group can be cited. When the aliphatic structure is a substitution product, as R¹¹ and R¹², for example, a 3,3-bis(trifluoromethyl)pentane structure or a 3-methoxypentane structure can be cited.

As the alicyclic structure of R¹¹ and R¹² in general formula (6), for example, a cyclobutane structure, cyclopentane, a cyclohexane structure, an ethylcyclohexane structure, a tetrahydrofuran structure, a bicyclohexyl structure, a 2,2-dicyclohexylpropane structure, a dicyclohexyl ether structure, a dicyclohexyl ketone structure, or a dicyclohexyl sulfone structure can be cited. As a substituent thereof, for example, a halogen atom or an alkoxy group can be cited. When the alicyclic structure is a substitution product, as R¹¹ and R¹², for example, a 1,1-dicyclohexyl-1,1-bis(trifluoromethyl) methane structure or a 1,1-dicyclohexyl-1-methoxymethane structure can be cited.

As the aromatic structure of R¹¹ and R¹² in general formula (6), for example, a benzene structure, an ethylbenzene structure, a naphthalene structure, a 1,2,3,4-tetrahydronaphthalene structure, a fluorene structure, a biphenyl structure, a terphenyl structure, a 2,2-diphenylpropane structure, a diphenyl ether structure, a diphenyl ketone structure, a diphenyl sulfone structure, or a 9,9-diphenyl fluorene structure can be cited. As a substituent thereof, for example, a halogen atom or an alkoxy group can be cited. When the aromatic structure is a substitution product, as R¹¹ and R¹², for example, a 1,1-diphenyl-1,1-bis(trifluoromethyl)methane structure or a 1,1-diphenyl-1-methoxymethane structure can be cited.

As the (A2) polyimide precursor, it is preferable to contain a structural unit, represented by general formula (6), as a main component, and the content ratio of the structural unit represented by general formula (6) in a structural unit originating from the entire carboxylic acids and its derivative in the (A2) polyimide precursor is preferably within the range of 50 to 100 mol %, more preferably within the range of 60 to 100 mol %, and further preferably within the range of 70 to 100 mol %. When the content ratio thereof is within the range mentioned above, the resolution can be improved.

<(A3) Polybenzoxazole and (A4) Polybenzoxazole Precursor>

As the (A3) polybenzoxazole, for example, those obtained by dehydrating cyclization of a dicarboxylic acid and, as a diamine, a bisaminophenol compound due to reaction using a polyphosphoric acid and those obtained by dehydrating cyclization of the aforementioned polyhydroxy amide due to heat or reaction using a phosphoric anhydride, a base, a carbodiimide compound, or the like can be cited. The (A3) polybenzoxazole has a dicarboxylic acid and/or its derivative residue and has a bisaminophenol compound and/or its derivative residue.

As the (A4) polybenzoxazole precursor, for example, those obtained by reacting a dicarboxylic acid, a corresponding dicarboxylic acid dichloride, a dicarboxylic acid active diester, or the like with a bisaminophenol compound as a diamine can be cited. The (A4) polybenzoxazole precursor has a dicarboxylic acid and/or its derivative residue and has a bisaminophenol compound and/or its derivative residue.

The (A4) polybenzoxazole precursor is a thermosetting resin and, when subjected to high-temperature thermosetting and therefore dehydrating cyclization, forms a high heat resistant and rigid benzoxazole ring, thus providing a (A3) polybenzoxazole. Therefore, containing in the resin composition the (A3) polybenzoxazole having a high heat resistant and rigid benzoxazole ring can conspicuously improve the heat resistance of the cured film obtained. Therefore, the resin composition is suitable in the case where the cured film is used for uses that require high heat resistance of the film, and the like cases. Furthermore, since the (A4) polybenzoxazole precursor is a resin that improves in heat resistance after dehydrating cyclization, the resin composition is suitable in the case where the resin composition is used for uses in which it is desired to achieve both favorable characteristics of the precursor structure prior to the dehydrating cyclization and favorable heat resistance of the cured film, or the like cases.

The (A3) polybenzoxazole and the (A4) polybenzoxazole precursor have oxazole bonds and/or amide bonds as polar bonds. Thus, when the aftermentioned (C) benzofuranone based organic pigment having an amide structure is contained, these polar bonds strongly interact with the (C) benzofuranone based organic pigment having an amide structure, so that it is possible to improve the dispersion stability of the (C) benzofuranone based organic pigment having an amide structure.

As the (A3) polybenzoxazole used in the present invention, it is preferable to contain a structural unit represented by general formula (7) from the viewpoint of improving the heat resistance of the cured film.

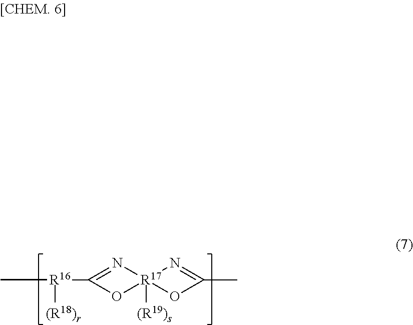

(In general formula (7), R¹⁷ represents an organic group having a valence of 2 to 10, and R¹⁶ represents an organic group having a valence of 4 to 10 that has an aromatic structure. R¹⁸ and R¹⁹ each independently represent a phenolic hydroxyl group, a sulfonic acid group, a mercapto group, or a substituent represented by general formula (4) or general formula (5) mentioned above. r represents an integer of 0 to 8, and s represents an integer of 0 to 6.)

R¹⁷ in general formula (7) represents dicarboxylic acid and/or its derivative residue, and R¹⁶ represents a bisaminophenol compound and/or its derivative residue. As the dicarboxylic acid derivative, dicarboxylic acid anhydride, dicarboxylic acid chloride, dicarboxylic acid active ester, tricarboxylic acid anhydride, tricarboxylic acid chloride, tricarboxylic acid active ester, and diformyl compound can be cited.

In general formula (7), it is preferable that R¹⁶ be an organic group having a valence of 2 to 10 that has one or more species selected from an aliphatic structure having a carbon number of 2 to 20, an alicyclic structure having a carbon number of 4 to 20, and an aromatic structure having a carbon number of 6 to 30, and it is more preferable that R¹⁶ be an organic group having a valence of 2 to 10 that has one or more species selected from an aliphatic structure having a carbon number of 4 to 15, an alicyclic structure having a carbon number of 4 to 15, and an aromatic structure having a carbon number of 6 to 25. R¹⁷ is preferably an organic group having a valence of 4 to 10 that has an aromatic structure having a carbon number of 6 to 30, and more preferably an organic group having a valence of 4 to 10 that has an aromatic structure having a carbon number of 6 to 25. s is preferably 1 to 8. The aliphatic structure, alicyclic structure and aromatic structure mentioned above may be either an unsubstituted product or a substitution product.

As the aliphatic structure of R¹⁶ in general formula (7), for example, an ethane structure, an n-butane structure, an n-pentane structure, an n-hexane structure, an n-decane structure, a 3,3-dimethylpentane structure, a di-n-butyl ether structure, a di-n-butyl ketone structure or a di-n-butyl sulfone structure can be cited. As a substituent thereof, for example, a halogen atom or an alkoxy group can be cited. When the aliphatic structure is a substitution product, as R¹⁶, for example, a 3,3-bis(trifluoromethyl)pentane structure or a 3-methoxypentane structure can be cited.

As the alicyclic structure of R¹⁶ in general formula (7), for example, a cyclobutane structure, cyclopentane, a cyclohexane structure, an ethylcyclohexane structure, a tetrahydrofuran structure, a bicyclohexyl structure, a 2,2-dicyclohexylpropane structure, a dicyclohexyl ether structure, a dicyclohexyl ketone structure, or a dicyclohexyl sulfone structure can be cited. As a substituent thereof, for example, a halogen atom or an alkoxy group can be cited. When the alicyclic structure is a substitution product, as R¹⁶, for example, a 1,1-dicyclohexyl-1,1-bis(trifluoromethyl)methane structure or a 1,1-dicyclohexyl-1-methoxymethane structure can be cited.

As the aromatic structure of R¹⁶ and R¹⁷ in general formula (7), for example, a benzene structure, an ethylbenzene structure, a naphthalene structure, a 1,2,3,4-tetrahydronaphthalene structure, a fluorene structure, a biphenyl structure, a terphenyl structure, a 2,2-diphenylpropane structure, a diphenyl ether structure, a diphenyl ketone structure, a diphenyl sulfone structure, or a 9,9-diphenyl fluorene structure can be cited. As a substituent thereof, for example, a halogen atom or an alkoxy group can be cited. When the aromatic structure is a substitution product, as R¹⁶ and R¹⁷, for example, a 1,1-diphenyl-1,1-bis(trifluoromethyl)methane structure or a 1,1-diphenyl-1-methoxymethane structure can be cited.

As the (A3) polybenzoxazole, it is preferable to contain a structural unit, represented by general formula (7), as a main component, and the content ratio of the structural unit represented by general formula (7) in a structural unit originating from the entire amines and its derivative in the (A3) polybenzoxazole is preferably within the range of 50 to 100 mol %, more preferably within the range of 60 to 100 mol %, and further preferably within the range of 70 to 100 mol %. When the content ratio thereof is within the range mentioned above, the heat resistance of the cured film can be improved.

As the (A3) polybenzoxazole precursor used in the present invention, it is preferable to contain a structural unit represented by general formula (8) from the viewpoint of improving the heat resistance of the cured film and improving the resolution after development.

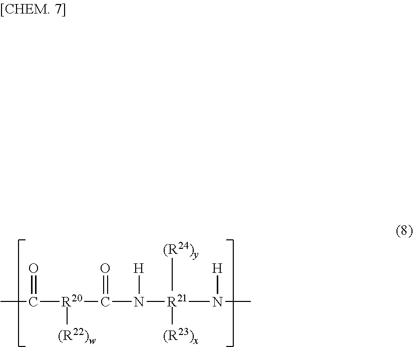

(In general formula (8), R²⁰ represents an organic group having a valence of 2 to 10, and R²¹ represents an organic group having a valence of 4 to 10 that has an aromatic structure. R²² represents a phenolic hydroxyl group, a sulfonic acid group, a mercapto group, or a substituent represented by general formula (4) or general formula (5), R²³ represents a phenolic hydroxyl group, and R²⁴ represents a sulfonic acid group, a mercapto group, or a substituent represented by general formula (4) or general formula (5) mentioned above. w represents an integer of 0 to 8, x represents an integer of 2 to 8, y represents an integer of 0 to 6, and 2≤x+y≤8.)

R²⁰ in general formula (8) represents dicarboxylic acid and/or its derivative residue, and R²¹ represents a bisaminophenol compound and/or its derivative residue. As the dicarboxylic acid derivative, dicarboxylic acid anhydride, dicarboxylic acid chloride, dicarboxylic acid active ester, tricarboxylic acid anhydride, tricarboxylic acid chloride, tricarboxylic acid active ester, and diformyl compound can be cited.

In general formula (8), it is preferable that R²⁰ be an organic group having a valence of 2 to 10 that has one or more species selected from an aliphatic structure having a carbon number of 2 to 20, an alicyclic structure having a carbon number of 4 to 20, and an aromatic structure having a carbon number of 6 to 30, and it is more preferable that R²⁰ be an organic group having a valence of 2 to 10 that has one or more species selected from an aliphatic structure having a carbon number of 4 to 15, an alicyclic structure having a carbon number of 4 to 15, and an aromatic structure having a carbon number of 6 to 25. R²¹ is preferably an organic group having a valence of 4 to 10 that has an aromatic structure having a carbon number of 6 to 30, and more preferably an organic group having a valence of 4 to 10 that has an aromatic structure having a carbon number of 6 to 25. The aliphatic structure, alicyclic structure and aromatic structure mentioned above may be either an unsubstituted product or a substitution product.

As the aliphatic structure of R²⁰ in general formula (8), for example, an ethane structure, an n-butane structure, an n-pentane structure, an n-hexane structure, an n-decane structure, a 3,3-dimethylpentane structure, a di-n-butyl ether structure, a di-n-butyl ketone structure or a di-n-butyl sulfone structure can be cited. As a substituent thereof, for example, a halogen atom or an alkoxy group can be cited. When the aliphatic structure is a substitution product, as R²⁰, for example, a 3,3-bis(trifluoromethyl)pentane structure or a 3-methoxypentane structure can be cited.

As the alicyclic structure of R²⁰ in general formula (8), for example, a cyclobutane structure, cyclopentane, a cyclohexane structure, an ethylcyclohexane structure, a tetrahydrofuran structure, a bicyclohexyl structure, a 2,2-dicyclohexylpropane structure, a dicyclohexyl ether structure, a dicyclohexyl ketone structure, or a dicyclohexyl sulfone structure can be cited. As a substituent thereof, for example, a halogen atom or an alkoxy group can be cited. When the alicyclic structure is a substitution product, as R²⁰, for example, a 1,1-dicyclohexyl-1,1-bis(trifluoromethyl)methane structure or a 1,1-dicyclohexyl-1-methoxymethane structure can be cited.

As the aromatic structure of R²⁰ and R²¹ in general formula (8), for example, a benzene structure, an ethylbenzene structure, a naphthalene structure, a 1,2,3,4-tetrahydronaphthalene structure, a fluorene structure, a biphenyl structure, a terphenyl structure, a 2,2-diphenylpropane structure, a diphenyl ether structure, a diphenyl ketone structure, a diphenyl sulfone structure, or a 9,9-diphenyl fluorene structure can be cited. As a substituent thereof, for example, a halogen atom or an alkoxy group can be cited. When the aromatic structure is a substitution product, as R²⁰ and R²¹, for example, a 1,1-diphenyl-1,1-bis(trifluoromethyl)methane structure or a 1,1-diphenyl-1-methoxymethane structure can be cited.

As the (A4) polybenzoxazole precursor, it is preferable to contain a structural unit, represented by general formula (8), as a main component, and the content ratio of the structural unit represented by general formula (8) in a structural unit originating from the entire amines and its derivative in the (A4) polybenzoxazole precursor is preferably within the range of 50 to 100 mol %, more preferably within the range of 60 to 100 mol %, and further preferably within the range of 70 to 100 mol %. When the content ratio thereof is within the range mentioned above, the resolution can be improved.

<Tetracarboxylic Acid and Dicarboxylic Acid and their Derivatives>

As the tetracarboxylic acid, for example, aromatic tetracarboxylic acids, alicyclic tetracarboxylic acids, or aliphatic tetracarboxylic acids can be cited.

As the aromatic tetracarboxylic acids and their derivatives, for example, 1,2,4,5-benzene tetracarboxylic acid (pyromellitic acid), 3,3′,4,4′-biphenyl tetracarboxylic acid, 2,3,3′,4′-biphenyl tetracarboxylic acid, 2,2′,3,3′-biphenyl tetracarboxylic acid, 1,2,5,6-naphthalene tetracarboxylic acid, 1,4,5,8-naphthalene tetracarboxylic acid, 2,3,6,7-naphthalene tetracarboxylic acid, 3,3′,4,4′-benzophenone tetracarboxylic acid, 2,2′,3,3′-benzophenone tetracarboxylic acid, bis(3,4-dicarboxyphenyl)methane, bis(2,3-dicarboxyphenyl)methane, 1,1-bis(3,4-dicarboxyphenyl)ethane, 1,1-bis(2,3-dicarboxyphenyl)ethane, 2,2-bis(3,4-dicarboxyphenyl)propane, 2,2-bis(2,3-dicarboxyphenyl)propane, 2,2-bis[4-(3,4-dicarboxy phenoxy)phenyl]propane, 2,2-bis(3,4-dicarboxyphenyl)hexafluoropropane, 2,2-bis(2,3-dicarboxyphenyl)hexafluoropropane, bis(3,4-dicarboxyphenyl)sulfone, bis(3,4-dicarboxyphenyl)ether, 2,3,5,6-pyridine tetracarboxylic acid or 3,4,9,10-perylene tetracarboxylic acid, or N,N′-bis[5,5′-hexafluoropropane-2,2-diyl-bis(2-hydroxyphenyl)]bis(3,4-dicarboxybenzoic acid amide) can be cited. That is, compounds represented by the following general formula (70) or their tetracarboxylic acid dianhydride, tetracarboxylic acid dichloride or tetracarboxylic acid active diester can be cited.

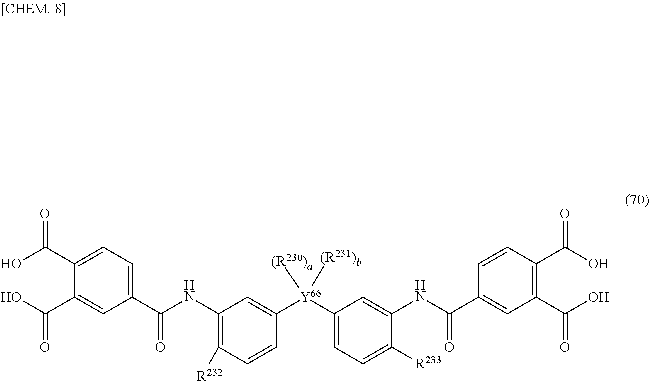

(In general formula (70), Y⁶⁶ represents a direct bond, an oxygen atom, or an alkylene chain having a carbon number of 1 to 4. In the case where Y⁶⁶ is a direct bond or an oxygen atom, a and b are 0. In the case where Y⁶⁶ is an alkylene chain having a carbon number of 1 to 4, R²³⁰ and R²³¹ represent a hydrogen, an alkyl group having a carbon number of 1 to 4, or an alkyl group which has 1 to 8 fluorine atoms and has a carbon number of 1 to 4. R²³² and R²³³ represent hydrogen, an alkyl group having a carbon number of 1 to 4, or a hydroxy group. a and b each represent an integer of 0 to 4. The alkylene chains and the alkyl groups mentioned above may be either an unsubstituted product or a substitution product.)

As the alicyclic tetracarboxylic acid and its derivative, for example, bicyclo[2.2.2]octane-7-ene-2,3,5,6-tetracarboxylic acid, 1,2,4,5-cyclohexane tetracarboxylic acid, 1,2,3,4-cyclopentane tetracarboxylic acid, 1,2,3,4-cyclobutane tetracarboxylic acid, or 2,3,4,5-tetrahydrofuran tetracarboxylic acid, or their tetracarboxylic dianhydrides, tetracarboxylic acid dichlorides, or tetracarboxylic acid active diesters can be cited.

As the aliphatic tetracarboxylic acid and its derivative, for example, butane-1,2,3,4-tetracarboxylic acid, or its tetracarboxylic dianhydride, tetracarboxylic acid dichloride or tetracarboxylic acid active diester can be cited.

As the dicarboxylic acids and their derivatives in the (A3) polybenzoxazole and the (A4) polybenzoxazole precursor, tricarboxylic acids and/or their derivatives may be used.

As the dicarboxylic acids and the tricarboxylic acids, for example, aromatic dicarboxylic acids, aromatic tricarboxylic acids, alicyclic dicarboxylic acids, alicyclic tricarboxylic acids, aliphatic dicarboxylic acids, or aliphatic tricarboxylic acids can be cited.

As the aromatic dicarboxylic acids and their derivatives, for example, phthalic acid, isophthalic acid, terephthalic acid, 4,4′-dicarboxybiphenyl, 2,2′-bis(trifluoromethyl)-4,4′-dicarboxybiphenyl, 4,4′-benzophenone dicarboxylic acid, 2,2-bis(4-carboxyphenyl)hexafluoropropane, 2,2-bis(3-carboxyphenyl)hexafluoropropane, or 4,4′-dicarboxy diphenyl ether, or their dicarboxylic acid anhydrides, dicarboxylic acid chlorides, dicarboxylic acid active esters, or diformyl compounds can be cited.

The aromatic tricarboxylic acids and their derivatives, for example, 1,2,4-benzene tricarboxylic acid, 1,3,5-benzene tricarboxylic acid, 2,4,5-benzophenone tricarboxylic acid, 2,4,4′-biphenyl tricarboxylic acid, or 3,3′,4′-tricarboxy diphenyl ether, or their tricarboxylic acid anhydrides, tricarboxylic acid chlorides, tricarboxylic acid active esters, or diformyl monocarboxylic acids can be cited.

As the alicyclic dicarboxylic acids and their derivatives, for example, 1,4-cyclohexane dicarboxylic acid or 1,2-cyclohexane dicarboxylic acid, or their dicarboxylic acid anhydrides, dicarboxylic acid chlorides, dicarboxylic acid active esters, or diformyl compounds can be cited.

As the alicyclic tricarboxylic acids and their derivatives, for example, 1,2,4-cyclohexane tricarboxylic acid or 1,3,5-cyclohexane tricarboxylic acid, or their tricarboxylic acid anhydrides, tricarboxylic acid chlorides, tricarboxylic acid active esters, or diformyl monocarboxylic acids can be cited.

As the aliphatic dicarboxylic acids and their derivatives, for example, hexane-1,6-dicarboxylic acid or succinic acid, or their dicarboxylic acid anhydrides, dicarboxylic acid chlorides, dicarboxylic acid active esters, or diformyl compounds can be cited.

As the aliphatic tricarboxylic acids and their derivatives, for example, hexane-1,3,6-tricarboxylic acid or propane-1,2,3-tricarboxylic acid, or their tricarboxylic acid anhydrides, tricarboxylic acid chlorides, tricarboxylic acid active esters, or diformyl monocarboxylic acids can be cited.

<Diamine and Its Derivatives>

As the diamine and its derivative, for example, aromatic diamines, bisaminophenol compounds, alicyclic diamines, alicyclic dihydroxy diamines, aliphatic diamines, or aliphatic dihydroxy diamines can be cited.

As the aromatic diamines, the bisaminophenol compounds, and their derivatives, for example, m-phenylene diamine, p-phenylene diamine, 1,4-bis(4-aminophenoxy) benzene, 4,4′-diaminobiphenyl, bis(4-aminophenoxy) biphenyl, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, 2,2′-bis(trifluoromethyl)-4,4′-diaminobiphenyl, 3,3′-diamino-4,4′-biphenol, 1,5-naphthalene diamine, 2,6-naphthalene diamine, 9,9-bis(3-amino-4-hydroxyphenyl)fluorene, 3,4′-diaminodiphenylmethane, 4,4′-diaminodiphenylmethane, bis(3-amino-4-hydroxyphenyl)methane, 1,1-bis(3-amino-4-hydroxyphenyl)ethane, 2,2-bis(3-amino-4-hydroxyphenyl)propane, 2,2-bis(4-aminophenyl)hexafluoropropane, 2,2-bis(3-amino-4-hydroxyphenyl)hexafluoropropane, 3,4′-diaminodiphenyl sulfone, 4,4′-diaminodiphenyl sulfone, bis(4-aminophenoxy phenyl)sulfone, bis(3-aminophenoxy phenyl)sulfone, bis(3-amino-4-hydroxyphenyl)sulfone, 3,4′-diaminodiphenyl sulfide, 4,4′-diaminodiphenyl sulfide, 3,4′-diaminodiphenyl ether, 4,4′-diaminodiphenyl ether, bis[4-(4-aminophenoxy)phenyl]ether, bis(3-amino-4-hydroxyphenyl)ether, 3-sulfonic acid-4,4′-diaminodiphenyl ether or dimercapto phenylene diamine, or N,N′-bis[5,5′-hexafluoropropane-2,2-diyl-bis(2-hydroxyphenyl)]bis(3-aminobenzoic acid amide) can be cited. That is, compounds represented by the following general formulas (61) to (66), or their diisocyanate compounds or trimethylsilylated diamines can be cited.

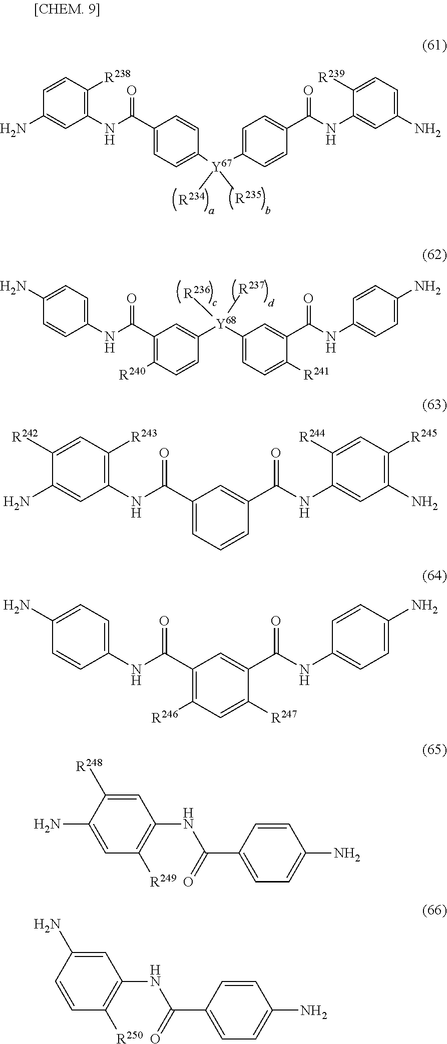

(In general formulas (61) to (66), Y⁶⁷ and Y⁶⁸ represent a direct bond, an oxygen atom, or an alkylene chain having a carbon number of 1 to 4. In the case where Y⁶⁷ and Y⁶⁸ is a direct bond or an oxygen atom, a, b, c, and d are 0. In the case where Y⁶⁷ and Y⁶⁸ are each an alkylene chain having a carbon number of 1 to 4, R²³⁴ and R²³⁷ represent a hydrogen, an alkyl group having a carbon number of 1 to 4, or an alkyl group which has 1 to 8 fluorine atoms and has a carbon number of 1 to 4. R²³⁸ to R²⁵⁰ represent hydrogen, an alkyl group having a carbon number of 1 to 4, or a hydroxy group. a, b, c and d represent an integer of 0 to 4. The alkylene chains and the alkyl groups mentioned above may be either an unsubstituted product or a substitution product.)

As the alicyclic diamines, the alicyclic dihydroxy diamine, and their derivatives, for example, compounds obtained by substituting one or more of hydrogen atoms of aromatic rings of the aromatic diamines and the bisaminophenol compounds with alkyl groups having a carbon number of 1 to 10, fluoroalkyl groups, or halogen atoms, 1,2-cyclohexane diamine, 1,4-cyclohexane diamine, bis(4-aminocyclohexyl)methane, 3,6-dihydroxy-1,2-cyclohexane diamine, 2,5-dihydroxy-1,4-cyclohexane diamine, or bis(3-hydroxy-4-aminocyclohexyl)methane, or their diisocyanate compounds or trimethylsilylated diamines can be cited.

As the aliphatic diamines, the aliphatic dihydroxy diamines, and their derivatives, for example, 1,6-hexamethylene diamine or 2,5-dihydroxy-1,6-hexamethylene diamine, or their diisocyanate compounds or trimethylsilylated diamines can be cited.

<Structural Unit Having Fluorine Atom>

It is preferable that one or more selected from the (A1) polyimide, the (A2) polyimide precursor, the (A3) polybenzoxazole, and the (A4) polybenzoxazole precursor contain a structural unit having a fluorine atom. When one or more selected from the (A1) polyimide, the (A2) polyimide precursor, the (A3) polybenzoxazole, and the (A4) polybenzoxazole precursor contains a structural unit having a fluorine atom, transparency is improved, and the sensitivity at the time of exposure can be improved. Furthermore, the one or more species of resins can provide a film surface with water repellency and can inhibit infiltration from the film surface at the time of alkaline development. The exposure mentioned herein means irradiation with chemical active rays (radiant rays); for example, visible light rays, ultraviolet ray, electron rays, X rays, or the like can be cited. From the viewpoint of being a generally-used light source, for example, a super high-pressure mercury lamp light source capable of radiating visible light rays or ultraviolet rays is preferable, and irradiation with j rays (313 nm wavelength), i rays (365 nm wavelength), h rays (405 nm wavelength), or g rays (436 nm wavelength) is more preferable. Hereinafter, exposure refers to irradiation with chemical active rays (radiant rays).

In general, when the (A1) polyimide, the (A2) polyimide precursor, the (A3) polybenzoxazole, and the (A4) polybenzoxazole precursor are used, as an aftermentioned solvent used for dissolving these resins, it is necessary to use a highly polar solvent such as N-methyl-2-pyrrolidone, dimethylsulfoxide, N,N-dimethylformamide or γ-butyrolactone. However, when the aftermentioned (C) benzofuranone based organic pigment having an amide structure is contained, those highly polar solvents strongly interact with the (C) benzofuranone based organic pigment having an amide structure, so that the effect of improving the dispersion stability due to the (A) alkali-soluble resin may be insufficient.

When one or more selected from the (A1) polyimide, the (A2) polyimide precursor, the (A3) polybenzoxazole, and the (A4) polybenzoxazole precursor contains the structural unit having a fluorine atom, the solubility with respect to the solvent can be improved. Thus, it is possible to reduce the content of the highly polar solvent mentioned above or to dissolve the resins without using the highly polar solvent, and the dispersion stability of the (C) benzofuranone based organic pigment having an amide structure can be improved.

As the structural unit having a fluorine atom which the (A1) polyimide and/or the (A2) polyimide precursor contain, a structural unit originating from a tetracarboxylic acid having a fluorine atom and/or its derivative or a structural unit originating from a diamine having a fluorine atom and/or its derivative can be cited.

As the structural unit having a fluorine atom which the (A3) polybenzoxazole and/or the (A4) polybenzoxazole precursor contain, a structural unit originating from a dicarboxylic acid having a fluorine atom and/or its derivative or a structural unit originating from a bisaminophenol compound having a fluorine atom and/or its derivative can be cited.

As the tetracarboxylic acids having fluorine atoms and their derivatives, for example, 2,2-bis(3,4-dicarboxyphenyl)hexafluoropropane, 2,2-bis(2,3-dicarboxyphenyl)hexafluoropropane, or N,N′-bis[5,5′-hexafluoropropane-2,2-diyl-bis(2-hydroxyphenyl)]bis(3,4-dicarboxybenzoic acid amide) or their tetracarboxylic dianhydrides, tetracarboxylic acid dichlorides, or tetracarboxylic acid active diesters can be cited.

As the dicarboxylic acids having fluorine atoms and their derivatives, for example, 2,2′-bis(trifluoromethyl)-4,4′-dicarboxybiphenyl, 2,2-bis(4-carboxyphenyl)hexafluoropropane, or 2,2-bis(3-carboxyphenyl)hexafluoropropane or their dicarboxylic acid anhydrides, dicarboxylic acid chlorides, dicarboxylic acid active esters, or diformyl compounds can be cited.

As the diamines or bisaminophenol compounds having fluorine atoms and their derivatives, for example, 2,2′-bis(trifluoromethyl)-4,4′-diaminobiphenyl, 2,2-bis(4-aminophenyl)hexafluoropropane, 2,2-bis(3-amino-4-hydroxyphenyl)hexafluoropropane, or N,N′-bis[5,5′-hexafluoropropane-2,2-diyl-bis(2-hydroxyphenyl)]bis(3-aminobenzoic acid amide) or their diisocyanate compounds or trimethylsilylated diamines can be cited.

In one or more species of resins selected from the (A1) polyimide, the (A2) polyimide precursor, the (A3) polybenzoxazole, and the (A4) polybenzoxazole precursor, the content ratio of the structural unit originating from one or more species selected from tetracarboxylic acid having a fluorine atom, tetracarboxylic acid derivative having a fluorine atom, dicarboxylic acid having a fluorine atom, and a dicarboxylic acid derivative having a fluorine atom in the structural unit originating from the entire carboxylic acids and their derivatives is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

In one or more species of resins selected from the (A1) polyimide, the (A2) polyimide precursor, the (A3) polybenzoxazole, and the (A4) polybenzoxazole precursor, the content ratio of the structural unit originating from one or more species selected from diamine having a fluorine atom, diamine derivative having a fluorine atom, a bisaminophenol compound having a fluorine atom, and a bisaminophenol compound derivative having a fluorine atom in the structural unit originating from the entire amines and their derivatives is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

<Structural Unit Originating from One or More Species Selected from Tetracarboxylic Acid Having Fluorine Atom, Tetracarboxylic Acid Derivative Having Fluorine Atom, Dicarboxylic Acid Having Fluorine Atom, and Dicarboxylic Acid Derivative Having Fluorine Atom>

It is preferable that the (A1) polyimide and/or the (A2) polyimide precursor contain, as the structural unit originating from a tetracarboxylic acid having a fluorine atom and its derivative, a structural unit represented by general formula (16) and/or a structural unit represented by general formula (17).

In the (A1) polyimide and/or the (A2) polyimide precursor, it is more preferable that R¹ in general formula (3a) or R¹¹ in general formula (6) contain a structural unit represented by general formula (16) and/or a structural unit represented by general formula (17).

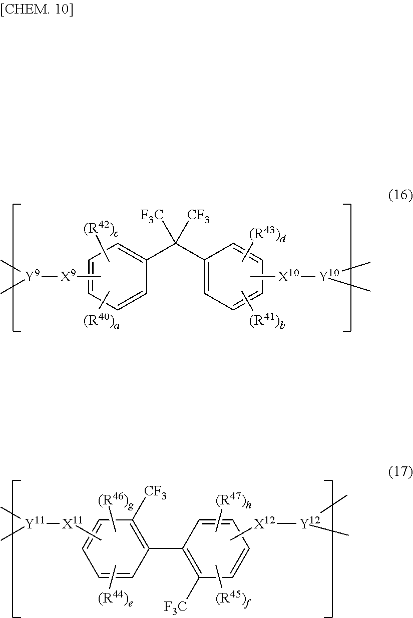

(In general formulas (16) and (17), R⁴⁰, R⁴¹, R⁴⁴ and R⁴⁵ each independently represent a substituent represented by general formula (5) or (6) mentioned above, R⁴², R⁴³, R⁴⁶ and R⁴⁷ each independently represent an alkyl group having a carbon number of 1 to 10, a cycloalkyl group having a carbon number of 4 to 10, an aryl group having a carbon number of 6 to 15, a phenolic hydroxyl group, a sulfonic acid group, or a mercapto group. X⁹ to X¹² each independently represent a direct bond, an oxygen atom, or a bond represented by general formula (20) In the case where X⁹ to X¹² are direct bonds, Y⁹ to Y¹² each independently represent a direct bond, an alkylene chain having a carbon number of 1 to 10, a cycloalkylene chain having a carbon number of 4 to 10, or an arylene chain having a carbon number of 6 to 15. In the case where X⁹ to X¹² are each an oxygen atom or a bond represented by general formula (20), Y⁹ to Y¹² each independently represent an alkylene chain having a carbon number of 1 to 10, a cycloalkylene chain having a carbon number of 4 to 10, or an arylene chain having a carbon number of 6 to 15. a to d each independently represent an integer of 0 to 4, e to h each independently represent an integer of 0 to 3, 0≤a+c≤4, 0≤b+d≤4, 0≤e+g≤3, and 0≤f+h≤3.)

In general formulas (16) and (17), it is preferable that R⁴², R⁴³, R⁴⁶ and R⁴⁷ each independently be an alkyl group having a carbon number of 1 to 6, a cycloalkyl group having a carbon number of 4 to 7, an aryl group having a carbon number of 6 to 10, a phenolic hydroxyl group, a sulfonic acid group, or a mercapto group. It is preferable that Y⁹ to Y¹² each independently be a direct bond, an alkylene chain having a carbon number of 1 to 6, a cycloalkylene chain having a carbon number of 4 to 7, or an arylene chain having a carbon number of 6 to 10. The alkyl group, the cycloalkyl group, the aryl group, the alkylene chain, the cycloalkylene chain, and the arylene chain mentioned above may be either an unsubstituted product or a substitution product.

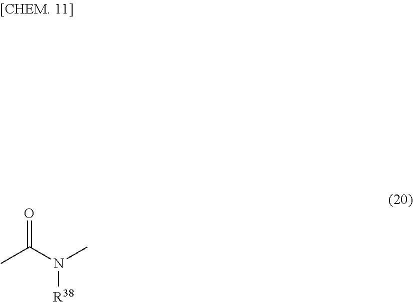

(In general formula (20), R³⁸ represents hydrogen, an alkyl group having a carbon number of 1 to 10, an acyl group having a carbon number of 2 to 6, or an aryl group having a carbon number of 6 to 15.)

In general formula (20), it is preferable that R³⁸ be hydrogen, an alkyl group having a carbon number of 1 to 6, an acyl group having a carbon number of 2 to 4, or an aryl group having a carbon number of 6 to 10. The alkyl group, the acyl group, and the aryl group mentioned above may be either an unsubstituted product or a substitution product.

It is preferable that the (A3) polybenzoxazole and/or the (A4) polybenzoxazole precursor contain, as a structural unit originating from a dicarboxylic acid having a fluorine atom or its derivative, a structural unit represented by general formula (18) and/or a structural unit represented by general formula (19).

In the (A3) polybenzoxazole and/or the (A4) polybenzoxazole precursor, it is more preferable that R⁵ in general formula (2) or R¹⁴ in general formula (4) contain a structural unit represented by general formula (18) and/or a structural unit represented by general formula (19).

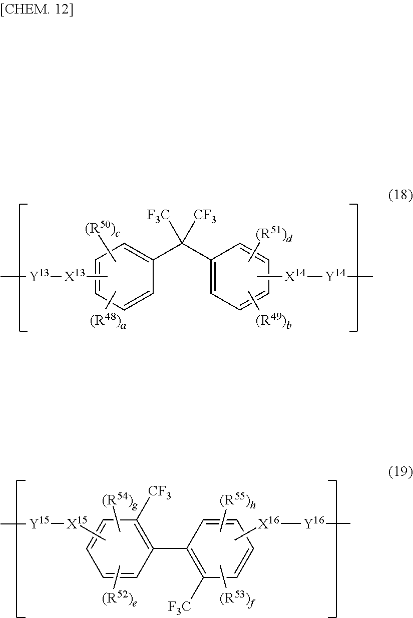

(In general formulas (18) and (19), R⁴⁸, R⁴⁹, R⁵² and R⁵³ each independently represent a substituent represented by general formula (4) or (5) mentioned above, R⁵⁰, R⁵¹, R⁵⁴ and R⁵⁵ each independently represent an alkyl group having a carbon number of 1 to 10, a cycloalkyl group having a carbon number of 4 to 10, an aryl group having a carbon number of 6 to 15, a phenolic hydroxyl group, a sulfonic acid group, or a mercapto group. X¹³ to X¹⁶ each independently represent a direct bond, an oxygen atom, or a bond represented by general formula (20) mentioned above. In the case where X¹³ to X¹⁶ are direct bonds, Y¹³ to Y¹⁶ each independently represent a direct bond, an alkylene chain having a carbon number of 1 to 10, a cycloalkylene chain having a carbon number of 4 to 10, or an arylene chain having a carbon number of 6 to 15. In the case where X¹³ to X¹⁶ are oxygen atoms or bonds represented by general formula (20) mentioned above, Y¹³ to Y¹⁶ each independently represent an alkylene chain having a carbon number of 1 to 10, a cycloalkylene chain having a carbon number of 4 to 10, or an arylene chain having a carbon number of 6 to 15. a to d each independently represent an integer of 0 to 4, e to h each independently represent an integer of 0 to 3, 0≤a+c≤4, 0≤b+d≤4, 0≤e+g≤3, and 0≤f+h≤3.)

In general formulas (18) and (19), it is preferable that R⁵⁰, R⁵¹, R⁵⁴ and R⁵⁵ each independently be an alkyl group having a carbon number of 1 to 6, a cycloalkyl group having a carbon number of 4 to 7, an aryl group having a carbon number of 6 to 10, a phenolic hydroxyl group, a sulfonic acid group, or a mercapto group. It is preferable that Y¹³ to Y¹⁶ each independently be a direct bond, an alkylene chain having a carbon number of 1 to 6, a cycloalkylene chain having a carbon number of 4 to 7, or an arylene chain having a carbon number of 6 to 10. The alkyl group, the cycloalkyl group, the aryl group, the alkylene chain, the cycloalkylene chain, and the arylene chain mentioned above may be either an unsubstituted product or a substitution product.

As a structural unit represented by general formula (16) or (17) contained in the (A1) polyimide and/or the (A2) polyimide precursor, a structural unit represented by any of general formulas (33) to (38) is preferable.

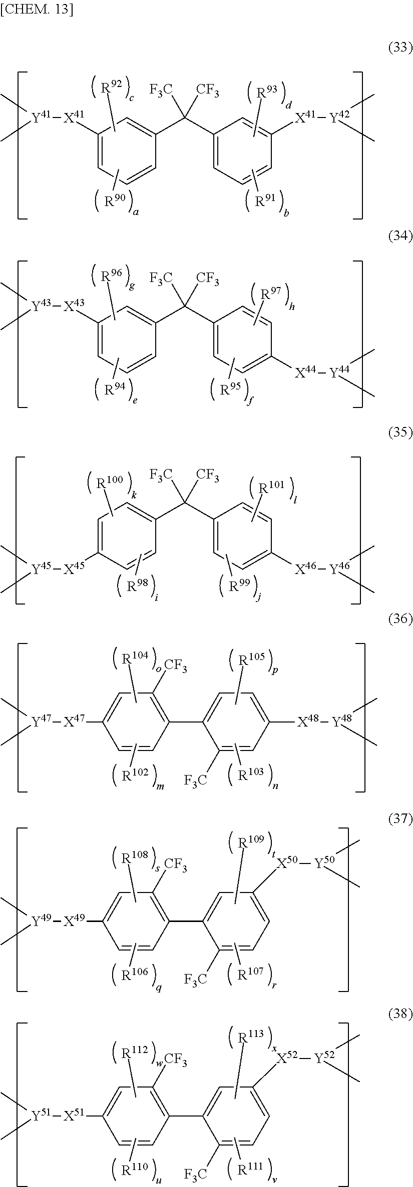

(In general formulas (33) to (38), R⁹⁰, R⁹¹, R⁹⁴, R⁹⁵, R⁹⁸, R⁹⁹, R¹⁰², R¹⁰³, R¹⁰⁶, R¹⁰⁷, R¹¹⁰, and R¹¹¹ each independently represent a substituent represented by general formula (4) or (5) mentioned above, and R⁹², R⁹³, R⁹⁶, R⁹⁷, R¹⁰⁰, R¹⁰¹, R¹⁰⁴, R¹⁰⁵, R¹⁰¹⁸, R¹⁰⁹, R¹¹², and R¹¹³ each independently represent an alkyl group having a carbon number of 1 to 10, a cycloalkyl group having a carbon number of 4 to 10, an aryl group having a carbon number of 6 to 15, a phenolic hydroxyl group, a sulfonic acid group, or a mercapto group. X⁴¹ to X⁵² each independently represent a direct bond, an oxygen atom, or a bond represented by general formula (20) mentioned above. In the case where X⁴¹ to X⁵² are direct bonds, X⁴¹ to X⁵² each independently represent a direct bond, an alkylene chain having a carbon number of 1 to 10, a cycloalkylene chain having a carbon number of 4 to 10, or an arylene chain having a carbon number of 6 to 15. In the case where X⁴¹ to X⁵² are oxygen atoms or bonds represented by general formula (20) mentioned above, Y⁴¹ to Y⁵² each independently represent an alkylene chain having a carbon number of 1 to 10, a cycloalkylene chain having a carbon number of 4 to 10, or an arylene chain having a carbon number of 6 to 15. a to 1 each independently represent an integer of 0 to 4, m to x each independently represent an integer of 0 to 3, 0≤a+c≤4, 0≤b+d≤4, 0≤e+g≤4, 0≤f+h≤4, 0≤i+k≤4, 0≤j+l≤4, 0≤m+o≤3, 0≤n+p≤3, 0≤q+s≤3, 0≤r+t≤3, 0≤u+w≤3, and 0≤v+x≤3.

In general formulas (33) to (38), it is preferable that R⁹², R⁹³, R⁹⁶, R⁹⁷, R¹⁰⁰, R¹⁰¹, R¹⁰⁴, R¹⁰⁵, R¹⁰⁸, R¹⁰⁹, R¹¹², and R¹¹³ each independently be an alkyl group having a carbon number of 1 to 6, a cycloalkyl group having a carbon number of 4 to 7, an aryl group having a carbon number of 6 to 10, a phenolic hydroxyl group, a sulfonic acid group, or a mercapto group. It is preferable that X⁴¹ to X⁵² each independently be a direct bond, an alkylene chain having a carbon number of 1 to 6, a cycloalkylene chain having a carbon number of 4 to 7, or an arylene chain having a carbon number of 6 to 10. The alkyl group, the cycloalkyl group, the aryl group, the alkylene chain, the cycloalkylene chain, and the arylene chain mentioned above may be either an unsubstituted product or a substitution product.

As a structural unit represented by general formula (18) or (19) contained in the (A3) polybenzoxazole and/or the (A4) polybenzoxazole precursor, a structural unit represented by any of general formulas (39) to (44) is preferable.

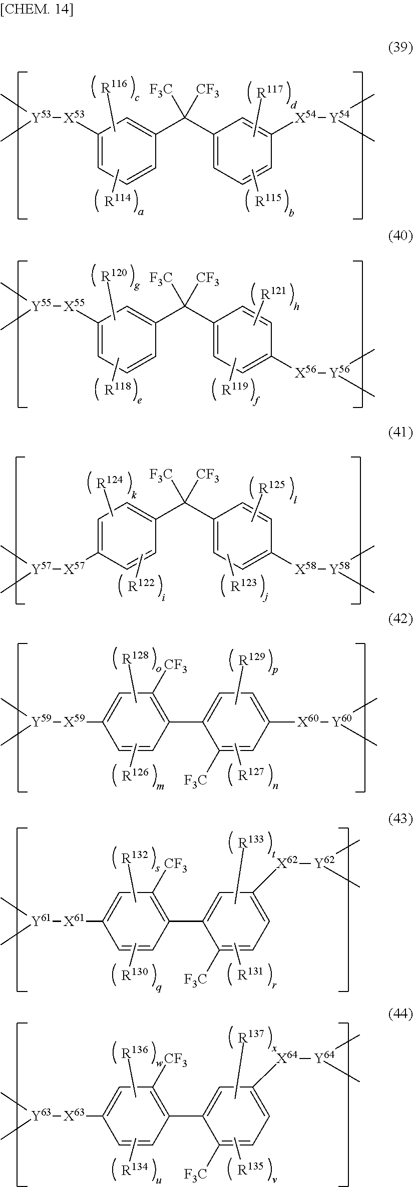

(In general formulas (39) to (44), R¹¹⁴, R¹¹⁵, R¹¹⁸, R¹¹⁹, R¹²², R¹²³, R¹²⁶, R¹²⁷, R¹³⁰, R¹³¹, R¹³⁴, and R¹³⁵ each independently represent a substituent represented by general formula (4) or (5) mentioned above, and R¹¹⁶, R¹¹⁷, R¹²⁰, R¹²¹, R¹²⁴, R¹²⁵, R¹²⁸, R¹²⁹, R¹³², R¹³³, R¹³⁶, and R¹³⁷ each independently represent an alkyl group having a carbon number of 1 to 10, a cycloalkyl group having a carbon number of 4 to 10, an aryl group having a carbon number of 6 to 15, a phenolic hydroxyl group, a sulfonic acid group, or a mercapto group. X⁵³ to X⁶⁴ each independently represent a direct bond, an oxygen atom, or a bond represented by general formula (20) mentioned above. In the case where X⁵³ to X⁶⁴ are direct bonds, X⁵³ to X⁶⁴ each independently represent a direct bond, an alkylene chain having a carbon number of 1 to 10, a cycloalkylene chain having a carbon number of 4 to 10, or an arylene chain having a carbon number of 6 to 15. In the case where X⁵³ to X⁶⁴ are oxygen atoms or bonds represented by general formula (20) mentioned above, X⁵³ to X⁶⁴ each independently represent an alkylene chain having a carbon number of 1 to 10, a cycloalkylene chain having a carbon number of 4 to 10, or an arylene chain having a carbon number of 6 to 15. a to 1 each independently represent an integer of 0 to 4, m to x each independently represent an integer of 0 to 3, 0≤a+c≤4, 0≤b+d≤4, 0≤e+g≤4, 0≤f+h≤4, 0≤i+k≤4, 0≤j+l≤4, 0≤m+o≤3, 0≤n+p≤3, 0≤q+s≤3, 0≤r+t≤3, 0≤u+w≤3, and 0≤v+x≤3.)

In general formulas (39) to (44), it is preferable that R¹¹⁶, R¹¹⁷, R¹²⁰, R¹²¹, R¹²⁴, R¹²⁵, R¹²⁸, R¹²⁹, R¹³², R¹³³, R¹³⁶, and R¹³⁷ each independently be an alkyl group having a carbon number of 1 to 6, a cycloalkyl group having a carbon number of 4 to 7, an aryl group having a carbon number of 6 to 10, a phenolic hydroxyl group, a sulfonic acid group, or a mercapto group. It is preferable that X⁵³ to X⁶⁴ each independently be a direct bond, an alkylene chain having a carbon number of 1 to 6, a cycloalkylene chain having a carbon number of 4 to 7, or an arylene chain having a carbon number of 6 to 10. The alkyl group, the cycloalkyl group, the aryl group, the alkylene chain, the cycloalkylene chain, and the arylene chain mentioned above may be either an unsubstituted product or a substitution product.

The content ratio of the structural unit represented by any of general formulas (33) to (38) in a structural unit originating from the entire carboxylic acids and its derivative in the (A1) polyimide is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

The content ratio of the structural unit represented by any of general formulas (33) to (38) in a structural unit originating from the entire carboxylic acids and its derivative in the (A2) polyimide precursor is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

The content ratio of the structural unit represented by any of general formulas (39) to (44) in a structural unit originating from the entire carboxylic acids and its derivative in the (A3) polybenzoxazole is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

The content ratio of the structural unit represented by any of general formulas (39) to (44) in a structural unit originating from the entire carboxylic acids and its derivative in the (A4) polybenzoxazole precursor is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

<Structural Unit Originating from One or More Species Selected from Diamine Having Fluorine Atom, Diamine Derivative Having Fluorine Atom, Bisaminophenol Compound Having Fluorine Atom, and Bisaminophenol Compound Derivative Having Fluorine Atom>

It is preferable that the (A1) polyimide and/or the (A2) polyimide precursor contain, as a structural unit originating from diamine having a fluorine atom and its derivative, a structural unit represented by general formula (12) and/or a structural unit represented by general formula (13).

In the (A1) polyimide and/or the (A2) polyimide precursor, it is more preferable that R² in general formula (3a) or R¹¹ in general formula (6) contain a structural unit represented by general formula (12) and/or a structural unit represented by general formula (13).

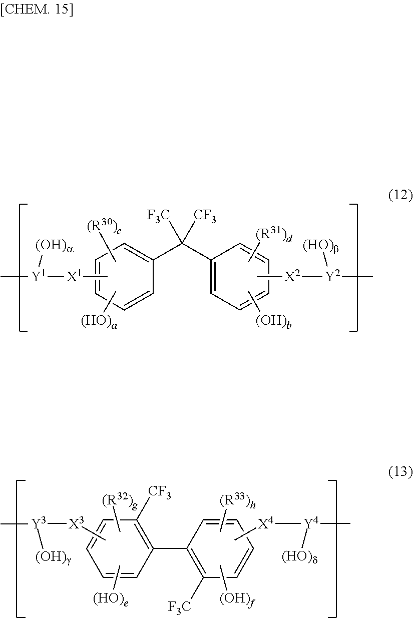

(In general formulas (12) and (13), R³⁰ to R³³ each independently represent an alkyl group having a carbon number of 1 to 10, a cycloalkyl group having a carbon number of 4 to 10, an aryl group having a carbon number of 6 to 15, a sulfonic acid group, a carboxy group, or a mercapto group. X¹ to X⁴ each independently represent a direct bond, an oxygen atom, or a bond represented by general formula (20) mentioned above. In the case where X¹ to X⁴ are direct bonds, Y¹ to Y⁴ each independently represent a direct bond, an alkylene chain having a carbon number of 1 to 10, a cycloalkylene chain having a carbon number of 4 to 10, or an arylene chain having a carbon number of 6 to 15. In the case where X¹ to X⁴ are oxygen atoms or bonds represented by general formula (20) mentioned above, Y¹ to Y⁴ each independently represent an alkylene chain having a carbon number of 1 to 10, a cycloalkylene chain having a carbon number of 4 to 10, or an arylene chain having a carbon number of 6 to 15. a to h and a to 6 each independently represent an integer of 0 to 4, 0≤a+c≤4, 0≤b+d≤4, 0≤e+g≤4, and 0≤f+h≤4. In the case where Y¹ to Y⁴ are direct bonds, a to 6 are 0.)

In general formulas (12) and (13), it is preferable that R³⁰ to R³³ each independently be an alkyl group having a carbon number of 1 to 6, a cycloalkyl group having a carbon number of 4 to 7, an aryl group having a carbon number of 6 to 10, a sulfonic acid group, a carboxy group, or a mercapto group. It is preferable that Y¹ to Y⁴ each independently be a direct bond, an alkylene chain having a carbon number of 1 to 6, a cycloalkylene chain having a carbon number of 4 to 7, or an arylene chain having a carbon number of 6 to 10. a, b, e and f are each independently preferably 1 to 4. The alkyl group, the cycloalkyl group, the aryl group, the alkylene chain, the cycloalkylene chain, and the arylene chain mentioned above may be either an unsubstituted product or a substitution product.

It is preferable that the (A3) polybenzoxazole and/or the (A4) polybenzoxazole precursor contain as a structural unit originating from a bisaminophenol compound having a fluorine atom and its derivative, a structural unit represented by general formula (14) and/or a structural unit represented by general formula (15).

In the (A3) polybenzoxazole and/or the (A4) polybenzoxazole precursor, it is more preferable that R¹¹ in general formula (7) or R²¹ in general formula (8) contain a structural unit represented by general formula (14) and/or a structural unit represented by general formula (15).

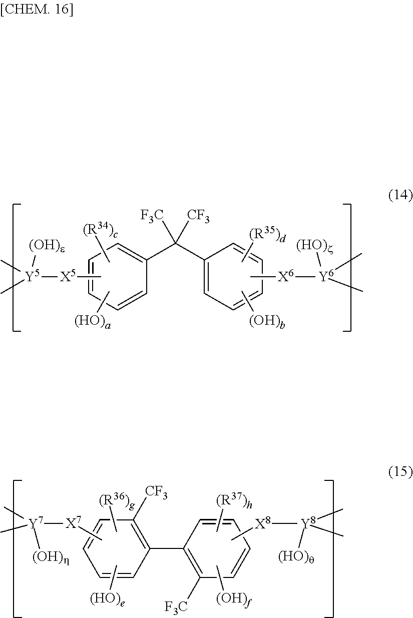

(In general formulas (14) and (15), R³⁴ to R³⁷ each independently represent an alkyl group having a carbon number of 1 to 10, a cycloalkyl group having a carbon number of 4 to 10, an aryl group having a carbon number of 6 to 15, a sulfonic acid group, a carboxy group, or a mercapto group. X⁵ to X⁸ each independently represent a direct bond, an oxygen atom, or a bond represented by general formula (20) mentioned above. In the case where X⁵ to X⁸ are direct bonds, Y⁵ to Y⁸ each independently represent a direct bond, an alkylene chain having a carbon number of 1 to 10, a cycloalkylene chain having a carbon number of 4 to 10, or an arylene chain having a carbon number of 6 to 15. In the case where X⁵ to X⁸ are oxygen atoms or bonds represented by general formula (20) mentioned above, Y⁵ to Y⁸ each independently represent an alkylene chain having a carbon number of 1 to 10, a cycloalkylene chain having a carbon number of 4 to 10, or an arylene chain having a carbon number of 6 to 15. a to d and $ to 0 each independently represent an integer of 0 to 4, e to h each independently represent an integer of 0 to 3, 0≤a+c≤4, 0≤b+d≤4, 0≤e+g≤3, and 0≤f+h≤3. In the case where Y⁵ to Y⁸ are direct bonds, ε to θ are 0.)

In general formulas (14) and (15), it is preferable that R³⁴ to R³⁷ each independently be an alkyl group having a carbon number of 1 to 6, a cycloalkyl group having a carbon number of 4 to 7, an aryl group having a carbon number of 6 to 10, a sulfonic acid group, a carboxy group, or a mercapto group. It is preferable that Y⁵ to Y⁸ each independently be a direct bond, an alkylene chain having a carbon number of 1 to 6, a cycloalkylene chain having a carbon number of 4 to 7, or an arylene chain having a carbon number of 6 to 10. a, b, e and f are each independently preferably 1 to 4. The alkyl group, the cycloalkyl group, the aryl group, the alkylene chain, the cycloalkylene chain, and the arylene chain mentioned above may be either an unsubstituted product or a substitution product.

As a structural unit represented by general formula (12) or (13) contained in the (A1) polyimide and/or the (A2) polyimide precursor, structural units represented by general formulas (21) to (26) are preferable.

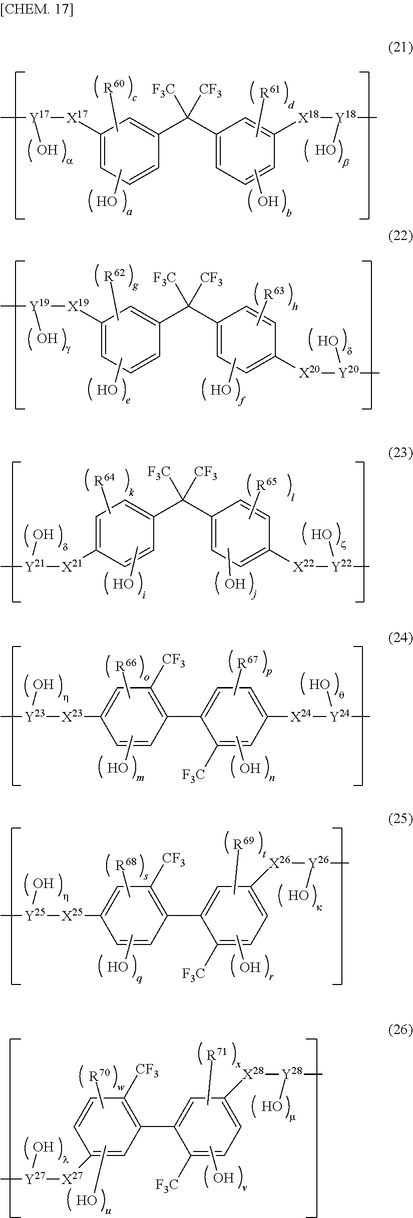

In general formulas (21) to (26), R⁶⁰ to R⁷¹ each independently represent an alkyl group having a carbon number of 1 to 10, a cycloalkyl group having a carbon number of 4 to 10, an aryl group having a carbon number of 6 to 15, a sulfonic acid group, a carboxy group, or a mercapto group. X¹⁷ to X²⁸ each independently represent a direct bond, an oxygen atom, or a bond represented by general formula (20) mentioned above. In the case where X¹⁷ to X²⁸ are direct bonds, Y¹⁷ to Y²⁸ each independently represent a direct bond, an alkylene chain having a carbon number of 1 to 10, a cycloalkylene chain having a carbon number of 4 to 10, or an arylene chain having a carbon number of 6 to 15. In the case where X¹⁷ to X²⁸ are oxygen atoms or bonds represented by general formula (20) mentioned above, Y¹⁷ to Y²⁸ each independently represent an alkylene chain having a carbon number of 1 to 10, a cycloalkylene chain having a carbon number of 4 to 10, or an arylene chain having a carbon number of 6 to 15. a to 1 and a to t each independently represent an integer of 0 to 4, m to x each independently represent an integer of 0 to 3, 0≤a+c≤4, 0≤b+d≤4, 0≤e+g≤4, 0≤f+h≤4, 0≤I+k≤4, 0≤j+l≤4, 0≤m+o≤3, 0≤n+p≤3, 0≤q+s≤3, 0≤r+t≤3, 0≤u+w≤3, and 0≤v+x≤3. In the case where Y¹⁷ to Y²⁸ are direct bonds, α to μ are 0.)

In general formulas (21) to (26), it is preferable that R⁶⁰ to R⁷¹ each independently be an alkyl group having a carbon number of 1 to 6, a cycloalkyl group having a carbon number of 4 to 7, an aryl group having a carbon number of 6 to 10, a sulfonic acid group, a carboxy group, or a mercapto group. It is preferable that Y¹⁷ to Y²⁸ each independently be a direct bond, an alkylene chain having a carbon number of 1 to 6, a cycloalkylene chain having a carbon number of 4 to 7, or an arylene chain having a carbon number of 6 to 10. a, b, e, f, i, j, m, n, q, r, u and v are each independently preferably 1 to 4. The alkyl group, the cycloalkyl group, the aryl group, the alkylene chain, the cycloalkylene chain, and the arylene chain mentioned above may be either an unsubstituted product or a substitution product.

As a structural unit represented by general formula (14) or (15) contained in the (A3) polybenzoxazole and/or the (A4) polybenzoxazole precursor, a structural unit represented by any of general formulas (27) to (32) is preferable.

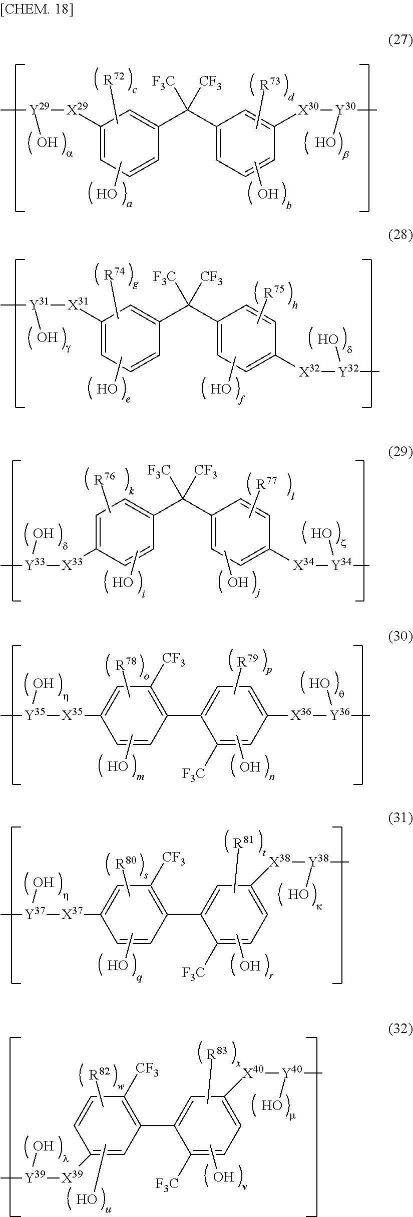

(In general formulas (27) to (32), R⁷² to R⁸³ each independently represent an alkyl group having a carbon number of 1 to 10, a cycloalkyl group having a carbon number of 4 to 10, an aryl group having a carbon number of 6 to 15, a sulfonic acid group, a carboxy group, or a mercapto group. X²⁹ to X⁴⁰ each independently represent a direct bond, an oxygen atom, or a bond represented by general formula (20) mentioned above. In the case where X²⁹ to X⁴⁰ are direct bonds, Y²⁹ to Y⁴⁰ each independently represent a direct bond, an alkylene chain having a carbon number of 1 to 10, a cycloalkylene chain having a carbon number of 4 to 10, or an arylene chain having a carbon number of 6 to 15. In the case where X²⁹ to X⁴⁰ are oxygen atoms or bonds represented by general formula (20) mentioned above, Y²⁹ to Y⁴⁰ each independently represent an alkylene chain having a carbon number of 1 to 10, a cycloalkylene chain having a carbon number of 4 to 10, or an arylene chain having a carbon number of 6 to 15. a to 1 and a to t each independently represent an integer of 0 to 4, m to x each independently represent an integer of 0 to 3, 0≤a+c≤4, 0≤b+d≤4, 0≤e+g≤4, 0≤f+h≤4, 0≤I+k≤4, 0≤j+l≤4, 0≤m+o≤3, 0≤n+p≤3, 0≤q+s≤3, 0≤r+t≤3, 0≤u+w≤3, and 0≤v+x≤3. In the case where Y²⁹ to Y⁴⁰ are direct bonds, α to μ are 0.)

In general formulas (27) to (32), it is preferable that R⁷² to R⁸³ each independently be an alkyl group having a carbon number of 1 to 6, a cycloalkyl group having a carbon number of 4 to 7, an aryl group having a carbon number of 6 to 10, a sulfonic acid group, a carboxy group, or a mercapto group. It is preferable that Y²⁹ and Y³⁰ each independently be a direct bond, an alkylene chain having a carbon number of 1 to 6, a cycloalkylene chain having a carbon number of 4 to 7, or an arylene chain having a carbon number of 6 to 10. a, b, e, f, i, j, m, n, q, r, u and v are each independently preferably 1 to 4. The alkyl group, the cycloalkyl group, the aryl group, the alkylene chain, the cycloalkylene chain, and the arylene chain mentioned above may be either an unsubstituted product or a substitution product.

The content ratio of the structural unit represented by any of general formulas (21) to (26) in a structural unit originating from the entire amines and its derivative in the (A1) polyimide is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

The content ratio of the structural unit represented by any of general formulas (21) to (26) in a structural unit originating from the entire amines and its derivative in the (A2) polyimide precursor is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

The content ratio of the structural unit represented by any of general formulas (27) to (32) in a structural unit originating from the entire amines and its derivative in the (A3) polybenzoxazole is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

The content ratio of the structural unit represented by any of general formulas (27) to (32) in a structural unit originating from the entire amines and its derivative in the (A4) polybenzoxazole precursor is preferably within the range of 30 to 100 mol %, more preferably within the range of 50 to 100 mol %, and further preferably within the range of 70 to 100 mol %. When the content ratio thereof is within the range mentioned above, the sensitivity at the time of exposure can be improved.

<Structural Unit Originating from Aromatic, Alicyclic and Aliphatic Carboxylic Acids and their Derivatives>

It is preferable that the (A1) polyimide and/or the (A2) polyimide precursor contain a structural unit originating from aromatic tetracarboxylic acid and/or its derivative. When the (A1) polyimide and/or the (A2) polyimide precursor contain a structural unit originating from aromatic carboxylic acid and/or its derivative, the heat resistance of the cured film can be improved by heat resistance of an aromatic group. As aromatic carboxylic acid and its derivative, aromatic tetracarboxylic acid and/or its derivative are preferable.

The content ratio of the structural unit originating from aromatic tetracarboxylic acid and/or its derivative in the structural unit originating from the entire carboxylic acids and its derivative in the (A1) polyimide is preferably within the range of 50 to 100 mol %, more preferably within the range of 60 to 100 mol %, and further preferably within the range of 70 to 100 mol %. When the content ratio thereof is within the range mentioned above, the heat resistance of the cured film can be improved.

The content ratio of the structural unit originating from aromatic tetracarboxylic acid and/or its derivative in the structural unit originating from the entire carboxylic acids and its derivative in the (A2) polyimide precursor is preferably within the range of 50 to 100 mol %, more preferably within the range of 60 to 100 mol %, and further preferably within the range of 70 to 100 mol %. When the content ratio thereof is within the range mentioned above, the heat resistance of the cured film can be improved.

The (A1) polyimide and/or the (A2) polyimide precursor may contain a structural unit originating from alicyclic carboxylic acid or aliphatic carboxylic acid and/or their derivatives. As alicyclic carboxylic acid or aliphatic carboxylic acid and their derivatives, alicyclic tetracarboxylic acid or aliphatic tetracarboxylic acid and/or their derivatives are preferable.

It is preferable that the (A3) polybenzoxazole and/or the (A4) polybenzoxazole precursor contain a structural unit originating from aromatic carboxylic acid and/or its derivative. When the (A3) polybenzoxazole and/or the (A4) polybenzoxazole precursor contain the structural unit originating from aromatic carboxylic acid and/or its derivative, the heat resistance of the cured film can be improved by the heat resistance of the aromatic group. As aromatic carboxylic acid and its derivative, aromatic dicarboxylic acid or aromatic tricarboxylic acid and/or their derivatives are preferable, and aromatic dicarboxylic acid and/or its derivative are more preferable.

The content ratio of the structural unit originating from aromatic carboxylic acid and/or its derivative in the structural unit originating from the entire carboxylic acids and its derivative in the (A3) polybenzoxazole is preferably within the range of 50 to 100 mol %, more preferably within the range of 60 to 100 mol %, and further preferably within the range of 70 to 100 mol %. When the content ratio thereof is within the range mentioned above, the heat resistance of the cured film can be improved.

The content ratio of the structural unit originating from aromatic carboxylic acid and/or its derivative in the structural unit originating from the entire carboxylic acids and its derivative in the (A4) polybenzoxazole precursor is preferably within the range of 50 to 100 mol %, more preferably within the range of 60 to 100 mol %, and further preferably within the range of 70 to 100 mol %. When the content ratio thereof is within the range mentioned above, the heat resistance of the cured film can be improved.

The (A3) polybenzoxazole and/or the (A4) polybenzoxazole precursor may contain a structural unit originating from alicyclic carboxylic acid or aliphatic carboxylic acid and/or their derivatives. As alicyclic carboxylic acid or aliphatic carboxylic acid and their derivatives, alicyclic dicarboxylic acid, aliphatic dicarboxylic acid, alicyclic tricarboxylic acid or aliphatic tricarboxylic acid and/or their derivatives are preferable, and alicyclic dicarboxylic acid or aliphatic dicarboxylic acid and/or their derivatives are more preferable.

<Structural Unit Originating from Aromatic, Alicyclic and Aliphatic Amines and Their Derivatives>

It is preferable that the one or more selected from the (A1) polyimide, the (A2) polyimide precursor, the (A3) polybenzoxazole, and the (A4) polybenzoxazole precursor contain a structural unit originating from aromatic amine and/or a derivative of the aromatic amine. When the one or more selected from the (A1) polyimide, the (A3) polybenzoxazole, the (A2) polyimide precursor, and the (A4) polybenzoxazole precursor contain the structural unit originating from aromatic amine and/or the derivative of the aromatic amine, the heat resistance of the cured film can be improved by the heat resistance of the aromatic group. As aromatic amine and the derivative of the aromatic amine, aromatic diamine, a bisaminophenol compound, aromatic triamine or a trisaminophenol compound and/or their derivatives are preferable, and aromatic diamine or a bisaminophenol compound and/or their derivatives are more preferable.

In one or more species of resins selected from the (A1) polyimide, the (A2) polyimide precursor, the (A3) polybenzoxazole, and the (A4) polybenzoxazole precursor, the content ratio of the structural unit originating from aromatic amine and/or the derivative of the aromatic amine in a structural unit originating from the entire amines and their derivatives is preferably within the range of 50 to 100 mol %, more preferably within the range of 60 to 100 mol %, and further preferably within the range of 70 to 100 mol %. When the content ratio thereof is within the range mentioned above, the heat resistance of the cured film can be improved.

The one or more selected from the (A1) polyimide, the (A2) polyimide precursor, the (A3) polybenzoxazole, and the (A4) polybenzoxazole precursor may contain a structural unit originating from alicyclic amine or aliphatic amine and/or their derivatives. As alicyclic amine or aliphatic amine and their derivatives, alicyclic diamines, alicyclic dihydroxy diamines, aliphatic diamines, or aliphatic dihydroxy diamines and/or their derivatives are preferable.

<Structural Unit Originating from Diamine Having Silyl Group or Siloxane Bond and its Derivative>

It is preferable that the one or more selected from the (A1) polyimide, the (A3) polybenzoxazole, the (A2) polyimide precursor, and the (A4) polybenzoxazole precursor contain a structural unit originating from diamine having a silyl group or a siloxane bond and/or a derivative of the diamine. As the one or more selected from the (A1) polyimide, the (A3) polybenzoxazole, the (A2) polyimide precursor, and the (A4) polybenzoxazole precursor contains a structural unit originating from diamine having a silyl group or a siloxane bond and/or a derivative of the diamine, the interaction at an interface between the cured film of the resin composition and a base substrate increases, so that the adhesion with the base substrate and the chemical resistance of the cured film can be improved.

As the diamine having a silyl group or a siloxane bond and its derivative, for example, 1,3-bis(3-aminopropyl)tetramethyl disiloxane or 1,9-bis(4-aminophenyl)octamethyl pentasiloxane can be cited.

In one or more species of resins selected from the (A1) polyimide, the (A3) polybenzoxazole, the (A2) polyimide precursor, and the (A4) polybenzoxazole precursor, content ratio of a structural unit originating from diamine having a silyl group or a siloxane bond and/or a derivative of the diamine in a structural unit originating from the entire amines and their derivatives is preferably 0.1 mol % or greater, more preferably 0.5 mol % or greater, and further preferably 1.0 mol % or greater. When the content ratio thereof is within the range mentioned above, the adhesion with the base substrate and the chemical resistance of the cured film can be improved. On the other hand, the content ratio thereof is preferably 30 mol % or less, more preferably 20 mol % or less, and further preferably 10 mol % or less. When the content ratio thereof is within the range mentioned above, the heat resistance of the cured film can be improved.

<Structural Unit Originating from Amine Having Oxyalkylene Structure and its Derivative>

It is preferable that the one or more selected from the (A1) polyimide, the (A3) polybenzoxazole, the (A2) polyimide precursor, and the (A4) polybenzoxazole precursor contain a structural unit originating from amine having an oxyalkylene structure and/or a derivative of the amine. As the one or more selected from the (A1) polyimide, the (A3) polybenzoxazole, the (A2) polyimide precursor, and the (A4) polybenzoxazole precursor contains a structural unit originating from amine having an oxyalkylene structure and/or a derivative of the amine, a low-taper pattern shape can be obtained and the mechanical characteristic of a cured film can be improved.

As the amine having an oxyalkylene structure and a derivative of the amine, a diamine having an oxyalkylene structure or triamine having an oxyalkylene structure and/or their derivatives are preferable.

It is preferable that the one or more selected from the (A1) polyimide, the (A2) polyimide precursor, the (A3) polybenzoxazole, and the (A4) polybenzoxazole precursor contain a structural unit represented by general formula (45) as a structural unit originating from diamine having an oxyalkylene structure and a derivative of the diamine.

In the (A1) polyimide and/or the (A2) polyimide precursor, it is more preferable that R⁵ in general formula (3a) or R¹² in general formula (3) contain a structural unit represented by general formula (45).

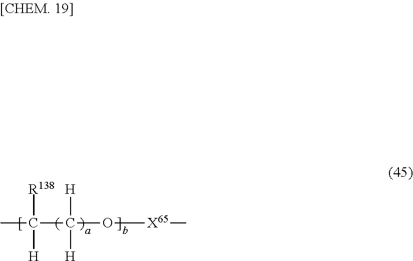

(In general formula (45), X⁶⁵ represents a direct bond or an alkylene chain having a carbon number of 1 to 10. R¹³⁸ represents hydrogen, an alkyl group having a carbon number of 1 to 10, a cycloalkyl group having a carbon number of 4 to 10, or an aryl group having a carbon number of 6 to 15. a and b represent an integer of 1 to 10.)

In general formula (45), it is preferable that X⁶⁵ be a direct bond or an alkylene chain having a carbon number of 1 to 6. It is preferable that R¹³⁸ be hydrogen, an alkyl group having a carbon number of 1 to 6, a cycloalkyl group having a carbon number of 4 to 7, or an aryl group having a carbon number of 6 to 10. The alkylene chain, the alkyl group, the cycloalkyl group, and the aryl group mentioned above may be either an unsubstituted product or a substitution product.

As triamine having an oxyalkylene structure and its derivative, a compound represented by general formula (46) is preferable.

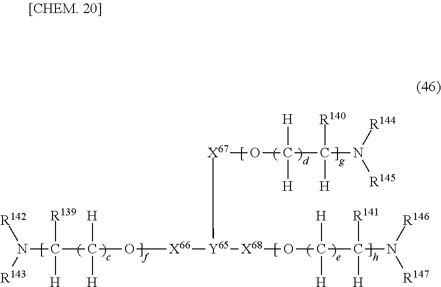

(In general formula (46), X⁶⁶ to X⁶⁸ each independently represent a direct bond or an alkylene chain having a carbon number of 1 to 10, and Y⁶⁵ represents a methine group, an alkane-1,1,1-triyl group having a carbon number of 1 to 10, a cycloalkane-triyl group having a carbon number of 4 to 10, or an arene-triyl group having a carbon number of 6 to 15. R¹³⁹ to R¹⁴⁷ each independently represent hydrogen or an alkyl group having a carbon number of 1 to 10. c to h represent an integer of 1 to 10.)

In general formula (46), it is preferable that X⁶⁶ to X⁶⁸ each independently be a direct bond or an alkylene chain having a carbon number of 1 to 6. Further, it is preferable that Y⁶⁵ be a methine group, an alkane-1,1,1-triyl group having a carbon number of 1 to 6, a cycloalkane-triyl group having a carbon number of 4 to 7, or an arene-triyl group having a carbon number of 6 to 10. Furthermore, it is preferable that R¹³⁹ to R¹⁴⁷ each independently be hydrogen or an alkyl group having a carbon number of 1 to 6. The alkyl group, the alkylene chain, the alkane-1,1,1-triyl group, the cycloalkane-triyl group or the arene-triyl group mentioned above may be either an unsubstituted product or a substitution product.

As the diamine having an oxyalkylene structure and its derivative, for example, “JEFFAMINE” (registered trademark) D-230, D-400 of the same, D-2000 of the same, D-4000 of the same, HK-511 of the same, ED-600 of the same, ED-900 of the same, ED-2003 of the same, EDR-148 of the same, EDR-176 of the same, SD-231 of the same, SD-401 of the same, SD-2001 of the same, THF-100 of the same, THF-140 of the same, THF-170 of the same, XTJ-582 of the same, XTJ-578 of the same, XTJ-542 of the same, XTJ-548 of the same, or XTJ-559 of the same, or “ELASTAMINE” (registered trademark) RP-405, RP-409 of the same, RP-2005 of the same, RP-2009 of the same, RT-1000 of the same, RE-600 of the same, RE-900 of the same, RE-2000 of the same, HE-150 of the same, HE-180 of the same, HE-1700 of the same, HT-1700 of the same, RE1-1000 of the same, RE1-2005 of the same, RE1-2007 of the same, RP3-400 of the same, or RP3-5000 of the same (all of which are made by HUNTSMAN) can be cited.

As the triamine having an oxyalkylene structure and its derivative, for example, “JEFFAMINE” (registered trademark) T-403, T-3000 of the same, T-5000 of the same, and ST-404 of the same (all of which are made by HUNTSMAN) can be cited.

In one or more species of resins selected from the (A1) polyimide, the (A3) polybenzoxazole, the (A2) polyimide precursor, and the (A4) polybenzoxazole precursor, content ratio of a structural unit originating from amine having an oxyalkylene structure and/or a derivative of the amine in a structural unit originating from the entire amines and their derivatives is preferably 1 mol % or greater, more preferably 5 mol % or greater, and further preferably 10 mol % or greater. When the content ratio thereof is within the range mentioned above, a low-taper pattern shape can be obtained and the mechanical characteristic of a cured film can be improved. On the other hand, the content ratio thereof is preferably 60 mol % or less, more preferably 50 mol % or less, and further preferably 40 mol % or less. When the content ratio thereof is within the range mentioned above, the heat resistance of the cured film can be improved.

<End-Capping Agent>

The one or more species of resins selected from the (A1) polyimide, the (A2) polyimide precursor, the (A3) polybenzoxazole, and the (A4) polybenzoxazole precursor may each have an end of the resin sealed by an end-capping agent such as monoamine, dicarboxylic anhydride, monocarboxylic acid, monocarboxylic acid chloride, or monocarboxylic acid active ester. As the resin end is sealed by an end-capping agent, it is possible to improve the storage stability of a coating liquid of a resin composition that contains the one or more selected from the (A1) polyimide, the (A2) polyimide precursor, the (A3) polybenzoxazole, and the (A4) polybenzoxazole precursor.

As the monoamine for use as an end-capping agent, for example, 5-amino-8-hydroxy quinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 3-amino-4,6-dihydroxy pyrimidine, 2-aminophenol, 3-aminophenol, 4-aminophenol, 2-aminothiophenol, 3-aminothiophenol, or 4-aminothiophenol can be cited.

As the dicarboxylic anhydride for use as an end-capping agent, for example, phthalic anhydride, maleic anhydride, succinic anhydride, 5-norbornene-2,3-dicarboxylic anhydride, cyclohexane dicarboxylic anhydride, or 3-hydroxy phthalic anhydride can be cited.

As the monocarboxylic acid and the monocarboxylic acid chloride for use as an end-capping agent, for example, benzoic acid, 3-carboxy phenol, 4-carboxy phenol, 3-carboxy thiophenol, 4-carboxy thiophenol, 1-hydroxy-7-carboxy naphthalene, 1-hydroxy-6-carboxy naphthalene, 1-hydroxy-5-carboxy naphthalene, 1-mercapto-7-carboxy naphthalene, 1-mercapto-6-carboxy naphthalene, 1-mercapto-5-carboxy naphthalene, 3-carboxybenzene sulfonic aid, 4-carboxybenzene sulfonic aid, and their monocarboxylic acid chlorides, or monocarboxylic acid chlorides of terephthalic acid, phthalic acid, maleic acid, cyclohexane dicarboxylic acid, 1,5-dicarboxy naphthalene, 1,6-dicarboxy naphthalene, 1,7-dicarboxy naphthalene, 2,6-dicarboxy naphthalene can be cited.

As the monocarboxylic acid active ester for use as an end-capping agent, for example, monocarboxylic acid active ester compounds obtained by reaction of the aforementioned acid chlorides with N-hydroxybenzotriazole or N-hydroxy-5-norbornene-2,3-dicarboxy imide can be cited.

In one or more species of resins selected from the (A1) polyimide, the (A2) polyimide precursor, the (A3) polybenzoxazole, and the (A4) polybenzoxazole precursor, content ratio of a structural unit originating from an end-capping agent in a structural unit originating from the entire amines, the entire carboxylic acids, and their derivatives is preferably 1 mol % or more, more preferably 3 mol % or more, and further preferably 5 mol % or more. When the content ratio is within the range mentioned above, the storage stability of a coating liquid of a resin composition can be improved. On the other hand, the content ratio thereof is preferably 30 mol % or less, more preferably 25 mol % or less, and further preferably 20 mol % or less. When the content ratio is within the range mentioned above, the post-development resolution can be improved.

The content ratio of the structural unit originating from various carboxylic acids or amines and their derivatives in the (A1) polyimide, the (A3) polybenzoxazole, the (A2) polyimide precursor or the (A4) polybenzoxazole precursor can be determined by a combination of ¹H-NMR, ¹³C-NMR, 15N-NMR, IR, TOF-MS, a chemical element analysis method, ash content measurement, and the like.

<Physical Properties of (A1) Polyimide, (A3) Polybenzoxazole, (A2) Polyimide Precursor or (A4) Polybenzoxazole Precursor>

In one or more species of resins selected from the (A1) polyimide, the (A2) polyimide precursor, the (A3) polybenzoxazole, and the (A4) polybenzoxazole precursor, the number of repetitions n of the structural unit is preferably 5 or greater, more preferably 10 or greater, and further preferably 15 or greater. When the number of repetitions n is within the range mentioned above, the post-development resolution can be improved. On the other hand, the number of repetitions n is preferably 1,000 or less, more preferably 500 or less, and further preferably 100 or less. When the number of repetitions n is within the range mentioned above, the leveling property at the time of coating application and the pattern workability with an alkaline developer can be improved.

The weight-average molecular weight (hereinafter, “Mw”) of one or more selected from the (A1) polyimide, the (A2) polyimide precursor, the (A3) polybenzoxazole, and the (A4) polybenzoxazole precursor, in terms of polystyrene measured by gel permeation chromatography (hereinafter, “GPC”), is preferably 1,000 or greater, more preferably 3,000 or greater, and further preferably 5,000 or greater. When the Mw thereof is within the range mentioned above, the post-development resolution can be improved. On the other hand, the Mw thereof is preferably 500,000 or less, more preferably 300,000 or less, and further preferably 100,000 or less. When the Mw thereof is within the range mentioned above, the leveling property at the time of coating application and the pattern workability with an alkaline developer can be improved.

Furthermore, the number-average molecular weight (hereinafter, “Mn”) is preferably 1,000 or greater, more preferably 3,000 or greater, and further preferably 5,000 or greater. When the Mn thereof is within the range mentioned above, the post-development resolution can be improved. On the other hand, the Mn thereof is preferably 500,000 or less, more preferably 300,000 or less, and further preferably 100,000 or less. When the Mn thereof is within the range mentioned above, the leveling property at the time of coating application and the pattern workability with an alkaline developer can be improved.

The Mw and Mn of the (A1) polyimide, the (A3) polybenzoxazole, the (A2) polyimide precursor, or the (A4) polybenzoxazole precursor can be easily measured as values in terms of polystyrene by GPC, a light scattering method, an X-ray small angle scattering method, or the like. The number of repetitions n of the structural unit in the (A1) polyimide, the (A3) polybenzoxazole, the (A2) polyimide precursor, or the (A4) polybenzoxazole precursor can be determined as n=Mw/M where M is the molecular weight of the structural unit and Mw is the weight-average molecular weight of the resin.

The alkali dissolution speed of the one or more selected from the (A1) polyimide, the (A2) polyimide precursor, the (A3) polybenzoxazole, and the (A4) polybenzoxazole precursor is preferably 50 nm/min or greater, more preferably 70 nm/min or greater, and further preferably 100 nm/min or greater. When the alkali dissolution speed thereof is within the range mentioned above, the post-development resolution can be improved. On the other hand, the alkali dissolution speed is preferably 12,000 nm/min or less, more preferably 10,000 nm/min or less, and further preferably 8,000 nm/min or less. When the alkali dissolution speed is within the range mentioned above, the film reduction at the time of alkaline development can be inhibited.

The alkali dissolution speed mentioned herein refers to a film thickness reduction value obtained by applying a solution obtained by dissolving the resin in γ-butyrolactone onto an Si wafer, performing prebake at 120° C. for 4 minutes to form a pre-baked film having a film thickness of 10 m±0.5 m, developing the pre-baked film with a 2.38 mass % tetramethylammonium hydroxide aqueous solution at 23±1° C. for 60 seconds, and then rinsing the film with water for 30 seconds.

<Synthesis Method for (A1) Polyimide, (A3) Polybenzoxazole, (A2) Polyimide Precursor or (A4) Polybenzoxazole Precursor>

The (A1) polyimide or the (A2) polyimide precursor can be synthesized by a known method. For example, a method in which tetracarboxylic dianhydride and diamine (partially replaced with monoamine that is an end-capping agent) are reacted in a polar solvent, such as N-methyl-2-pyrrolidone at 80 to 200° C. or a method in which tetracarboxylic dianhydride (partially replaced with dicarboxylic anhydride, monocarboxylic acid, monocarboxylic acid chloride, or monocarboxylic acid active ester that is an end-capping agent) and diamine are reacted at 80 to 200° C. can be cited. In addition, a method in which the (A2) polyimide precursor is synthesized by, for example, carrying out the same method at 0 to 80° C., and the resulting (A2) polyimide precursor is completely imidized using a known imidation reaction method, a method in which an imidation reaction is stopped on the way and an imide bond is partially introduced, a method in which an imide bond is partially introduced by mixing completely imidized (A1) polyimide with the (A2) polyimide precursor, or the like can be cited.

The (A3) polybenzoxazole or the (A4) polybenzoxazole precursor can be synthesized by a known method. For example, a method in which dicarboxylic acid active diester and a bisaminophenol compound (partly replaced with monoamine that is an end-capping agent) are reacted in a polar solvent, such as N-methyl-2-pyrrolidone, at 80 to 250° C., a method in which dicarboxylic acid active diester (partly replaced with dicarboxylic anhydride, monocarboxylic acid, monocarboxylic acid chloride, or monocarboxylic acid active ester that is an end-capping agent) and a bisaminophenol compound are reacted at 80 to 250° C., or the like can be cited. In addition, a method in which the (A4) polybenzoxazole precursor is synthesized by, for example, carrying out the same method at 0 to 80° C., and the resulting (A2-2) polybenzoxazole is completely converted into oxazole using a known oxazolation reaction method, a method in which an oxazolation reaction is stopped on the way and an oxazole structure is partially introduced, a method in which an oxazole structure is partially introduced by mixing the (A3) polybenzoxazole completely converted into oxazole with the (A4) polybenzoxazole precursor, or the like can be cited.

The one or more selected from the (A1) polyimide, the (A2) polyimide precursor, the (A3) polybenzoxazole, and the (A4) polybenzoxazole precursor are preferably those obtained by, after end of polymerization reaction, carrying out precipitation in a poor solvent with respect to the one or more selected from the (A1) polyimide, the (A2) polyimide precursor, the (A3) polybenzoxazole, and the (A4) polybenzoxazole precursor, such as methanol or water, and then washing and drying the precipitate. By performing a re-precipitation process, a low-molecular weight component or the like can be removed, so that the mechanical characteristic of the cured film will considerably improve.

A concrete method for synthesizing the (A1) polyimide, the (A3) polybenzoxazole, the (A2) polyimide precursor, or the (A4) polybenzoxazole precursor will be described. First, diamine or the like or a bisaminophenol compound or the like are dissolved in a reaction solvent. Into this solution, a substantially equimolar amount of carboxylic anhydride or the like is gradually added. Using a mechanical stirrer, the mixture solution is agitated for preferably 0.5 to 50 hours and more preferably 2 to 24 hours at a temperature of preferably 0 to 200° C. and more preferably 40 to 150° C. In the case where an end-capping agent is used, addition of the carboxylic anhydride or the like is followed by agitation at a predetermined temperature for a predetermined time, which is followed by gradual addition of the end-capping agent and agitation.

It suffices that the reaction solvent for use in the polymerization reaction can dissolve diamines or the like or bisaminophenol compounds or the like and carboxylic anhydrides or the like that are raw materials, and the reaction solvent is preferably a polar solvent. As the reaction solvent, for example, amides, such as N,N-dimethylformamide, N,N-dimethylacetamide, or N-methyl-2-pyrrolidone, cyclic esters, such as γ-butyrolactone, γ-valerolactone, δ-valerolactone, γ-caprolactone, ε-caprolactone, or α-methyl-γ-butyrolactone, carbonates, such as ethylene carbonate or propylene carbonate, glycols, such as triethylene glycol, phenols, such as m-cresol or p-cresol, and other solvents, such as acetophenone, 1,3-dimethyl-2-imidazolidinone, sulfolane, or dimethyl sulfoxide, can be cited. The amount of the reaction solvent is preferably 100 to 1900 mass parts in the case where the total amount of the diamines or the like or the bisaminophenol compounds or the like and the carboxylic anhydride or the like is assumed to be 100 mass parts, and the amount of the reaction solvent is more preferably 150 to 950 mass parts.

The imide ring closure ratio (imide conversion ratio) of the (A1) polyimide or the (A2) polyimide precursor can be easily determined, for example, by the following method. First, an infrared absorption spectrum of the resin is measured, and the presence of absorption peaks (near 1780 cm⁻¹ and near 1377 cm⁻¹) of imide bonds resulting from the polyimide structure is checked. Next, the resin is thermoset at 350° C. for 1 hour, and then the infrared absorption spectrum is measured. By comparing the peak strengths near 1780 cm⁻¹ or near 1377 cm⁻¹ before and after the thermosetting, the imide bond content in the resin prior to the thermosetting can be calculated and therefore the imide conversion ratio can be determined.

The oxazole ring closure ratio (oxazole conversion ratio) of the (A3) polybenzoxazole or the (A4) polybenzoxazole precursor can be easily determined by, for example, the following method. First, an infrared absorption spectrum of the resin is measured, and the presence of absorption peaks (near 1574 cm⁻¹ and near 1557 cm⁻¹) of oxazole bonds resulting from a polybenzoxazole structure is checked. Next, the resin is thermoset at 350° C. for 1 hour, and then the infrared absorption spectrum is measured. By comparing the peak strengths near 1574 cm⁻¹ or near 1557 cm⁻¹ before and after the thermosetting, the oxazole bond content in the resin prior to the thermosetting can be calculated and therefore the oxazole conversion ratio can be determined.

<(B) Dispersant Having Amine Value Exceeding 0>

The negative photosensitive resin composition of the present invention contains a (B) dispersant having an amine value exceeding 0. The (B) dispersant having an amine value exceeding 0 is a dispersant in which a value calculated by using an automatic potentiometric titrator (AT-510; made by Kyoto Electronics Manufacturing Co., Ltd.) and calculated using a 0.1 mol/L HCl aqueous solution as a titration reagent and using THF as a titration solvent by a potentiometric titration method, on the basis of “Article 7: Potentiometric titration method (acid value)” of “JIS K2501:2003”, and the calculated value (mgKOH/g) exceeds 0.

A surface affinity group that interacts with the surface of the (C) benzofuranone based organic pigment having an amide structure and a compound having a dispersion stabilizing structure that improves the dispersion stability of the (C) benzofuranone based organic pigment having an amide structure are preferable. As the dispersion stabilizing structure of the (B) dispersant having an amine value exceeding 0, a polymer chain and/or a substituent that has electrostatic charge, or the like can be cited.

Further, the negative photosensitive resin composition of the present invention preferably contains a (B1) dispersant containing a repeating unit represented by general formulas (2) and (3) (hereinafter also referred to as “(B1) dispersant”).

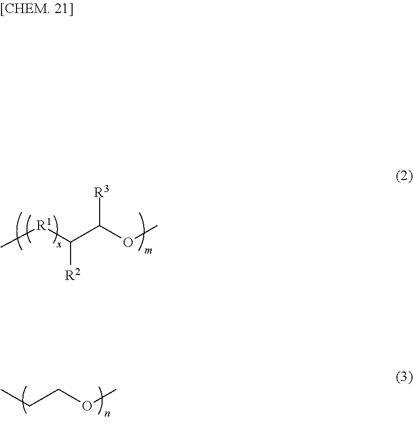

(In general formula (2), R¹ represents an alkyl group. R² and R³, which may be the same or different, each represent hydrogen, an alkyl group, or a hydroxyl group. x is an integer in the range of 0 to 20. However, when x is 0, at least one of R² and R³ is an alkyl group. m is an integer in the range of 1 to 100. In general formula (3), n is an integer in the range of 1 to 100.)

The (B1) dispersant preferably has a tertiary amino group. When it is tertiary, it is preferable because further dispersion stabilization is achieved with respect to the aftermentioned (C) benzofuranone based organic pigment having an amide structure.

Further, the (B1) dispersant preferably has a hydroxyl group. When the (B1) dispersant has the hydroxyl group, alkali developability can be imparted. When the repeating units represented by general formulas (2) and (3) are included, the alkali developability is further improved, which is preferable.

When x in general formula (2) is 0, an oxypropylene skeleton is provided, which is preferable because it is easy to synthesize. m in general formula (2) is an integer in the range of 10 to 50, and n in general formula (3) is an integer in the range of 10 to 50, whereby compatibility with the (A) alkali-soluble resin increases, so that the dispersion stability is further improved, which is preferable.

The (B) dispersant having an amine value exceeding 0 may be used alone or in combination of two or more, and it is preferable that the (B) dispersant having an amine value exceeding 0 contain at least one or more of a (B2) dispersant that is an acrylic block copolymer having an amine value of 15 to 60 mgKOH/g (hereinafter also referred to as “(B2) dispersant”) and a (B3) dispersant having a urethane bond (hereinafter also referred to as “(B3) dispersant”). Although the negative photosensitive resin composition is generally used by mixing a dispersion liquid and a diluent, the ratio varies depending on a required optical density value. Here, the dispersion liquid is a liquid containing at least a (A) dispersant having an amine value, the (C) benzofuranone based organic pigment having an amide structure, and a solvent, and the diluent is a liquid prepared by mixing the (A) alkali-soluble resin, a (D) radical polymerizable compound, a (E) photoinitiator, a solvent, a chain transfer agent, a surfactant, and the like.

In order to obtain a high optical density, it is necessary to increase a use amount of the (C) benzofuranone based organic pigment having an amide structure. In accordance therewith, since the use ratio of the dispersion liquid to the diluent becomes high, only by using the (A) dispersant having an amine value, the alkali dissolution speed tends to increase due to an increase in the amount of the dispersant used. Thus, at least one or more of the (B2) dispersant that is an acrylic block copolymer having an amine value of 15 mgKOH/g or more and the (B3) dispersant having a urethane bond is contained in the dispersion liquid or the diluent, whereby hydrophobicity is imparted by an acrylic block structure and an urethane structure, and it is possible to suppress the alkali dissolution speed, that is, to control the development speed while maintaining the dispersion stability.

In the (B2) dispersant, if the amine value is 60 mgKOH/g or less, it is possible to suppress reduction in compatibility with the (A) alkali-soluble resin, the (D) radical polymerizable compound, the (E) photoinitiator, and the solvent due to high polarity of the dispersant, and thus it is preferable. When the amine value is within the range of 20 to 30 mgKOH/g, the compatibility with the (A) alkali-soluble resin, the (D) radical polymerizable compound, the (E) photoinitiator, and the solvent is the best, and thus it is preferable.

Although the (B3) dispersant is not particularly limited as long as it has a urethane bond, if the amine value is 10 mgKOH/g or more, it is possible to achieve both the dispersion stability and the compatibility with the (A) alkali-soluble resin, the (D) radical polymerizable compound, the (E) photoinitiator, and the solvent, and thus it is preferable.

It is preferable that the total amount of the (B2) dispersant and the (B3) dispersant be within the range of 10 to 100 mass parts based on 100 mass parts of the (B1) dispersant. When the total amount of the (B2) dispersant and the (B3) dispersant is 10 mass parts or more, it is preferable because the alkali developing rate can be controlled while maintaining high dispersibility. If the total amount of the (B2) dispersant and the (B3) dispersant is 100 mass parts or less based on 100 mass parts of the (B1) dispersant, it is possible to suppress reduction in compatibility with the (A) alkali-soluble resin, the (D) radical polymerizable compound, the (E) photoinitiator, and the solvent while maintaining high dispersibility, and thus it is preferable.

When only the (B2) dispersant is contained, it is preferable that the (B2) dispersant be within the range of 10 to 100 mass parts. When only the (B3) dispersant is contained, it is preferable that the (B3) dispersant be within the range of 10 to 100 mass parts.

As commercially available dispersants having an acrylic block structure, “EFKA” (registered trademark) 4300, 4310 of the same, 4320 of the same (all of which are made by BASF) and the like can be cited; however, the dispersants are not limited thereto.

Further, as described later, in a case where the (C) benzofuranone based organic pigment having an amide structure is a compound represented by the following general formula (1), when m in general formula (1) is within the range of 10 to 30, n in general formula (2) is within the range of 5 to 15, and m≥n, a balance between hydrophobicity and hydrophilicity in general formula (1) is improved; therefore, both high compatibility with the (A) alkali-soluble resin and high dispersion stability can be achieved, and the alkali developing rate can also be controlled, which is preferable. When m is 10 or more, or n is 5 or more, the molecular weight increases, so that it is preferable because dispersion stabilization due to steric hindrance of the (B1) dispersant becomes possible. Further, when m is 30 or less, or n is 15 or less, dispersion instabilization due to excessive increase in molecular weight can be suppressed, and the alkali developing rate can be controlled while maintaining the balance between hydrophilicity and hydrophobicity, which is preferable. If a relationship of m≥n is satisfied, it is preferable because high dispersion stability can be obtained while maintaining compatibility with the (A) alkali-soluble resin.

In the (B) dispersant having an amine value exceeding 0, a dispersant other than those described above may be included, and as the (B) dispersant having an amine value exceeding 0 and having a surface affinity group, it may be preferable that an amino group and/or an acidic group as a surface affinity group have a structure in which a salt is formed with an acid and/or a base.

As the (B) dispersant having an amine value exceeding 0, in addition to the (B1) dispersant, the (B2) dispersant, and the (B3) dispersant, for example, “DP1SPERBYK” (registered trademark)-108, ditto-109, ditto-160, ditto-161, ditto-162, ditto-163, ditto-164, ditto-166, ditto-167, ditto-168, ditto-182, ditto-184, ditto-185, ditto-2000, ditto-2008, ditto-2009, ditto-2022, ditto-2050, ditto-2055, ditto-2150, ditto-2155, ditto-2163, ditto-2164 or ditto-2061, “BYK” (registered trademark)-9075, ditto-9076, ditto-9077, ditto-LP-N6919, ditto-LP-N21116 or ditto-LP-N21324 (which are all made by BYK Japan KK), “EFKA” (registered trademark) 4015, ditto 4020, ditto 4046, ditto 4047, ditto 4050, ditto 4055, ditto 4060, ditto 4080, ditto 4300, ditto 4330, ditto 4340, ditto 4400, ditto 4401, ditto 4402, ditto 4403 or ditto 4800 (which are all made by BASF), “AJISPER” (registered trademark) PB711 (made by Ajinomoto Fine-Techno Co., Inc.), or “SOLSPERSE” (registered trademark) 13240, ditto 13940, ditto 20000, ditto 71000 or ditto 76500 (which are all made by Lubrizol) can be cited.

In the (B) dispersant having an amine value exceeding 0, as the dispersant that also has an acid value, for example, “ANTI-TERRA” (registered trademark)-U100 or ditto-204, “DP1SPERBYK” (registered trademark)-106, ditto-140, ditto-142, ditto-145, ditto-180, ditto-2001, ditto-2013, ditto-2020, ditto-2025, ditto-187 or ditto-191, “BYK” (registered trademark)-9076 (made by BYK Japan KK, “AJISPER” (registered trademark) PB821, ditto PB880, or ditto PB881 (which are all made by Ajinomoto Fine-Techno Co., Inc.), or “SOLSPERSE” (registered trademark) 9000, ditto 11200, ditto 13650, ditto 24000, ditto 32000, ditto 32500, ditto 32500, ditto 32600, ditto 33000, ditto 34750, ditto 35100, ditto 35200, ditto 37500, ditto 39000, ditto 56000, or ditto 76500 (which are all made by Lubrizol) can be cited.

The amine value of the (B) dispersant having an amine value exceeding 0 is preferably 5 mgKOH/g or more, more preferably 8 mgKOH/g or more, and further preferably 10 mgKOH/g or more. When the amine value is within the range mentioned above, the dispersion stability of the (C) benzofuranone based organic pigment having an amide structure can be improved. On the other hand, the amine value is preferably 150 mgKOH/g or less, more preferably 120 mgKOH/g or less, and further preferably 100 mgKOH/g or less. When the amine value thereof is within the range mentioned above, the storage stability of the resin composition can be improved.

The amine value mentioned herein refers to a mass of potassium hydroxide equivalent to that of an acid that reacts with 1 g of the (B) dispersant having an amine value exceeding 0, and the unit of the amine value is mgKOH/g. The amine value can be determined by neutralizing 1 g of the (B) dispersant having an amine value exceeding 0 with an acid and then performing titration with a potassium hydroxide aqueous solution. The acid value of the (B) dispersant having an amine value exceeding 0 is preferably 5 mgKOH/g or greater, more preferably 8 mgKOH/g or greater, and further preferably 10 mgKOH or greater. When the acid value is within the range mentioned above, the dispersion stability of the (C) benzofuranone based organic pigment having an amide structure can be improved. On the other hand, the acid value is preferably 200mgKOH/g or less, more preferably 170 mgKOH/g or less, and further preferably 150 mgKOH/g or less. When the acid value thereof is within the range mentioned above, the storage stability of the resin composition can be improved.

The acid value mentioned herein refers to a mass of potassium hydroxide that reacts with 1 g of the (B) dispersant having an amine value exceeding 0, and the unit of the acid value is mgKOH/g. The acid value can be obtained by subjecting titration to 1 g of the (B) dispersant having an amine value exceeding 0 with a potassium hydroxide aqueous solution.

As the (B) dispersant having an amine value exceeding 0 and having a polymer chain, acrylic resin based dispersants, polyoxyalkylene ether based dispersants, polyester based dispersants, polyurethane based dispersants, polyol based dispersants, polyethylene imine based dispersants, or polyallylamine based dispersants can be cited. From the viewpoint of the pattern workability with an alkaline developer, it is preferable that the (B) dispersant having an amine value exceeding 0 be an acrylic resin based dispersant, a polyoxyalkylene ether based dispersant, a polyester based dispersant, a polyurethane based dispersant, or a polyol based dispersant.

The content ratio of the (B) dispersant having an amine value exceeding 0 in the negative photosensitive resin composition of the present invention is preferably 1 mass % or more, more preferably 5 mass % or more, and further preferably 10 mass % or more when the total of the aftermentioned (C) benzofuranone based organic pigment having an amide structure and the (B) dispersant having an amine value exceeding 0 is 100 mass %. When the content ratio thereof is within the range mentioned above, the dispersion stability of the (C) benzofuranone based organic pigment having an amide structure can be improved, and the post-development resolution can be improved. On the other hand, the content ratio of the (B) dispersant having an amine value exceeding 0 is preferably 60 mass % or less, more preferably 55 mass % or less, and further preferably 50 mass % or less. When the content ratio thereof is within the range mentioned above, the heat resistance of the cured film can be improved.

<(C) Benzofuranone Based Organic Pigment Having Amide Structure>

The negative photosensitive resin composition of the present invention further contains the (C) benzofuranone based organic pigment having an amide structure. The (C) benzofuranone based organic pigment having an amide structure is a compound that absorbs light having a specific wavelength, and particularly refers to a compound that is colored by absorbing light having a visible light wavelength (380 to 780 nm).

Due to containing of the (C) benzofuranone based organic pigment having an amide structure, dispersion stabilization is achieved by interaction with a dispersant, so that the film obtained from the resin composition can be colored, and it is possible to provide a colorability that causes light penetrating the film of the resin composition or light reflecting from the film of the resin composition to produce a desired color. Furthermore, it is possible to provide a light blocking property that eliminates the light of a wavelength that (C) benzofuranone based organic pigment having an amide structure absorbs from light that penetrates the film of the resin composition or light that reflects from the film of the resin composition.

As the (C) benzofuranone based organic pigment having an amide structure, compounds that absorb light of a visible ray wavelength and produce a color of white, red, orange, yellow, green, blue, or violet can be cited. By combining two or more colors of these pigments, it is possible to improve the color adjustment property that causes light that penetrates the film of a desired resin composition of the resin composition or light that reflects from the film of the resin composition to have a desired color coordinate. From the viewpoint of light blocking property, an organic pigment having an amide structure is preferable as long as the solid content ratio of the negative photosensitive resin composition of the present invention is 10% or more, because external light can be blocked sufficiently. When the solid content ratio is 70% or less, external light can be sufficiently blocked, and a pattern of a cured film of the negative photosensitive resin composition can be formed, which is preferable. The solid content ratio refers to a ratio in the total solid content excluding the solvent in the negative photosensitive resin composition.

As the negative photosensitive resin composition of the present invention, the (C) benzofuranone based organic pigment having an amide structure is preferably a compound represented by the following general formula (1), and since the film of the resin composition turns black by containing this compound, it is possible to improve the light blocking property that eliminates light that penetrates the film of the resin composition or light that reflects from the film of the resin composition. Therefore, the resin composition is suitable for light-blocking films, such as a black matrix of a color filter or a black column spacer of a liquid crystal display, and for uses in which increased contrast achieved by inhibiting external light reflection is required.

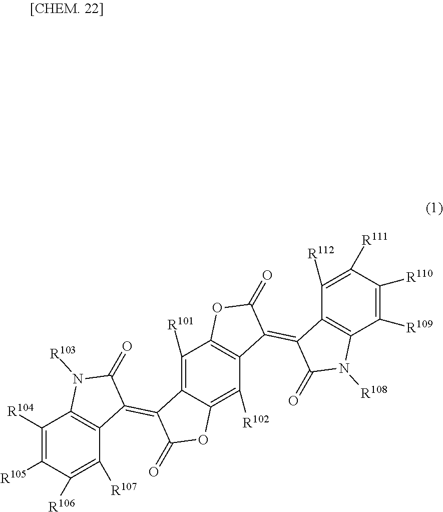

(In general formula (1), R¹⁰¹ and R¹⁰² each independently represent hydrogen, a halogen atom, an alkyl group having a carbon number of 1 to 10, or an alkyl group having a carbon number of 1 to 10 and having 1 to 20 fluorine atoms. R¹⁰⁴ to R¹⁰⁷ and R¹⁰⁹ to R¹² each independently represent hydrogen, a halogen atom, an alkyl group having a carbon number of 1 to 10, a carboxy group, a sulfonic acid group, an amino group or a nitro group. R¹⁰³ and R¹⁰⁸ each independently represent hydrogen, an alkyl group having a carbon number of 1 to 10, or an aryl group having a carbon number of 6 to 15.)

Due to containing of the compound represented by general formula (1) in the (C) benzofuranone based organic pigment having an amide structure, the film of the resin composition turns black and is excellent in hiding power, so that the light blocking property of the film of the resin composition can be improved. Furthermore, since it is an organic substance, the transmission spectrum or absorption spectrum of the film of the resin composition can be adjusted by achieving transmission or blockage of light of a desired specific wavelength, or the like, through chemical structural change or functional transformation, so that the color adjustment property can be improved. Particularly, because the transmittance at a wavelength in a near-infrared area (e.g., 700 nm or greater) can be improved, the film of the resin composition containing the (C) benzofuranone based organic pigment having an amide structure has light blocking property and is suitable for uses in which light of a wavelength in a near-infrared area is utilized.

As the compound represented by general formula (1), for example, “IRGAPHOR” (registered trademark) BLACK S0100CF (made by BASF), a black pigment mentioned in International Publication WO 2010-081624, or a black pigment mentioned in International Publication WO 2010-081756 can be cited.

The content ratio of the compound represented by general formula (1) in the solid content of the negative photosensitive resin composition of the present invention, excluding the solvent, is preferably 5 mass % or greater, more preferably 10 mass % or greater, and further preferably 15 mass % or greater. When the content ratio thereof is within the range mentioned above, the light blocking property and the color adjustment property can be improved. On the other hand, the content ratio thereof is preferably 70 mass % or less, more preferably 65 mass % or less, and further preferably 60 mass % or less. When the content ratio thereof is within the range mentioned above, the sensitivity at the time of exposure can be improved.

A (C1) perylene based black pigment may be contained in the (C) benzofuranone based organic pigment having an amide structure.

<(C1) Perylene-Based Black Pigment>

The (C1) perylene based black pigment refers to a compound that has in its molecule a perylene structure and that produces black color by absorbing light of visible ray wavelengths.

Due to containing of the (C1) perylene based black pigment, the film of the resin composition turns black and is excellent in hiding power, so that the light blocking property of the film of the resin composition can be improved. Furthermore, since it is an organic substance, the transmission spectrum or absorption spectrum of the film of the resin composition can be adjusted by achieving transmission or blockage of light of a desired specific wavelength, or the like, through chemical structural change or functional transformation, so that the color adjustment property can be improved. Particularly, because the transmittance at a wavelength in a near-infrared area (e.g., 700 nm or greater) can be improved, the film of the resin composition containing the (C1) perylene based black pigment has light blocking property and is suitable for uses in which light of a wavelength in a near-infrared area is utilized.

As the (C1) perylene based black pigment, a perylene compound represented by general formula (71) or (72) is preferable.

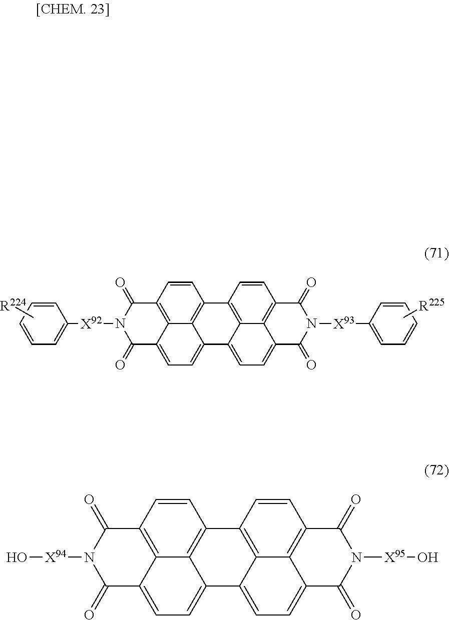

(In general formulas (71) and (72), X⁹², X⁹³, X⁹⁴ and X⁹⁵ each independently represent an alkylene chain having a carbon number of 1 to 10. R²²⁴ and R²²⁵ each independently represent hydrogen, a hydroxy group, an alkoxy group having a carbon number of 1 to 6, and an acyl group having a carbon number of 2 to 6.)

In general formulas (71) and (72), it is preferable that X⁹², X⁹³, X⁹⁴ and X⁹⁵ each independently be an alkylene chain having a carbon number of 1 to 6. Furthermore, it is preferable that R²²⁴ and R²²⁵ each independently be hydrogen, a hydroxy group, an alkoxy group having a carbon number of 1 to 4, or an acyl group having a carbon number of 2 to 4. The alkylene chains, the alkoxy group, and the acyl groups mentioned above may be either an unsubstituted product or a substitution product.

As the (C1) perylene based black pigment, for example, Pigment Black 21, 30, 31, 32, 33, or 34 can be cited (the numerical values are each a C.I. number).

Besides what have been mentioned above, “PALIOGEN” (registered trademark) BLACK S0084, K0084 of the same, L0086 of the same, K0086 of the same, EH0788 of the same, or FK4281 of the same (which are all made by BASF) can be cited.

The content ratio of the (C3) perylene based black pigment in the solid content of the negative photosensitive resin composition of the present invention, excluding the solvent, is preferably 5 mass % or greater, more preferably 10 mass % or greater, and further preferably 15 mass % or greater. When the content ratio thereof is within the range mentioned above, the light blocking property and the color adjustment property can be improved. On the other hand, the content ratio thereof is preferably 70 mass % or less, more preferably 65 mass % or less, and further preferably 60 mass % or less. When the content ratio thereof is within the range mentioned above, the sensitivity at the time of exposure can be improved.

In addition to the (C1) perylene based black pigment mentioned above, one or more selected from a (C2) dye, a (C3) black dye, a (C4) mixture of two or more color dyes, and a (C5) dye other than black, (C6) carbon black, a (C7) black inorganic pigment, an (C8) organic pigment other than black, and an (C9) inorganic pigment other than black, which will be described later, may be contained.

<(C2) Dye, (C3) Black Dye, (C4) Mixture of Two or More Color Dyes, (C5) Dye Other than Black>

As the negative photosensitive resin composition of the present invention, it is preferable that the (C) benzofuranone based organic pigment having an amide structure contain the (C2) dye.

The (C2) dye refers to a compound that colors an object because a substituent, such as an ionic group or a hydroxy group, in the (C2) dye undergoes chemical adsorption, strong interaction, or the like with respect to a surface structure of the object, and, generally, is soluble to solvents. Furthermore, because, in the coloration by the (C2) dye, individual molecules thereof are adsorbed to an object, the power of coloration is high and the color development efficiency is high.

Due to containing of the (C2) dye, coloration to a color that is excellent in coloration power can be achieved, so that the colorability or color adjustment property of the film of the resin composition can be improved.

As the (C2) dye, for example, direct dyes, reactivity dyes, sulfur dyes, vat dyes, sulfur dyes, acidic dyes, metal-containing dyes, metal-containing acidic dyes, basic dyes, mordant dyes, acidic mordant dye, disperse dyes, cation dyes, or fluorescent whitening dyes can be cited.

As the (C2) dye, anthraquinone based dyes, azo based dyes, azine based dyes, phthalocyanine based dyes, methine based dyes, oxazine based dyes, quinoline based dyes, indigo based dyes, indigoid based dyes, carbonium based dyes, threne based dyes, perinone based dyes, perylene based dyes, triaryl methane based dyes, or xanthene based dyes can be cited. It is preferable, from the viewpoint of the solubility with respect to the solvent described later and the heat resistance, that the (C2) dye be an anthraquinone based dye, an azo based dye, an azine based dye, a methine based dye, a triaryl methane based dye, or a xanthene based dye.

As for the negative photosensitive resin composition of the present invention, it is preferable that the (C2) dye contain a (C3) black dye, a (C4) mixture of two or more color dyes, and a (C5) dye other than black which will be described later.

The content ratio of the (C2) dye in the solid content of the negative photosensitive resin composition of the present invention, excluding the solvent, is preferably 0.01 mass % or greater, more preferably 0.05 mass % or greater, and further preferably 0.10 mass % or greater. When the content ratio is within the range mentioned above, the colorability or the color adjustment property can be improved. On the other hand, the content ratio thereof is preferably 50 mass % or less, more preferably 45 mass % or less, and further preferably 40 mass % or less. When the content ratio thereof is within the range mentioned above, the heat resistance of the cured film can be improved.

As for the negative photosensitive resin composition of the present invention, it is preferable that the (C2) dye contain the (C3) black dye, the (C4) mixture of two or more color dyes, and the (C5) dye other than black.

The (C3) black dye refers to a dye that produces black color by absorbing light of visible ray wavelengths.

Due to containing of the (C3) black dye, the film of the resin composition turns black and is excellent in colorability, so that the light blocking property of the film of the resin composition can be improved.

As the (C3) black dye, for example, Solvent Black 3, 5, 7, 22, 27, 29, or 34, Mordant Black 1, 11, or 17, Acid Black 2 or 52, or Direct Black 19 or 154, can be used (the numerical values are each a C.I. number).

Besides what have been mentioned above, “NUBIAN” (registered trademark) BLACK TH-807, ditto TH-827, ditto TH-827 K, ditto TN-870, ditto PC-0855, ditto PC-5856, ditto PC-5857, ditto PC-5877, ditto PC-8550, ditto TN-873, ditto TN-877 or ditto AH-807, OIL BLACK HBB or ditto 860, “VALIFAST” (registered trademark) BLACK 1807, ditto 3904, ditto 3810, ditto 3820, ditto 3830, ditto 3840, ditto 3866 or ditto 3870, or WATER BLACK 100-L, ditto 191-L, ditto 256-L, ditto R-510 or ditto 187-LM (which are all made by Orient Chemical Industries Co., Ltd.) can be cited.

The content ratio of the (C3) black dye in the solid content of the negative photosensitive resin composition of the present invention, excluding the solvent, is preferably 0.01 mass % or greater, more preferably 0.05 mass % or greater, and further preferably 0.10 mass % or greater. When the content ratio thereof is within the range mentioned above, the light blocking property can be improved. On the other hand, the content ratio thereof is preferably 50 mass % or less, more preferably 45 mass % or less, and further preferably 40 mass % or less. When the content ratio thereof is within the range mentioned above, the sensitivity at the time of exposure can be improved.

The (C4) mixture of two or more color dyes refers to a dye mixture that produces black color in a pseudo manner due to combining two or more color dyes selected from dyes of white, red, orange, yellow, green, blue, or violet.

Due to containing of the (C4) mixture of two or more color dyes, the film of the resin composition turns black and is excellent in colorability, so that the light blocking property of the film of the resin composition can be improved. Furthermore, since two or more color dyes are mixed, the transmission spectrum or absorption spectrum of the film of the resin composition can be adjusted by achieving transmission or blockage of light of a desired specific wavelength, or the like, so that the color adjustment property can be improved.

As the dye that produces red color, for example, Direct Red 2, 4, 9, 23, 26, 28, 31, 39, 62, 63, 72, 75, 76, 79, 80, 81, 83, 84, 89, 92, 95, 111, 173, 184, 207, 211, 212, 214, 218, 221, 223, 224, 225, 226, 227, 232, 233, 240, 241, 242, 243 or 247; Acid Red 35, 42, 51, 52, 57, 62, 80, 82, 111, 114, 118, 119, 127, 128, 131, 143, 145, 151, 154, 157, 158, 211, 249, 254, 257, 261, 263, 266, 289, 299, 301, 305, 319, 336, 337, 361, 396 or 397; Reactive Red 3, 13, 17, 19, 21, 22, 23, 24, 29, 35, 37, 40, 41, 43, 45, 49 or 55; or Basic Red 12, 13, 14, 15, 18, 22, 23, 24, 25, 27, 29, 35, 36, 38, 39, 45 or 46 can be cited (the numerical values are each a C.I. number).

As the dye that produces orange color, for example, Basic Orange 21 or 23 can be cited (the numerical values are each a C.I. number).

As the dye that produces yellow color, for example, Direct Yellow 8, 9, 11, 12, 27, 28, 29, 33, 35, 39, 41, 44, 50, 53, 58, 59, 68, 87, 93, 95, 96, 98, 100, 106, 108, 109, 110, 130, 142, 144, 161 or 163; Acid Yellow 17, 19, 23, 25, 39, 40, 42, 44, 49, 50, 61, 64, 76, 79, 110, 127, 135, 143, 151, 159, 169, 174, 190, 195, 196, 197, 199, 218, 219, 222 or 227; Reactive Yellow 2, 3, 13, 14, 15, 17, 18, 23, 24, 25, 26, 27, 29, 35, 37, 41 or 42; and Basic Yellow 1, 2, 4, 11, 13, 14, 15, 19, 21, 23, 24, 25, 28, 29, 32, 36, 39 or 40 can be cited (the numerical values are each a C.I. number).

As the dye that produces green color, for example, Acid Green 16 can be cited (the numerical values are each a C.I. number).

As the dye that produces blue color, for example, Acid Blue 9, 45, 80, 83, 90 or 185 can be cited (the numerical values are each a C.I. number).

As the dye that produces purple color, for example, Direct Violet 7, 9, 47, 48, 51, 66, 90, 93, 94, 95, 98, 100 or 101; Acid Violet 5, 9, 11, 34, 43, 47, 48, 51, 75, 90, 103 or 126; Reactive Violet 1, 3, 4, 5, 6, 7, 8, 9, 16, 17, 22, 23, 24, 26, 27, 33 or 34; or Basic Violet 1, 2, 3, 7, 10, 15, 16, 20, 21, 25, 27, 28, 35, 37, 39, 40 or 48 can be cited (the numerical values are each a C.I. number).

Besides what have been mentioned above, “SUMILAN” (registered trademark) dye and “LANYL dye” (registered trademark) (which are all made by Sumitomo Chemical Industry Company Limited); “ORASOL” (registered trademark) dye, “ORACET” (registered trademark) dye, “FILAMID” (registered trademark) dye and “IRGASPERSE” (registered trademark) dye (which are all made by Ciba Specialty Chemicals Co.); “ZAPON” (registered trademark) dye, “NEOZAPON” (registered trademark) dye, “NEPTUNE” (registered trademark) dye and “ACIDOL” (registered trademark) dye (which are all made by BASF); “KAYASET” (registered trademark) dye and “KAYAKALAN” (registered trademark) dye (which are all made by Nippon Kayaku Co., Ltd.); “VALIFAST” (registered trademark) COLORS dye and “NUBIAN” (registered trademark) COLORS dye (made by Orient Chemical Industries, Co., Ltd.); “SAVINYL” (registered trademark) dye, “SANDOPLAST” (registered trademark) dye, “POLYSYNTHREN” (registered trademark) dye and “LANASYN” (registered trademark) dye (which are all made by Clariant (Japan) K.K.); “AIZEN” (registered trademark) and “SPILON” (registered trademark) dye (made by Hodogaya Chemical Co., Ltd.); a functional dye (made by Yamada Chemical Co., Ltd.); and PLAST COLOR dye and OIL COLOR dye (which are all made by Arimoto Chemical Co., Ltd.) can be cited.

The content ratio of a (C4-3) mixture of two or more color dyes in the solid content of the negative photosensitive resin composition of the present invention, excluding the solvent, is preferably 0.01 mass % or greater, more preferably 0.05 mass % or greater, and further preferably 0.10 mass % or greater. When the content ratio thereof is within the range mentioned above, the light blocking property and the color adjustment property can be improved. On the other hand, the content ratio thereof is preferably 50 mass % or less, more preferably 45 mass % or less, and further preferably 40 mass % or less. When the content ratio thereof is within the range mentioned above, the sensitivity at the time of exposure can be improved.

The (C5) dye other than black refers to a dye that produces color of white, red, orange, yellow, green, blue, or violet, except black, by absorbing light of a visible ray wavelength.

Due to containing of the (C5) dye other than black, the film of the resin composition can be colored, so that it is possible to provide colorability or color adjustment property. Due to combining two or more colors of (C5) dyes other than black, the film of the resin composition can be adjusted in color to a desired color coordinate, so that the color adjustment property can be improved.

As the (C5) dye other than black, aforementioned dyes that produce color of white, red, orange, yellow, green, blue, or violet, except black, can be cited.

The content ratio of the (C4) dye other than black in the solid content of the negative photosensitive resin composition of the present invention, excluding the solvent, is preferably 0.01 mass % or greater, more preferably 0.05 mass % or greater, and further preferably 0.10 mass % or greater. When the content ratio is within the range mentioned above, the colorability or the color adjustment property can be improved. On the other hand, the content ratio thereof is preferably 50 mass % or less, more preferably 45 mass % or less, and further preferably 40 mass % or less. When the content ratio thereof is within the range mentioned above, the heat resistance of the cured film can be improved.

<(C6) Carbon Black>

As the carbon black, for example, channel black, furnace black, thermal black, acetylene black, and lamp black can be cited. From the viewpoint of light blocking property, channel black is preferable.

As the carbon black, carbon black subjected to surface treatment is preferable. The method for the surface treatment is preferably a surface treatment method in which an acidic group is introduced, a surface treatment method using a silane coupling agent or a coating method using a resin.

When a surface treatment by introducing an acidic group or a surface treatment using a silane coupling agent is carried out, the state of the surfaces of carbon black particles can be modified, and, for example, the particle surface of carbon black is acidified, hydrophilized or hydrophobized, resulting in the improvement in dispersion stability of the resin contained in the resin composition or by the aftermentioned (B) dispersant having an amine value exceeding 0.

As the acidic group introduced into carbon black by the surface treatment by introducing an acidic group, a substituent that exhibits an acidic property in the Bronsted theory can be cited. Specific examples of the acidic group include a carboxy group, a sulfonic acid group, and a phosphoric acid group.

The acidic group to be introduced into the carbon black may form a salt. As the cation that forms a salt in conjunction with the acidic group, various metal ions, cations of nitrogenated compounds, an arylammonium ion, an alkylammonium ion or an ammonium ion can be cited. From the viewpoint of the insulation property of the cured film, an arylammonium ion, an alkylammonium ion or an ammonium ion is preferable.

As the surface treatment method for introducing an acidic group into carbon black, for example, the following methods (1) to (5) can be cited.

(1) A method for introducing a sulfonic acid group into carbon black by a direct substitution technique using concentrated sulfuric acid, fuming sulfuric acid or chlorosulfonic acid or an indirect substitution technique using a sulfite salt or a bisulfite salt;

(2) a method in which an organic compound having an amino group and an acidic group is subjected to diazo coupling with carbon black;

(3) a method in which an organic compound having a halogen atom and an acidic group is reacted with carbon black having a hydroxy group by a Williamson ether synthesis;

(4) a method in which an organic compound having a halogenated carbonyl group and an acidic group that is protected by a protecting group is reacted with carbon black having a hydroxy group; and

(5) a method in which an organic compound having a halogenated carbonyl group and an acidic group that is protected by a protecting group is subjected to a Friedel-Crafts reaction with carbon black and the acidic group is then deprotected.

From the viewpoint of the easiness and safety of the acidic group introduction treatment, the method (2) is preferable. As the organic compound having an amino group and an acidic group to be used in the method (2), for example, an organic compound in which an amino group and an acidic group are bonded to an aromatic group is preferable. As the organic compound in which an amino group and an acidic group are bonded to an aromatic group, any known compound such as 4-aminobenzenesulfonic acid and 4-aminobenzoic acid can be used.

The molar number of the acidic group to be introduced into carbon black is preferably 1 mmol or more, more preferably 5 mmol or more, relative to 100 g of carbon black. When the molar number is within the range mentioned above, the dispersion stability of carbon black can be improved. On the other hand, the molar number is preferably 200 mmol or less, more preferably 150 mmol or less. When the molar number is within the range mentioned above, the dispersion stability of carbon black can be improved.

As the substituent to be introduced into carbon black by means of a surface treatment with a silane coupling agent capable of modifying the state of the surfaces of carbon black particles (wherein the silane coupling agent is hereinafter referred to as “surface-treating organosilane”), for example, an acidic group, a basic group, a hydrophilic group or a hydrophobic group can be cited. As the acidic group, the basic group, the hydrophilic group and the hydrophobic group, for example, an alkylsilyl group, an arylsilyl group, or hydroxy group, or an alkylsilyl group or arylsilyl group having a carboxy group or an amino group can be cited.

As the surface treatment method using the surface-treating organosilane, for example, a method in which the surface-treating organosilane and carbon black are mixed can be cited. If necessary, a reaction solvent, water or a catalyst may be added.

As the reaction solvent to be used in the surface treatment with the surface-treating organosilane, for example, those solvents which are same as the aftermentioned solvents can be cited. The amount of the reaction solvent to be added is preferably 10 to 1,000 mass parts relative to the total mass, i.e., 100 mass parts, of carbon black and the surface-treating organosilane. The amount of water to be added is preferably 0.5 to 2 mol relative to 1 mol of a hydrolyzable group.

The catalyst to be used in the surface treatment with the surface-treating organosilane is preferably an acid catalyst or a base catalyst. As the acid catalyst, for example, hydrochloric acid, nitric acid, sulfuric acid, hydrofluoric acid, phosphoric acid, acetic acid, trifluoroacetic acid, formic acid, a polycarboxylic acid or their anhydrides, or an ion exchange resin can be cited. As the base catalyst, for example, triethylamine, tri-n-propylamine, tri-n-butylamine, tri-n-pentylamine, tri-n-hexylamine, tri-n-heptylamine, tri-n-octylamine, diethylamine, triethanolamine, diethanolamine, sodium hydroxide, potassium hydroxide, an alkoxysilane having an amino group, or an ion exchange resin can be cited. The amount of the catalyst to be added is preferably 0.01 to 10 mass parts relative to 100 mass parts of carbon black and the surface-treating organosilane.

The temperature to be employed for the surface treatment with the surface-treating organosilane is preferably 20 to 250° C., preferably 40 to 200° C., and further preferably 60 to 180° C.

Any known compound may be used, such as methyltrimethoxysilane, methyltriethoxysilane, methyltri-n-butoxysilane, methyltrichlorosilane, methyltriacetoxysilane, ethyltrimethoxysilane, n-propyltrimethoxysilane, n-hexyltrimethoxysilane, n-decyltrimethoxysilane, phenyltrimethoxysilane, 4-hydroxyphenyltrimethoxysilane, 3-aminopropyltrimethoxysilane, 4-aminophenyltrimethoxysilane or 3-trimethoxysilylpropylsuccinic anhydride.

The content of the surface-treating organosilane is preferably 0.01 mass parts or more and more preferably 0.05 mass parts or more, relative to the total mass, i.e., 100 mass %, of carbon black and the surface-treating organosilane. When the content is within the range mentioned above, the dispersion stability of carbon black can be improved. On the other hand, the content is preferably 20 mass parts or less, and more preferably 15 mass parts or less. When the content is within the range mentioned above, the dispersion stability of carbon black can be improved.

As the carbon black, resin-coated carbon black is also preferable. When the carbon black is coated with a resin capable of coating carbon black (wherein the resin is hereinafter referred to as “a coating resin”), the surfaces of particles of the carbon black are coated with the coating resin, which has a poorly electrically conductive insulation property, to modify the state of the surfaces of the particles, and consequently the light blocking property and the insulation property of the cured film can be improved. Furthermore, because the leakage current or the like is reduced, the reliability of the resultant display and the like can also be improved. Thus, it is suitable for the case where the cured film is put to a use in which the insulating property is required, and the like cases.

As the coating resin, polyamide, polyamideimide, an epoxy resin, a novolac resin, a phenolic resin, a urea resin, a melamine resin, polyurethane, a diallyl phthalate resin, an alkylbenzene resin, polystyrene, polycarbonate, polybutylene terephthalate or modified polyphenylene oxide can be cited.

The content of the coating resin is preferably 0.1 mass parts or more, more preferably 0.5 mass parts or more, relative to the total weight, i.e., 100 mass %, of the carbon black and the coating resin. When the content thereof is within the range mentioned above, the light blocking property and insulating property of the cured film can be improved. On the other hand, the content is preferably 40 mass parts or less, and more preferably 30 mass parts or less. When the content thereof is within the range mentioned above, the light blocking property and insulating property of the cured film can be improved.

The content ratio of carbon black subjected to surface treatment in the solid content of the negative photosensitive resin composition of the present invention, excluding the solvent, is preferably 5 mass % or greater, more preferably 10 mass % or greater, and further preferably 15 mass % or greater. When the content ratio thereof is within the range mentioned above, the light blocking property and the color adjustment property can be improved. On the other hand, the content ratio thereof is preferably 70 mass % or less, more preferably 65 mass % or less, and further preferably 60 mass % or less. When the content ratio thereof is within the range mentioned above, the sensitivity at the time of exposure can be improved.

<(C7) Black Inorganic Pigment>

The (C7) black inorganic pigment refers to an inorganic pigment that produces black color by absorbing light of visible ray wavelengths.

Due to containing of the (C7) black inorganic pigment, the film of the resin composition turns black and is excellent in hiding power, so that the light blocking property of the film of the resin composition can be improved. Furthermore, since it is an inorganic substance and more excellent in heat resistance and weather resistance, the heat resistance and weather resistance of the film of the resin composition can be improved.

As the (C7) black inorganic pigment, for example, graphite, silver tin alloy, fine particles, oxides, composite oxides, sulfides, sulfate salts, nitrate salts, carbonate salts, nitrides, carbides, or oxynitrides of a metal, such as titanium, copper, iron, manganese, cobalt, chromium, nickel, zinc, calcium, or silver, can be cited. From the viewpoint of improvement of the light blocking property, the (C7) black inorganic pigment is preferably fine particles, oxides, composite oxides, sulfides, nitrides, carbides, or oxynitrides of titanium or silver, and more preferably nitrides or oxynitrides of titanium.

As the black organic pigment or the black inorganic pigment, for example, Pigment Black 1, 6, 7, 12, 20, 31, or 32 can be cited. (The numerical values are each a color index (hereinafter, “C.I.”) number.)

The content ratio of a (D1a-2) black inorganic pigment in the solid content of the negative photosensitive resin composition of the present invention, excluding the solvent, is preferably 5 mass % or greater, more preferably 10 mass % or greater, and further preferably 15 mass % or greater. When the content ratio thereof is within the range mentioned above, the light blocking property, the heat resistance, and the weather resistance can be improved. On the other hand, the content ratio thereof is preferably 70 mass % or less, more preferably 65 mass % or less, and further preferably 60 mass % or less. When the content ratio thereof is within the range mentioned above, the sensitivity at the time of exposure can be improved.

<(C8) Organic Pigment Other than Black, (C9) Inorganic Pigment Other than Black>

As the negative photosensitive resin composition of the present invention, in addition to (C) benzofuranone based organic pigment having an amide structure, the (C8) organic pigment other than black and the (C9) inorganic pigment other than black may be contained.

The (C8) organic pigment other than black refers to an organic pigment that produces color of white, red, orange, yellow, green, blue, or violet, except black, by absorbing light of visible ray wavelengths.

Due to containing of the (C9) organic pigment other than black, the film of the resin composition can be colored and can be provided with colorability or color adjustment property. Furthermore, since it is an organic substance, the transmission spectrum or absorption spectrum of the film of the resin composition can be adjusted by achieving transmission or blockage of light of a desired specific wavelength, or the like, through chemical structural change or functional transformation, so that the color adjustment property can be improved. As two or more colors of (C7-1) organic pigments other than black are combined, the film of the resin composition can be adjusted in color to a desired color coordinate, so that the color adjustment property can be improved.

As the (C8) organic pigment other than black, the organic pigments that produce color of white, red, orange, yellow, green, blue, or violet, except black, can be cited.

As the (C9) organic pigment other than black, for example, phthalocyanine based pigments, anthraquinone based pigments, quinacridone based pigments, pyranthrone based pigments, dioxazine based pigments, thioindigo based pigments, diketopyrrolopyrrole based pigments, quinophthalone based pigments, threne based pigments, indoline based pigments, isoindoline based pigments, isoindolinone based pigments, benzofuranone based pigments, perylene based pigments, aniline based pigments, azo based pigments, azomethine based pigments, metal complex based pigments, lake pigments, toner pigments, or fluorescent pigments can be cited.

The content ratio of the (C7-1) organic pigments other than black in the solid content of the negative photosensitive resin composition of the present invention, excluding the solvent, is preferably 5 mass % or greater, more preferably 10 mass % or greater, and further preferably 15 mass % or greater. When the content ratio thereof is within the range mentioned above, the colorability and the color adjustment property can be improved. On the other hand, the content ratio thereof is preferably 70 mass % or less, more preferably 65 mass % or less, and further preferably 60 mass % or less. When the content ratio thereof is within the range mentioned above, the sensitivity at the time of exposure can be improved.

The (C9) inorganic pigment other than black refers to an inorganic pigment that produces color of white, red, orange, yellow, green, blue, or violet, except black, by absorbing light of visible ray wavelengths.

Due to containing of the (C9) inorganic pigment other than black, the film of the resin composition can be colored and can be provided with colorability or color adjustment property. Furthermore, since it is an inorganic substance and more excellent in heat resistance and weather resistance, the heat resistance and weather resistance of the film of the resin composition can be improved. As two or more colors of the (C9) inorganic pigments other than black are combined, the film of the resin composition can be adjusted in color to a desired color coordinate, so that the color adjustment property can be improved.

As two or more colors of the (C9) inorganic pigments other than black are combined, the film of the resin composition can be adjusted in color to a desired color coordinate, so that the color adjustment property can be improved.

As the (C9) inorganic pigment other than black, inorganic pigments that produce color of white, red, orange, yellow, green, blue, or violet, except black, can be cited.

As the (C9) inorganic pigment other than black, for example, titanium oxide, barium carbonate, zirconium oxide, zinc white, zinc sulfide, white lead, calcium carbonate, barium sulfate, white carbon, alumina white, silicon dioxide, kaolin clay, talc, bentonite, red iron oxide, molybdenum red, molybdenum orange, chromium vermilion, chrome yellow, cadmium yellow, yellow iron oxide, titanium yellow, chromic oxide, viridian, titanium cobalt green, cobalt green, cobalt chromium green, victoria green, ultramarine, iron blue, cobalt blue, cerulean blue, cobalt silica blue, cobalt zinc silica blue, manganese violet, or cobalt violet can be cited.

The content ratio of an (C7-2) inorganic pigments other than black in the solid content of the negative photosensitive resin composition of the present invention, excluding the solvent, is preferably 5 mass % or greater, more preferably 10 mass % or greater, and further preferably 15 mass % or greater. When the content ratio is within the range mentioned above, the colorability or the color adjustment property, the heat resistance, and the weather resistance can be improved. On the other hand, the content ratio thereof is preferably 70 mass % or less, more preferably 65 mass % or less, and further preferably 60 mass % or less. When the content ratio thereof is within the range mentioned above, the sensitivity at the time of exposure can be improved.

Note that the primary particle diameter of the (C) benzofuranone based organic pigment having an amide structure can be determined by measuring the laser scattering due to Brownian movement of the (C) benzofuranone based organic pigment having an amide structure in the solution (dynamic light scattering method) through the use of a submicron particle size distribution measurement apparatus (N4-PLUS, made by Beckman Coulter, Inc.) or a zeta potential/particle diameter/molecular weight measurement apparatus (Zeta Sizer Nano ZS, made by SYSMEX CORPORATION). Furthermore, in the cured film obtained from the resin composition, the number average particle diameter of the (C) benzofuranone based organic pigment having an amide structure can be determined by measurement through the use of SEM and TEM. The number average particle diameter of the (C) benzofuranone based organic pigment having an amide structure is determined directly with magnifications of 50,000 to 200,000 times. In the case where the (C) benzofuranone based organic pigment having an amide structure is composed of truly spherical particles, the diameters of the truly spherical particles are measured, and a number average particle diameter is determined. In the case where the (C) benzofuranone based organic pigment having an amide structure is not a true sphere, the longest diameter (hereinafter, “major axis diameter”) and the longest diameter in directions orthogonal to the major axis diameter (hereinafter, “minor axis diameter”) are measured, and a two-axis average diameter obtained by averaging the major axis diameter and the minor axis diameter is determined as the number average particle diameter.

<(D) Radical Polymerizable Compound>

As the negative photosensitive resin composition of the present invention, the (D) radical polymerizable compound is preferably further contained.

The (D) radical polymerizable compound refers to a compound having a plurality of ethylenically unsaturated double bond groups in the molecule. At the time of exposure, radicals produced from the (E) photoinitiator described below cause radical polymerization of the (D) radical polymerizable compound to progress so that photo-exposed portion of the film of the resin composition becomes insoluble in the alkaline developer. Thus, a negative-type pattern can be formed.

As the (D) radical polymerizable compound is contained, the UV curing at the time of exposure is facilitated, so that the sensitivity at the time of exposure can be improved. Moreover, the post-thermosetting crosslink density improves and therefore the hardness of the cured film can be improved.

The (D) radical polymerizable compound is preferably a compound having a (meth)acrylic group, because the radical polymerization of the compound can proceed readily. From the viewpoint of improvement in sensitivity upon exposure to light and the hardness improvement of the cured film, a compound having at least two (meth)acrylic groups in the molecule is more preferable. The double bond equivalent of the (D) radical polymerizable compound is preferably 80 to 400 g/mol from the viewpoint of improvement in sensitivity upon exposure to light and the hardness improvement of the cured film.

As the (D) radical polymerizable compound, for example, diethylene glycol di(meth)acrylate, triethylene glycol di(meth)acrylate, tetraethylene glycol di(meth)acrylate, propylene glycol di(meth)acrylate, trimethylol propane di(meth)acrylate, trimethylol propane tri(meth)acrylate, ethoxylated trimethylol propane di(meth)acrylate, ethoxylated trimethylol propane tri(meth)acrylate, ditrimethylol propane tri(meth)acrylate, ditrimethylolpropane tetra(meth)acrylate, 1,3-butanediol di(meth)acrylate, neopentyl glycol di(meth)acrylate, 1,4-butanediol di(meth)acrylate, 1,6-hexanediol di(meth)acrylate, 1,9-nonane diol di(meth)acrylate, 1,10-decane diol di(meth)acrylate, dimethylol-tricyclodecane di(meth)acrylate, ethoxylated glycerin tri(meth)acrylate, pentaerythritol tri(meth)acrylate, pentaerythritol tetra(meth)acrylate, ethoxylated pentaerythritol tri(meth)acrylate, ethoxylated pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, tetrapentaerythritol nona(meth)acrylate, tetrapentaerythritol deca(meth)acrylate, pentapentaerythritol undeca(meth)acrylate, pentapentaerythritol dodeca(meth)acrylate, ethoxylated bisphenol A di(meth)acrylate, 2,2-bis[4-(3-(meth)acryloxy-2-hydroxypropoxy)phenyl]propane, 1,3,5-tris((meth)acryloxyethyl)isocyanuric acid, 1,3-bis((meth)acryloxyethyl)isocyanuric acid, 9,9-bis[4-(2-(meth)acryloxyethoxy)phenyl]fluorene, 9,9-bis[4-(3-(meth)acryloxy propoxy)phenyl]fluorene, or 9,9-bis(4-(meth)acryloxy phenyl)fluorene, or their acid-modified products, ethylene oxide-modified products, or propylene oxide-modified products can be cited.

From the viewpoint of improvement in sensitivity upon exposure to light and the hardness improve of the cured film, trimethylolpropane tri(meth)acrylate, ditrimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, 2,2-bis[4-(3-(meth)acryloyloxy-2-hydroxypropoxy)phenyl]propane, 1,3,5-tris((meth)acryloyloxyethyl)isocyanuric acid, 1,3-bis((meth)acryloyloxyethyl)isocyanuric acid, 9,9-bis[4-(2-(meth)acryloyloxyethoxy)phenyl]fluorene, 9,9-bis[4-(3-(meth)acryloyloxypropoxy)phenyl]fluorene or 9,9-bis(4-(meth)acryloyloxyphenyl)fluorene or acid-modified products, ethylene oxide-modified products or propylene oxide-modified products thereof are preferable. From the viewpoint of the improvement in resolution after development, the acid-modified products and the ethylene oxide-modified products are more preferable.

From the viewpoint of improvement of the post-development resolution, it is also preferable that the compound be a compound obtained by reacting a compound obtained by ring-opening addition reaction of a compound having in its molecule two or more glycidoxy groups and an unsaturated carboxylic acid having an ethylenic unsaturated double bond group, with a polybasic acid carboxylic acid or a polybasic carboxylic anhydride.

The content of the (D) radical polymerizable compound in the negative photosensitive resin composition of the present invention is preferably 15 mass parts or greater in the case where the total of the (A) alkali-soluble resin and the (D) radical polymerizable compound is assumed to be 100 mass parts, the content thereof is more preferably 20 mass parts or greater, further preferably 25 mass parts or greater, and particularly preferably 30 mass parts or greater. When the content thereof is within the range mentioned above, the sensitivity at the time of exposure can be improved and, at the same time, a low-taper pattern shape can be obtained. On the other hand, the content is preferably 65 mass parts or less, more preferably 60 mass parts or less, further preferably 55 mass parts or less, and particularly preferably 50 mass parts. When the content is within the range mentioned above, the heat resistance of the cured film can be improved, and, at the same time, a low-taper pattern shape can be obtained.

<(E) Photoinitiator>

The negative photosensitive resin composition of the present invention further contains a (E) photoinitiator.

The (E) photoinitiator refers to a compound that, when exposed to light, undergoes bond cleavage and/or reaction to produce radicals.

As the (E) photoinitiator is contained, the radical polymerization of the (D) radical polymerizable compound mentioned above progresses so that the photo-exposed portion of the film of the resin composition becomes insoluble in the alkaline developer and, therefore, a negative-type pattern can be formed. Furthermore, the UV curing at the time of exposure is facilitated and therefore the sensitivity can be improved.

As the (E) photoinitiator, for example, a benzyl ketal based photoinitiator, an α-hydroxyketone based photoinitiator, an α-amino ketone based photoinitiator, an acyl phosphine oxide based photoinitiator, an oxime ester based photoinitiator, an acridine based photoinitiator, a titanocene based photoinitiator, a benzophenone-based photoinitiator, an acetophenone based photoinitiator, an aromatic ketoester based photoinitiator, or a benzoic acid ester based photoinitiator is preferable and, from the viewpoint of sensitivity improvement at the time of exposure, an α-hydroxyketone based photoinitiator, an α-amino ketone based photoinitiator, an acyl phosphine oxide based photoinitiator, an oxime ester based photoinitiator, an acridine based photoinitiator, or a benzophenone-based photoinitiator is more preferable, and an α-amino ketone based photoinitiator, an acyl phosphine oxide based photoinitiator, or an oxime ester based photoinitiator is even more preferable.

As the benzyl ketal based photoinitiator, for example, 2,2-dimethoxy-1,2-diphenylethane-1-one can be cited.

As the α-hydroxyketone based photoinitiator, for example, 1-(4-isopropylphenyl)-2-hydroxy-2-methylpropane-1-one, 2-hydroxy-2-methyl-1-phenylpropane-1-one, 1-hydroxycyclohexyl phenyl ketone, 1-[4-(2-hydroxyethoxy)phenyl]-2-hydroxy-2-methylpropane-1-one, or 2-hydroxy-1-[4-[4-(2-hydroxy-2-methylpropionyl) benzyl]phenyl]-2-methylpropane-1-one can be cited.

As the α-amino ketone based photoinitiator, for example, 2-methyl-1-[4-(methylthio)phenyl]-2-morpholino propane-1-one, 2-benzyl-2-dimethylamino-1-(4-morpholino phenyl)-butane-1-one, 2-dimethylamino-2-(4-methylbenzyl)-1-(4-morpholino phenyl)-butane-1-one, or 3,6-bis(2-methyl-2-morpholinopropionyl)-9-octyl-9H-carbazol can be cited.

As the acyl phosphine oxide based photoinitiator, for example, 2,4,6-trimethylbenzoyl-diphenyl phosphine oxide, bis(2,4,6-trimethylbenzoyl)-phenyl phosphine oxide, or bis(2,6-dimethoxybenzoyl)-(2,4,4-trimethylpentyl)phosphine oxide can be cited.

As the oxime ester based photoinitiator, for example, 1-phenylpropane-1,2-dione-2-(O-ethoxycarbonyl)oxime, 1-phenyl butane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-(carboxyphenyl)thio]phenyl]propane-1,2-dione-2-(O-acetyl)oxime, 1-[9-ethyl-6-(2-methylbenzoyl)-9H-carbazol-3-yl]ethanone-1-(O-acetyl)oxime, 1-[9-ethyl-6-[2-methyl-4-[l-(2,2-dimethyl-1,3-dioxolane-4-yl)methyloxy]benzoyl]-9H-carbazol-3-yl]ethanone-1-(O-acetyl) oxime, or 1-(9-ethyl-6-nitro-9H-carbazol-3-yl)-1-[2-methyl-4-(1-methoxypropane-2-yloxy)phenyl]methanone-1-(O-acetyl)oxime can be cited.

As the acridine based photoinitiator, for example, 1,7-bis(acridine-9-yl)-n-heptane can be cited.

As the titanocene based photoinitiator, for example, bis(η⁵-2,4-cyclopentadiene-1-yl)-bis[2,6-difluoro)-3-(1H-pyrrole-1-yl)phenyl]titanium(IV) or bis(η⁵-3-methyl-2,4-cyclopentadiene-1-yl)-bis(2,6-difluorophenyl)titanium(IV) can be cited.

As the benzophenone-based photoinitiator, for example, benzophenone, 4,4′-bis(dimethylamino) benzophenone, 4,4′-bis(diethylamino) benzophenone, 4-phenylbenzophenone, 4,4-dichlorobenzophenone, 4-hydroxybenzophenone, alkylated benzophenone, 3,3′,4,4′-tetrakis(t-butylperoxycarbonyl) benzophenone, 4-methyl benzophenone, dibenzyl ketone, or fluorenone can be cited.

As the acetophenone based photoinitiator, for example, 2,2-diethoxyacetophenone, 2,3-diethoxyacetophenone, 4-t-butyldichloroacetophenone, benzalacetophenone, or 4-azidobenzalacetophenone can be cited.

As the aromatic ketoester based photoinitiator, for example, 2-phenyl-2-oxymethyl acetate can be cited.

As the benzoic acid ester based photoinitiator, for example, ethyl 4-dimethylaminobenzoate, (2-ethyl)hexyl 4-dimethylaminobenzoate, ethyl 4-diethylaminobenzoate, or methyl 2-benzoylbenzoate can be cited.

The content of the (E) photoinitiator in the negative photosensitive resin composition of the present invention is preferably 0.1 mass part or greater in the case where the total of the (A) alkali-soluble resin and the (D) radical polymerizable compound is assumed to be 100 mass parts, the content thereof is more preferably 0.5 mass part or greater, further preferably 0.7 mass part or greater, and particularly preferably 1.0 mass part or greater. When the content thereof is within the range mentioned above, the sensitivity at the time of exposure can be improved. On the other hand, the content is preferably 25 mass parts or less, more preferably 20 mass parts or less, further preferably 17 mass parts or less, and particularly preferably 15 mass parts or less. When the content is within the range mentioned above, the post-development resolution can be improved and, at the same time, a low-taper pattern shape can be obtained.

<Chain Transfer Agent>

It is preferable that the negative photosensitive resin composition of the present invention further contain a chain transfer agent.

The chain transfer agent refers to a compound capable of receiving radicals from a growing polymer end of a polymer chain obtained by radical polymerization at the time of exposure and causing transfer of radicals to another polymer chain.

Due to containing of a chain transfer agent, the sensitivity at the time of exposure can be improved. This is speculated to be because radicals produced by exposure undergo radical transfer to other polymer chains due to the chain transfer agent so that radical crosslinking occurs to deep portions of the film. In particular, for example, when the resin composition contains the aforementioned (C) benzofuranone based organic pigment having an amide structure, light for the exposure is absorbed by the (C) benzofuranone based organic pigment having an amide structure, and therefore the light sometimes cannot reach deep portions of the film. On the other hand, in the case where the resin composition contains a chain transfer agent, the radical transfer due to the chain transfer agent achieves radical crosslinking to deep portions of the film, so that the sensitivity at the time of exposure can be improved.

Furthermore, due to containing of a chain transfer agent, a low-taper pattern shape can be obtained. This is speculated to be because the radical transfer by the chain transfer agent can provide a molecular weight control of polymer chains that are obtained by radical polymerization at the time of exposure. Specifically, due to containing of a chain transfer agent, the production of remarkably high molecular weight polymer chains due to excessive radical polymerization at the time of exposure is inhibited and therefore increase in the softening point of the obtained film is restrained. Therefore, it is considered that the pattern reflow property at the time of thermosetting improves so that a low-taper pattern shape is obtained.

The chain transfer agent is preferably a thiol-type chain transfer agent. As the thiol-type chain transfer agent, for example, β-mercaptopropionic acid, methyl β-mercaptopropionate, ethyl β-mercaptopropionate, 2-ethylhexyl β-mercaptopropionate, n-octyl β-mercaptopropionate, methoxybutyl β-mercaptopropionate, stearyl β-mercaptopropionate, isononyl β-mercaptopropionate, β-mercaptobutanoic acid, methyl β-mercaptobutanoate, ethyl β-mercaptobutanoate, 2-ethylhexyl β-mercaptobutanoate, n-octyl β-mercaptobutanoate, methoxybutyl β-mercaptobutanoate, stearyl β-mercaptobutanoate, isononyl β-mercaptobutanoate, methyl thioglycolate, n-octyl thioglycolate, methoxybutyl thioglycolate, 1,4-bis(3-mercaptobutanoyloxy)butane, 1,4-bis(3-mercaptopropionyloxy)butane, 1,4-bis(thioglycoloyloxy)butane, ethylene glycol bis(thioglycollate), trimethylolethane tris(3-mercaptopropionate), trimethylolethane tris(3-mercaptobutyrate), trimethylolpropane tris(3-mercaptopropionate), trimethylolpropane tris(3-mercaptobutyrate), trimethylolpropane tris(thioglycollate), 1,3,5-tris[(3-mercaptopropionyloxy)ethyl]isocyanuric acid, 1,3,5-tris[(3-mercaptobutanoyloxy)ethyl]isocyanuric acid, pentaerythritol tetrakis(3-mercaptopropionate), pentaerythritol tetrakis(3-mercaptobutyrate), pentaerythritol tetrakis(thioglycollate), dipentaerythritol hexakis(3-mercaptopropionate) or dipentaerythritol hexakis(3-mercaptobutyrate) can be cited.

From the viewpoint of the improvement in the sensitivity upon exposure to light and the formation of a low-tapered pattern form, 1,4-bis(3-mercaptobutanoyloxy)butane, 1,4-bis(3-mercaptopropionyloxy)butane, 1,4-bis(thioglycoloyloxy)butane, ethylene glycol bis(thioglycollate), trimethylolethane tris(3-mercaptopropionate), trimethylolethane tris(3-mercaptobutyrate), trimethylolpropane tris(3-mercaptopropionate), trimethylolpropane tris(3-mercaptobutyrate), trimethylolpropane tris(thioglycollate), 1,3,5-tris[(3-mercaptopropionyloxy)ethyl]isocyanuric acid, 1,3,5-tris[(3-mercaptobutanoyloxy)ethyl]isocyanuric acid, pentaerythritol tetrakis(3-mercaptopropionate), pentaerythritol tetrakis(3-mercaptobutyrate), pentaerythritol tetrakis(thioglycollate), dipentaerythritol hexakis(3-mercaptopropionate) or dipentaerythritol hexakis(3-mercaptobutyrate) is preferable.

The content of the chain transfer agent in the negative photosensitive resin composition of the present invention is preferably 0.01 mass part or greater in the case where a total of a (A1) first region, a (A2) second resin, and the (D) radical polymerizable compound is assumed to be 100 mass parts, and the content thereof is more preferably 0.1 mass part or greater, further preferably 0.5 mass part or greater, and particularly preferably 1.0 mass part of greater. When the content thereof is within the range mentioned above, the sensitivity at the time of exposure can be improved and, at the same time, a low-taper pattern shape can be obtained. On the other hand, the content is preferably 15 mass parts or less, more preferably 13 mass parts or less, further preferably 10 mass parts or less, and particularly preferably 8 mass parts or less. When the content thereof is within the range mentioned above, the post-development resolution and the heat resistance of the cured film can be improved.

<Polymerization Terminator>

It is preferable that the negative photosensitive resin composition of the present invention further contain a polymerization terminator.

The polymerization terminator refers to a compound capable of stopping radical polymerization by trapping radicals produced at the time of exposure or radicals of growing polymer ends of polymer chains obtained by radical polymerization at the time of exposure and holding the radicals as stable radicals.

Due to containing an appropriate amount of a polymerization terminator, production of residue after development can be inhibited, so that the post-development resolution can be improved. This is speculated to be because the polymerization terminator traps an excess amount of radicals produced at the time of exposure or radicals at growing ends of high-molecular weight polymer chains, so that progress of excessive radical polymerization is inhibited.

As the polymerization terminator, phenol based polymerization terminators are preferable. As phenol based polymerization terminators, for example, 4-methoxyphenol, 1,4-hydroquinone, 1,4-benzoquinone, 2-t-butyl-4-methoxyphenol, 3-t-butyl-4-methoxyphenol, 4-t-butylcatechol, 2,6-di-t-butyl-4-methylphenol, 2,5-di-t-butyl-1,4-hydroquinone, 2,5-di-t-amyl-1,4-hydroquinone, or “IRGANOX” (registered trademark) 1010, ditto 1035, ditto 1076, ditto 1098, ditto 1135, ditto 1330, ditto 1726, ditto 1425, ditto 1520, ditto 245, ditto 259, ditto 3114, ditto 565, or ditto 295 (which are all made by BASF) can be cited.

The content of the polymerization terminator in the negative photosensitive resin composition of the present invention is preferably 0.01 mass parts or greater in the case where a total of the (A) alkali-soluble resin and the (D) radical polymerizable compound is assumed to be 100 mass parts, and the content thereof is more preferably 0.03 mass parts or greater, further preferably 0.05 mass parts or greater, and particularly preferably 0.10 mass parts or greater. When the content thereof is within the range mentioned above, the post-development resolution and the heat resistance of the cured film can be improved. On the other hand, the content is preferably 10 mass parts or less, more preferably 8 mass parts or less, further preferably 5 mass parts or less, and particularly preferably 3 mass parts or less. When the content thereof is within the range mentioned above, the sensitivity at the time of exposure can be improved.

<Sensitizer>

It is preferable that the negative photosensitive resin composition of the present invention further contain a sensitizer.

The sensitizer refers to a compound capable of absorbing energy from exposure to produce exited-triplet electrons due to internal conversion and intersystem crossing so that energy transfer to the aforementioned (E) photoinitiator or the like can be caused.

Due to containing of the sensitizer, the sensitivity at the time of exposure can be improved. This is speculated to be because the sensitizer can improve photoreaction efficiency by absorbing light of long wavelengths that the (E) photoinitiator does not absorb and transferring its energy from the sensitizer to the (E) photoinitiator and the like.

As the sensitizer, thioxanthone based sensitizers are preferable. As the thioxanthone based sensitizers, for example, thioxanthone, 2-methylthioxanthone, 2-chlorothioxanthone, 2-isopropyl thioxanthone, 2,4-dimethylthioxanthone, 2,4-diethylthioxanthone, or 2,4-dichlorothioxanthone can be cited.

The content of the sensitizer in the negative photosensitive resin composition of the present invention is preferably 0.01 mass part or greater in the case where the total of the (A) alkali-soluble resin and the (D) radical polymerizable compound is assumed to be 100 mass parts, and the content thereof is more preferably 0.1 mass part or greater, further preferably 0.5 mass part or greater, and particularly preferably 1.0 mass part or greater. When the content thereof is within the range mentioned above, the sensitivity at the time of exposure can be improved. On the other hand, the content is preferably 15 mass parts or less, more preferably 13 mass parts or less, further preferably 10 mass parts or less, and particularly preferably 8 mass parts or less. When the content is within the range mentioned above, the post-development resolution can be improved and, at the same time, a low-taper pattern shape can be obtained.

<Crosslinking Agent>

It is preferable that the negative photosensitive resin composition of the present invention further contain a crosslinking agent. The crosslinking agent refers to a compound that has a crosslinkable group capable of binding to the resin. Due to containing of a crosslinking agent, the hardness and chemical resistance of the cured film can be improved. This is speculated to be because the crosslinking agent makes it possible to introduce a new crosslink structure to the cured film of the resin composition and therefore the crosslink density improves.

The crosslinking agent is preferably a compound that has in its molecule two or more thermal crosslinkabilities such as alkoxy methyl groups, methylol groups, epoxy groups, or oxetanyl groups.

As the compound that has in its molecule two or more alkoxy methyl groups or methylol groups, for example, DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PTBP, DMOM-MBPC, TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA, or HMOM-TPHAP (which are all made by Honshu Chemical Industry Co., Ltd.), or “NIKALAC” (registered trademark) MX-290, ditto MX-280, ditto MX-270, ditto MX-279, ditto MW-100LM, ditto MW-30HM, ditto MW-390, or ditto MX-750LM (which are made by SANWA CHEMICAL CO., LTD.) can be cited.

As the compound that has in its molecule two or more epoxy groups, for example, “Epolite” (registered trademark) 40E, ditto 100E, ditto 200E, ditto 400E, ditto 70P, ditto 200P, ditto 400P, ditto 1500NP, ditto 80MF, ditto 4000, or ditto 3002 (which are all made by Kyoeisha Chemical Co., Ltd.), “Denacol” (registered trademark) EX-212L, ditto EX-214L, ditto EX-216L, ditto EX-321L, or ditto EX-850L (which are all made by Nagase ChemteX Corporation), “jER” (registered trademark) 828, ditto 1002, ditto 1750, ditto 1007, ditto YX8100-BH30, ditto E1256, ditto E4250, or ditto E4275 (which are all made by Mitsubishi Chemical Corporation), GAN, GOT, EPPN-502H, NC-3000, or NC-6000 (which are all made by Nippon Kayaku Co., Ltd.), “EPICLON” (registered trademark) EXA-9583, ditto HP4032, ditto N695, or ditto HP7200 (which are all made by DIC Corporation), “TECHMORE” (registered trademark) VG-3101L (made by Printec Corporation), “TEPIC” (registered trademark) S, ditto G, or ditto P (which are all made by Nissan Chemical Industries, Ltd.), or “Epotohto” (registered trademark) YH-434L (made by Tohto Kasei Co., Ltd.) can be cited.

As the compound that has in its molecule two or more oxetanyl groups, for example, “ETERNACOLL” (registered trademark) EHO, ditto OXBP, ditto OXTP, or ditto OXMA (which are all made by Ube Industries, Ltd.), or oxetanized phenol novolac can be cited.

The content of the crosslinking agent in the negative photosensitive resin composition of the present invention is preferably 0.1 mass part or greater in the case where a total of the (A) alkali-soluble resin and the (D) radical polymerizable compound is assumed to be 100 mass parts, and the content thereof is more preferably 0.5 mass part or greater, and further preferably 1.0 mass part or greater. When the content thereof is within the range mentioned above, the hardness and chemical resistance of the cured film can be improved. On the other hand, the content of the crosslinking agent is preferably 70 mass parts or less, more preferably 60 mass parts or less, and further preferably 50 mass parts or less. When the content thereof is within the range mentioned above, the hardness and chemical resistance of the cured film can be improved.

<Silane Coupling Agent>

The negative photosensitive resin composition of the present invention preferably further contains a silane coupling agent. The silane coupling agent refers to a compound that has a hydrolyzable silyl group or silanol group. Containing a silane coupling agent increases the interaction at the interface between the cured film of the resin composition and a base substrate, so that the adhesion with the base substrate and the chemical resistance of the cured film can be improved.

As the silane coupling agent, trifunctional organosilanes, tetrafunctional organosilanes, or silicate compounds are preferable.

As the trifunctional organosilane, for example, methyltrimethoxysilane, methyltriethoxysilane, methyltri-n-propoxysilane, ethyltrimethoxysilane, n-propyltrimethoxysilane, isopropyltrimethoxysilane, n-butyltrimethoxysilane, n-hexyltrimethoxysilane, n-octyltrimethoxysilane, n-decyltrimethoxysilane, cyclopentyltrimethoxysilane, cyclohexyltrimethoxysilane, vinyltrimethoxysilane, vinyltriethoxysilane, 3-methacryloxypropyltrimethoxysilane, 3-methacryloxypropyltriethoxysilane, 3-acryloxy propyl trimethoxysilane, 3-acryloxy propyltriethoxysilane, phenyltrimethoxysilane, phenyltriethoxysilane, 4-tolyltrimethoxysilane, 4-hydroxyphenyltrimethoxysilane, 4-methoxyphenyltrimethoxysilane, 4-t-butylphenyltrimethoxysilane, 1-naphthyltrimethoxysilane, 2-naphthyltrimethoxysilane, 4-styryltrimethoxysilane, 2-phenylethyltrimethoxysilane, 4-hydroxy benzyltrimethoxysilane, 1-(4-hydroxyphenyl)ethyltrimethoxysilane, 2-(4-hydroxyphenyl)ethyltrimethoxysilane, 4-hydroxy-5-(4-hydroxyphenylcarbonyloxy)pentyltrimethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, 2-(3-trimethoxysilylpropyl)-4-(N-t-butyl)amino-4-oxo butanoic acid, 3-(3-trimethoxysilylpropyl)-4-(N-t-butyl)amino-4-oxo butanoic acid, 3-trimethoxysilylpropylsuccinic acid, 3-triethoxysilylpropylsuccinic acid, 3-trimethoxysilylpropionic acid, 4-trimethoxysilylbutyric acid, 5-trimethoxysilylvaleric acid, 3-trimethoxysilylpropyl succinic anhydride, 3-triethoxysilylpropyl succinic anhydride, 4-(3-trimethoxysilylpropyl)cyclohexane-1,2-dicarboxylic anhydride, 4-(3-trimethoxysilylpropyl)phthalic anhydride, trifluoromethyltrimethoxysilane, trifluoromethyltriethoxysilane, 3,3,3-trifluoropropyltrimethoxysilane, 3-[(3-ethyl-3-oxetanyl)methoxy]propyltrimethoxysilane, 3-[(3-ethyl-3-oxetanyl)methoxy]propyltriethoxysilane, 3-aminopropyltrimethoxysilane, 3-aminopropyltriethoxysilane, N-(2-aminoethyl)-3-aminopropyltrimethoxysilane, N-(2-aminoethyl)-3-aminopropyltriethoxysilane, N-phenyl-3-aminopropyltrimethoxysilane, N-(vinylbenzyl)-2-aminoethyl-3-aminopropyltrimethoxysilane hydrochlorate salt, 3-(4-aminophenyl)propyltrimethoxysilane, 1-[4-(3-trimethoxysilylpropyl)phenyl]urea, 1-(3-trimethoxysilylpropyl)urea, 1-(3-triethoxysilylpropyl)urea, 3-trimethoxysilyl-N-(1,3-dimethylbutylidene) propyl amine, 3-triethoxysilyl-N-(1,3-dimethylbutylidene) propyl amine, 3-mercaptopropyltrimethoxysilane, 3-mercapto propyltriethoxysilane, 3-isocyanate propyltrimethoxysilane, 3-isocyanate propyltriethoxysilane, 1,3,5-tris(3-trimethoxysilylpropyl)isocyanuric acid, 1,3,5-tris(3-triethoxysilylpropyl)isocyanuric acid, N-t-butyl-2-(3-trimethoxysilylpropyl)succinimide, or N-t-butyl-2-(3-triethoxysilylpropyl)succinimide can be cited.

As the tetrafunctional organosilanes or the silicate compounds, for example, organosilanes represented by general formula (68) can be cited.

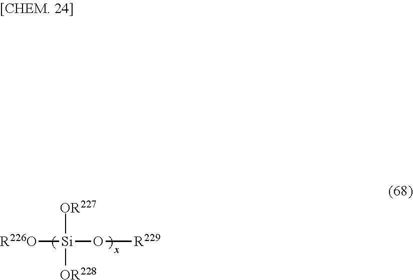

(In general formula (68), R²²⁶ to R²²⁹ each independently represent hydrogen, an alkyl group, an acyl group, or an aryl group, and x represents an integer of 1 to 15.)

In general formula (68), it is preferable that R²²⁶ to R²²⁹ each independently be hydrogen, an alkyl group having a carbon number of 1 to 6, an acyl group having a carbon number of 2 to 6, or an aryl group having a carbon number of 6 to 15, and it is more preferable that R²²⁶ to R²²⁹ each independently be hydrogen, an alkyl group having a carbon number of 1 to 4, an acyl group having a carbon number of 2 to 4, or an aryl group having a carbon number of 6 to 10. The alkyl group, the acyl group, and the aryl group mentioned above may be either an unsubstituted product or a substitution product.

As the organosilane represented by general formula (68), for example, tetrafunctional organosilanes, such as tetramethoxysilane, tetraethoxysilane, tetra-n-propoxysilane, tetraisopropoxysilane, tetra-n-butoxysilane, or tetraacetoxysilane, and silicate compounds, such as Methyl Silicate 51 (made by FUSO CHEMICAL CO., LTD.), M Silicate 51, Silicate 40, or Silicate 45 (which are all made by TAMA CHEMICALS CO., LTD.), or Methyl Silicate 51, Methyl Silicate 53A, Ethyl Silicate 40, or Ethyl Silicate 48 (which are all made by COLCOAT CO., LTD.), can be cited.

As the silane coupling agent, the following compounds are preferable from the viewpoint of the improvement in the adhesion to an underlying substrate and the chemical resistance of the cured film: a trifunctional organosilane such as vinyltrimethoxysilane, vinyltriethoxysilane, 3-methacryloyloxypropyltrimethoxysilane, 3-methacryloyloxypropyltriethoxysilane, 3-acryloyloxypropyltrimethoxysilane, 3-acryloyloxypropyltriethoxysilane, 1-naphthyltrimethoxysilane, 2-naphthyltrimethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, 3-[(3-ethyl-3-oxetanyl)methoxy]propyltrimethoxysilane, 3-[(3-ethyl-3-oxetanyl)methoxy]propyltriethoxysilane, 3-aminopropyltrimethoxysilane, 3-aminopropyltriethoxysilane, N-phenyl-3-aminopropyltrimethoxysilane, 3-(4-aminophenyl)propyltrimethoxysilane, 1-[4-(3-trimethoxysilylpropyl)phenyl]urea, 1-(3-trimethoxysilylpropyl)urea, 1-(3-triethoxysilylpropyl)urea, 3-trimethoxysilyl-N-(1,3-dimethylbutylidene)propylamine, 3-triethoxysilyl-N-(1,3-dimethylbutylidene)propylamine, 3-isocyanatepropyltrimethoxysilane, 3-isocyanatepropyltriethoxysilane, 1,3,5-tris(3-trimethoxysilylpropyl)isocyanuric acid, 1,3,5-tris(3-triethoxysilylpropyl)isocyanuric acid, N-t-butyl-2-(3-trimethoxysilylpropyl)succinimide and N-t-butyl-2-(3-triethoxysilylpropyl)succinimide; a tetrafunctional organosilane such as tetramethoxysilane, tetraethoxysilane, tetra-n-propoxysilane, tetraisopropoxysilane, tetra-n-butoxysilane and tetraacetoxysilane; and a silicate compound such as methyl silicate 51 (made by FUSO CHEMICAL CO., LTD.), M silicate 51, silicate 40 and silicate 45 (which are all made by TAMA CHEMICALS CO., LTD.), and methyl silicate 51, methyl silicate 53A, ethyl silicate 40 and ethyl silicate 48 (which are all made by COLCOAT CO., LTD.).

The content of the silane coupling agent in the negative photosensitive resin composition of the present invention is preferably 0.01 mass part or greater in the case where the total of the (A) alkali-soluble resin and the (D) radical polymerizable compound is assumed to be 100 mass parts, and the content thereof is more preferably 0.1 mass part or greater, further preferably 0.5 mass part or greater, and particularly preferably 1.0 mass part or greater. When the content thereof is within the range mentioned above, the adhesion with the base substrate and the chemical resistance of the cured film can be improved. On the other hand, the content is preferably 15 mass parts or less, more preferably 13 mass parts or less, further preferably 10 mass parts or less, and particularly preferably 8 mass parts or less. When the content thereof is within the range mentioned above, the post-development resolution can be improved.

<Surfactant>

The negative photosensitive resin composition of the present invention may further contain a surfactant. The surfactant refers to a compound that has a hydrophilic structure and a hydrophobic structure. Due to containing an appropriate amount of a surfactant, the surface tension of the resin composition can be arbitrarily adjusted, and the leveling property at the time of coating application improves, so that the film thickness uniformity of the coating film can be improved.

As the surfactant, fluorine resin based surfactants, silicone based surfactants, polyoxyalkylene ether based surfactants, or acrylic resin based surfactants are preferable.

As the fluorine resin based surfactants, 1,1,2,2-tetrafluorooctyl(1,1,2,2-tetrafluoropropyl)ether, 1,1,2,2-tetrafluorooctylhexyl ether, octaethylene glycol bis(1,1,2,2-tetrafluorobutyl)ether, hexaethylene glycol (1,1,2,2,3,3-hexafluoropentyl)ether, octapropylene glycol bis(1,1,2,2-tetrafluorobutyl)ether, hexapropylene glycol bis(1,1,2,2,3,3-hexafluoropentyl)ether, perfluorododecylsulfonic acid sodium, 1,1,2,2,8,8,9,9,10,10-decafluorododecane, 1,1,2,2,3,3-hexafluorodecane, N-[3-(perfluorooctanesulfoneamide)propyl]-N,N′-dimethyl-N-carboxymethyleneammonium betaine, perfluoroalkylsulfoneamide propyltrimethylammonium salt, perfluoroalkyl-N-ethylsulfonyl glycine salt, or bis(N-perfluorooctylsulfonyl-N-ethylaminoethyl)phosphate can be cited. In addition, a compound having a fluoroalkyl group or a fluoroalkylene chain at any one of an end, a main chain, and a side chain, such as monoperfluoroalkylethylphosphoric acid ester, can be cited.

As such a compound, for example, “MEGAFACE” (registered trademark) F-142D, ditto F-172, ditto F-173, ditto F-183, ditto F-444, ditto F-445, ditto F-470, ditto F-475, ditto F-477, ditto F-555, ditto F-558, or ditto F-559 (which are all made by DIC Corporation), “Eftop” (registered trademark) EF301, ditto 303, or ditto 352 (which are all made by Mitsubishi Materials Electronic Chemicals Co., Ltd.), “Fluorad” (registered trademark) FC-430 or ditto FC-431 (which are all made by Sumitomo 3M Limited), “AsahiGuard” (registered trademark) AG710 (made by Asahi Glass Co., Ltd.), “SURFLON” (registered trademark)S-382, ditto SC-101, ditto SC-102, ditto SC-103, ditto SC-104, ditto SC-105, or ditto SC-106 (which are all made by AGC Seimi Chemical Co., Ltd.), BM-1000 or BM-1100 (which are all made by Yusho Co., Ltd.), or “FTERGENT” (registered trademark) 710FM or ditto 730LM (which are all made by NEOS COMPANY LIMITED) can be cited.

As the silicone based surfactant, for example, SH28PA, SH7PA, SH21PA, SH30PA, or ST94PA (which are all made by Dow Corning Toray Co., Ltd.), or “BYK” (registered trademark)-301, ditto-306, ditto-307, ditto-331, ditto-333, ditto-337, or ditto-345 (which are all made by BYK Japan KK) can be cited.

As the polyoxyalkylene ether based surfactant, “FTERGENT” (registered trademark) 212M, ditto 209F, ditto 208G, ditto 240G, ditto 212P, ditto 220P, ditto 228P, ditto NBX-15, ditto FTX-218, or ditto DFX-218 (which are all made by NEOS COMPANY LIMITED) can be cited.

As the acrylic resin based surfactant, “BYK” (registered trademark)-350, ditto-352, ditto-354, ditto-355, ditto-356, ditto-358N, ditto-361N, ditto-392, ditto-394, or ditto-399 (which are all made by BYK Japan KK) can be cited.

The content ratio of the surfactant in the negative photosensitive resin composition of the present invention is preferably 0.001 mass % or greater of the entire negative photosensitive resin composition, and the content ratio thereof is more preferably 0.005 mass % or greater, and further preferably 0.010 mass part or greater. When the content ratio thereof is within the range mentioned above, the leveling property at the time of coating application can be improved. On the other hand, the content ratio thereof is preferably 1.0 mass % or less, more preferably 0.5 mass % or less, and further preferably 0.03 mass % or less. When the content ratio thereof is within the range mentioned above, the leveling property at the time of coating application can be improved.

<Solvent>

It is preferable that the negative photosensitive resin composition of the present invention further contain a solvent. The solvent refers to a compound capable of dissolving various resins and various additives that are to be contained in the resin composition. Due to containing of a solvent, various resins and various additives that are to be contained in the resin composition can be homogeneously dissolved, so that the transmittance of the cured film can be improved. Furthermore, the viscosity of the resin composition can be arbitrarily adjusted, so that a film can be formed with a desired film thickness on a substrate. Moreover, the surface tension of the resin composition or the desiccation speed thereof at the time of coating application can be arbitrarily adjusted, so that the leveling property at the time of coating application and the film thickness uniformity of the coating film can be improved.

It is preferable, from the viewpoint of the solubility of various resins and various additives, that the solvent be a compound that has an alcoholic hydroxyl group, a compound that has a carbonyl group, a compound that has three or more ether bonds. Moreover, a compound whose boiling point under atmospheric pressure is 110 to 250° C. is more preferable. Having a boiling point of 110° C. or greater, the solvent vaporizes appropriately at the time of coating application and thus promotes the drying of the coating film, so that coating unevenness can be inhibited and the film thickness uniformity can be improved. On the other hand, the solvent having a boiling point of 250° C. or less allows reduction of the amount of the solvent that remains in the coating film. Therefore, the amount of film shrinkage at the time of thermosetting can be reduced, so that the flatness of the cured film can be increased and the film thickness uniformity can be improved.

As the compound which has an alcoholic hydroxyl group and whose boiling point under atmospheric pressure is 110 to 250° C., for example, hydroxy acetone, 4-hydroxy-2-butanone, 3-hydroxy-3-methyl-2-butanone, 4-hydroxy-3-methyl-2-butanone, 5-hydroxy-2-pentanone, 4-hydroxy-2-pentanone, 4-hydroxy-4-methyl-2-pentanone (also called diacetone alcohol), methyl lactate, ethyl lactate, n-propyl lactate, n-butyl lactate, methyl 2-hydroxy-2-methylpropionate, methyl 2-hydroxy-3-methylbutanoate, ethylene glycol monomethyl ether, ethylene glycol monoethyl ether, ethylene glycol mono-n-propyl ether, ethylene glycol mono-n-butyl ether, propylene glycol monomethyl ether, propylene glycol monoethyl ether, propylene glycol mono-n-propyl ether, propylene glycol mono-n-butyl ether, propylene glycol mono-t-butyl ether, diethylene glycol monomethyl ether, diethylene glycol monoethyl ether, diethylene glycol mono-n-propyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, 3-methoxy-1-butanol, 3-methoxy-3-methyl-1-butanol, 1,3-butanediol, 1,4-butanediol, tetrahydrofurfuryl alcohol, n-butanol, or n-pentanol can be cited. From the viewpoint of the leveling property at the time of coating application, the compound is preferably diacetone alcohol, ethyl lactate, ethylene glycol monomethyl ether, propylene glycol monomethyl ether, diethylene glycol monomethyl ether, dipropylene glycol monomethyl ether, 3-methoxy-1-butanol, 3-methoxy-3-methyl-1-butanol, or tetrahydrofurfuryl alcohol.

As the compound which has a carbonyl group and whose boiling point under atmospheric pressure is 110 to 250° C., for example, n-butyl acetate, isobutyl acetate, 3-methoxymethyl propionate, methyl 3-ethoxypropionate, ethoxyethyl acetate, 3-methoxy-n-butyl acetate, 3-methyl-3-methoxy-n-butyl acetate, 3-methyl-3-methoxy-n-butyl propionate, ethylene glycol monomethyl ether acetate, ethylene glycol monoethyl ether acetate, ethylene glycol monobutyl ether acetate, propylene glycol monomethyl ether acetate, propylene glycol monoethyl ether acetate, propylene glycol monobutyl ether acetate, diethylene glycol monomethyl ether acetate, diethylene glycol monoethyl ether acetate, diethylene glycol mono-n-butyl ether acetate, dipropylene glycol monomethyl ether acetate, dipropylene glycol monoethyl ether acetate, cyclohexanol acetate, propylene glycol diacetate, 1,3-butanediol diacetate, 1,4-butanediol diacetate, methyl n-butyl ketone, methyl isobutyl ketone, diisobutyl ketone, 2-heptanone, acetylacetone, cyclopentanone, cyclohexanone, cycloheptanone, γ-butyrolactone, γ-valerolactone, δ-valerolactone, propylene carbonate, N-methyl-2-pyrrolidone, N,N′-dimethylformamide, N,N′-dimethylacetamide, or 1,3-dimethyl-2-imidazolidinone can be cited. From the viewpoint of the leveling property at the time of coating application, the compound is preferably 3-methoxy-n-butyl acetate, 3-methyl-3-n-butyl acetate, propylene glycol monomethyl ether acetate, dipropylene glycol monomethyl ether acetate, or γ-butyrolactone.

As the compound which has three or more ether bonds and whose boiling point under atmospheric pressure is 110 to 250° C., for example, diethylene glycol dimethyl ether, diethylene glycol diethyl ether, diethylene glycol ethyl methyl ether, diethylene glycol di-n-propyl ether, dipropylene glycol dimethyl ether, dipropylene glycol diethyl ether, dipropylene glycol methyl-n-propyl ether, dipropylene glycol ethyl methyl ether, or dipropylene glycol di-n-propyl ether can be cited. From the viewpoint of the leveling property at the time of coating application, the compound is preferably diethylene glycol dimethyl ether, diethylene glycol ethyl methyl ether, or dipropylene glycol dimethyl ether.

The content ratio of the solvent in the negative photosensitive resin composition of the present invention can be adjusted as appropriate according to the coating method or the like. For example, in the case where a coating film is formed by spin coating, it is common to set the content ratio thereof within the range of 50 to 95 mass % of the entire negative photosensitive resin composition.

In the case where the (C) benzofuranone based organic pigment having an amide structure is contained, the solvent is preferably a solvent that has a carbonyl group or an ester bond. Due to containing of the solvent that has a carbonyl group or an ester bond, the dispersion stability of the (C) benzofuranone based organic pigment having an amide structure or a disperse dye can be improved. From the viewpoint of dispersion stability, the solvent is more preferably a solvent that has an acetate bond. Due to containing of the solvent that has an acetate bond, the dispersion stability of the (C) benzofuranone based organic pigment having an amide structure can be improved.

As the solvent that has an acetate bond, for example, n-butyl acetate, isobutyl acetate, 3-methoxy-n-butyl acetate, 3-methyl-3-methoxy-n-butyl acetate, ethylene glycol monomethyl ether acetate, ethylene glycol monoethyl ether acetate, ethylene glycol monobutyl ether acetate, propylene glycol monomethyl ether acetate, propylene glycol monoethyl ether acetate, propylene glycol monobutyl ether acetate, diethylene glycol monomethyl ether acetate, diethylene glycol monoethyl ether acetate, diethylene glycol mono-n-butyl ether acetate, dipropylene glycol monomethyl ether acetate, dipropylene glycol monoethyl ether acetate, cyclohexanol acetate, propylene glycol diacetate, 1,3-butanediol diacetate, or 1,4-butanediol diacetate can be cited.

In the negative photosensitive resin composition of the present invention, the content ratio of the solvent that has a carbonyl group or an ester bond in the solvent is preferably within the range of 30 to 100 mass %, more preferably within the range of 50 to 100 mass %, and further preferably within the range of 70 to 100 mass %. When the content ratio is within the range mentioned above, the dispersion stability of the (C) benzofuranone based organic pigment having an amide structure can be improved.

<Other Additives>

The negative photosensitive resin composition of the present invention may further contain other resins or their precursors. As the other resins or their precursors, for example, polyamide, polyamide imide, epoxy resin, novolac resin, urea resin, polyurethane, or their precursors can be cited.

<Production Method for Negative Photosensitive Resin Composition of Present Invention>

A representative production method for the negative photosensitive resin composition of the present invention will be described. For example, when the (C) benzofuranone based organic pigment having an amide structure contains the (C) benzofuranone based organic pigment having an amide structure, the (B) dispersant having an amine value exceeding 0 is added to a solution of the (A) alkali-soluble resin, and the (C) benzofuranone based organic pigment having an amide structure is dispersed in this mixed solution by using a dispersing machine to prepare a pigment dispersion liquid. Next, the (D) radical polymerizable compound, the (E) photoinitiator, and other additives as well as an arbitrary solvent are added to the pigment dispersion liquid. Stirring is performed for 20 minutes to 3 hours to form a homogeneous solution. After stirring, the obtained solution is filtered to obtain a negative photosensitive resin composition of the present invention.

As the disperser, for example, a ball mill, a bead mill, a sand grinder, a three-roll mill, or a high-speed impact mill can be cited. From the viewpoint of more efficient dispersion and finer dispersion, the disperser is preferably a bead mill. As the bead mill, for example, a co-ball mill, a basket mill, a pin mill, or a DYNO mill can be cited. As beads of the bead mill, for example, titania beads, zirconia beads, or zircon beads can be cited. The bead diameter of the bead mill is preferably 0.01 to 6 mm, more preferably 0.015 to 5 mm, and further preferably 0.03 to 3 mm. In the case where the primary particle diameter of the (C) benzofuranone based organic pigment having an amide structure and the particle diameter of secondary particles formed by aggregation of primary particles of the (C) benzofuranone based organic pigment having an amide structure are each several hundred nanometers or less, small beads of 0.015 to 0.1 mm are preferable. In this case, a bead mill that has a separator based on a centrifugal separation system which is capable of separating small beads and the pigment dispersion liquid is preferable. On the other hand, in the case where the (C) benzofuranone based organic pigment having an amide structure contains large particles of several hundred nanometers or greater, beads of 0.1 to 6 mm are preferable from the viewpoint of more efficient dispersion.

<Optical Density>

The optical density of the cured film obtained from the negative photosensitive resin composition of the present invention is preferably 0.3 or more, because external light reflection can be suppressed. In addition, when the optical density of the cured film is 5.0 or less, reflection from external light can be sufficiently suppressed and contrast and visibility can be improved without impairing the post-development pattern workability, which is preferable. When the optical density of the cured film is within the range mentioned above, the light blocking property of the cured film is high, and external light reflection can be sufficiently prevented, so that contrast and visibility can be improved. When the optical density of the cured film exceeds 4.0, since the light blocking property becomes too high, it is difficult to sufficiently cure the film by photolithography.

<Process that Uses Negative Photosensitive Resin Composition of Present Invention>

The cured film obtained from the negative photosensitive resin composition of the present invention can be suitably put to uses constituted of elements such as light-emitting elements and display elements, such as pixel-separating layers, color filters, and black matrixes of color filters of organic EL displays, black column spacers of liquid crystal displays, gate insulation films of semiconductors, interlayer insulation films of semiconductors, protection films for metal wiring, insulation films for metal wiring, or planarization films for TFTs. Among them, it is preferable to use the cured film for planarization films for TFTs or insulation films of an organic EL display, a liquid crystal display, or the like. If the cured film is used for both of them, external light reflection can be further prevented, and thus it is more preferable. In addition, from the viewpoint of improving the contrast, the insulation film is preferably a pixel-separating layer.

<Production Process for Organic EL Display>

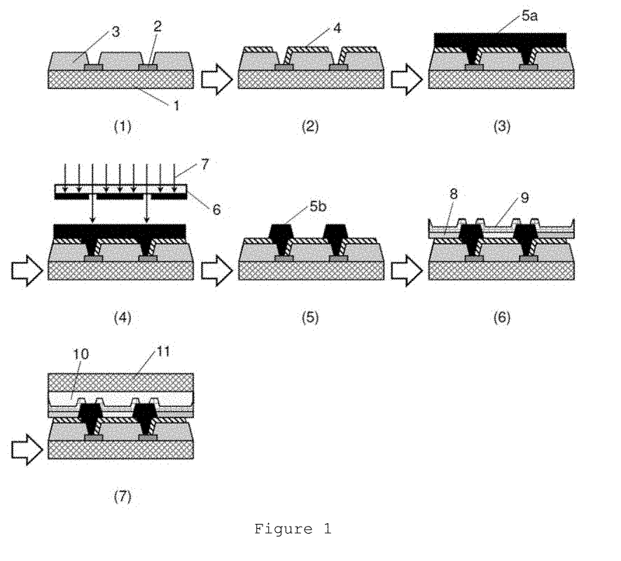

As a process that uses the negative photosensitive resin composition of the present invention, a process that uses a cured film of that composition as a light-blocking pixel-separating layer of an organic EL display is illustrated in FIG. 1 and will be described as an example. First, (1) thin-film transistors (hereinafter, “TFTs”) 2 are formed on a glass substrate 1, and a photosensitive material for a TFT planarization film is formed into a film, which is then pattern-processed by photolithography and subsequently thermally cured to form a cured film for TFT planarization 3. Next, (2) an alloy of magnesium and silver is sputtered to form a film, which is then pattern-processed by etching with photoresist to form a reflector electrode 4 as a first electrode. After that, (3) the negative photosensitive resin composition of the present invention is applied and prebaked to form a prebaked film 5a. Subsequently, (4) a chemical active ray 7 is applied via a mask 6 that has a desired pattern. Next, (5) after development and pattern processing, bleaching exposure and intermediate bake are performed as needed so as to carry out thermal cure. Thus, a cured pattern 5b having a desired pattern is formed as a light-blocking pixel-separating layer. After that, (6) an EL light-emitting material is subjected to vapor deposition via a mask to form a film. Thus, an EL light-emitting layer 8 is formed. ITO is sputtered to form a film, which is then pattern-processed by etching with photoresist to form a transparent electrode 9 as a second electrode. Next, (7) a photosensitive material for a planarization film is formed into a film, which is then pattern-processed by photolithography and then thermally cured to form a cured film for planarization 10. After that, a cover glass 11 is joined thereto to obtain an organic EL display that has the negative photosensitive resin composition of the present invention in a light-blocking pixel-separating layer.

<Production Process for Liquid Crystal Display>

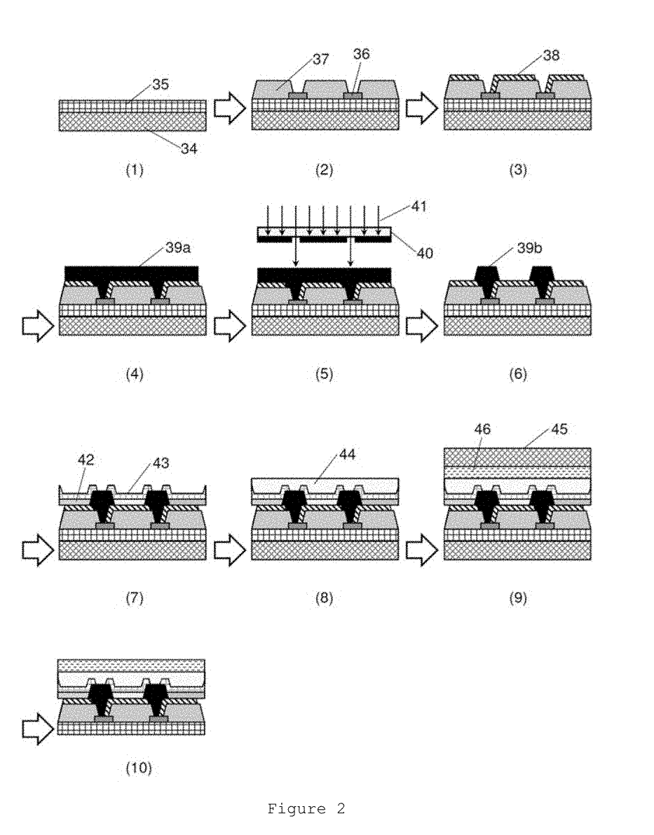

As another process that uses the negative photosensitive resin composition of the present invention, a process in which a cured film of the composition is used as a black column spacer (hereinafter, “BCS”) and a black matrix (hereinafter, “BM”) of a color filter of a liquid crystal display is illustrated in FIG. 2 and will be described as an example. First, (1) a backlight unit (hereinafter, “BLU”) 13 is formed on a glass substrate 12 to obtain a glass substrate 14 that includes a BLU.

Furthermore, (2) TFTs 16 are formed on another glass substrate 15. A photosensitive material for a TFT planarization film is formed into a film, which is then pattern-processed by photolithography and subsequently thermally cured to form a cured film for TFT planarization 17. Next, (3) ITO is sputtered to form a film, which is then pattern-processed by etching with photoresist to form a transparent electrode 18. On top of it, a planarization film 19 and an alignment layer 20 are formed. After that, (4) the negative photosensitive resin composition of the present invention is applied and prebaked to form a prebaked film 21a. Subsequently, (5) a chemical active ray 23 is applied via a mask 22 that has a desired pattern. Next, (6) after development and pattern processing, bleaching exposure and intermediate bake are performed as needed so as to carry out thermal cure. Thus, a cured pattern 21b having a desired pattern is formed as a BCS that has light blocking property so as to obtain a glass substrate 24 that has a BCS. Subsequently, (7) the foregoing glass substrate 14 and this glass substrate 24 are joined to obtain a glass substrate 25 that has a BLU and a BCS.

Furthermore, (8) a color filter 27 of three colors of red, green, and blue is formed on another glass substrate 26. Next, (9) in the same method as above, a cured pattern 28 having a desired pattern is formed as a BM that has light blocking property from the negative photosensitive resin composition of the present invention. After that, (10) a photosensitive material for planarization is formed into a film, which is then pattern-processed by photolithography and subsequently thermally cured to form a cured film for planarization 29, on which an alignment layer 30 is formed. Thus, a color filter substrate 31 is obtained. Subsequently, (11) the foregoing glass substrate 25 and this color filter substrate 31 are joined so that (12) a glass substrate 32 that has a BLU, a BCS, and a BM is obtained. Next, (13) a liquid crystal is injected to form a liquid crystal layer 33, so that a liquid crystal display that includes the negative photosensitive resin composition of the present invention in the BCS and the BM is obtained.

As described above, according to the production method for an organic EL display that uses the negative photosensitive resin composition of the present invention, it is possible to obtain a light-blocking cured film having high heat resistance which has been pattern-processed and contains polyimide and/or polybenzoxazole, leading to improvement in the yield of the production of organic EL displays and performance improvement and reliability improvement thereof.

A process using a non-photosensitive colored resin composition containing a polyamic acid as a conventional polyimide precursor has been very complicated. For example, in the case of obtaining a light-blocking cured pattern having a desired pattern, first, a non-photosensitive colored resin composition is formed into a film on a substrate. Then, a photoresist is formed on the film of the colored resin composition. In addition, when pattern processing is performed by photolithography, the photoresist and the colored resin composition of the lower layer are simultaneously pattern-processed at the time of alkaline development. After that, the photoresist is removed and thermally cured to obtain the light-blocking cured pattern having a desired pattern. In other words, it is necessary to use a photoresist to pattern-process the film of the colored resin composition, so that the number of steps increases in the process. In addition, in order to simultaneously pattern-process the photoresist and the colored resin composition of the lower layer, it is also required to control the dissolution speed of the photoresist and the colored resin composition.

On the other hand, according to the process that uses the negative photosensitive resin composition of the present invention, since the resin composition is photosensitive, direct pattern processing by photolithography is feasible, and the process is superior because a photoresist is not required. Therefore, in comparison with a conventional process, the number of steps can be reduced, so that improvement of productivity, process time reduction and takt time reduction can be achieved.

The cured film obtained from the negative photosensitive resin composition of the present invention is suitable as a display device having an EL light-emitting layer, a display device having a liquid crystal layer, and an insulation film of a display device having an EL light-emitting layer and a liquid crystal layer. As this display device, for example, an organic EL display or a liquid crystal display can be cited.

<Display Devices that Use Cured Films Obtained from Negative Photosensitive Resin Composition of Present Invention>

Furthermore, the negative photosensitive resin composition of the present invention makes it possible to obtain high resolution and a low-taper pattern shape and obtain a cured film excellent in high heat resistance. Therefore, the negative photosensitive resin composition of the present invention is suitable for uses in which high heat resistance and a low-taper pattern shape are required, such as insulation films of pixel-separating layers and the like of organic EL displays, and the like. Particularly, in uses in which problems attributable to heat resistance and pattern shape, such as defect or declined property of an element resulting from degassing due to thermal decomposition and a break of an electrode wiring due to a high-taper pattern shape, are assumed, the using of the cured film of the negative photosensitive resin composition of the present invention makes it possible to produce a highly reliable element with which the foregoing problems do not occur. Furthermore, since the cured film is excellent in light blocking property, it becomes possible to prevent visualization of electrode wirings or reduce external light reflection, so that contrast in image display can be improved. Therefore, by using the cured film obtained from the negative photosensitive resin composition of the present invention as a pixel-separating layer of an organic EL display, it is possible to improve contrast without a need to form a polarizing plate and a quarter-wavelength plate at the light extraction side of the light-emitting elements.

In a conventional organic EL display, a polarizing plate, a quarter wavelength plate, a reflection preventing layer, or the like is formed on the light extraction side of the light-emitting elements in order to reduce external light reflection. However, the phase of light output from the light-emitting element is changed by the quarter wavelength plate, the light is partially blocked by the polarizing plate, and only transmitted polarized light is output to the outside, so that the luminance of the organic EL display decreases.

On the other hand, according to an organic EL display using the cured film obtained from the negative photosensitive resin composition of the present invention, since the polarizing plate and the quarter wavelength plate are not used, it is possible to improve the luminance of the organic EL display.

In the organic EL display using the cured film obtained from the negative photosensitive resin composition of the present invention, since the polarizing plate and the quarter wavelength plate are not provided, the phase of the light output from the light-emitting element is not changed by the polarizing plate or the quarter wavelength plate, and the light is not partially blocked. When the display device using the cured film obtained from the composition has no liquid crystal layer, the light output from the display device is non-polarized, and the light is output to the outside while keeping the phase of the light output from the light-emitting element. On the other hand, when the display device using the cured film obtained from the composition has a liquid crystal layer, the light output from the display device is polarized light output from the liquid crystal layer, and the light output from the light-emitting element is output to the outside while keeping the phase changed in the liquid crystal layer.

<Flexible Organic EL Display Using Cured Film Obtained from Negative Photosensitive Resin Composition of Present Invention>

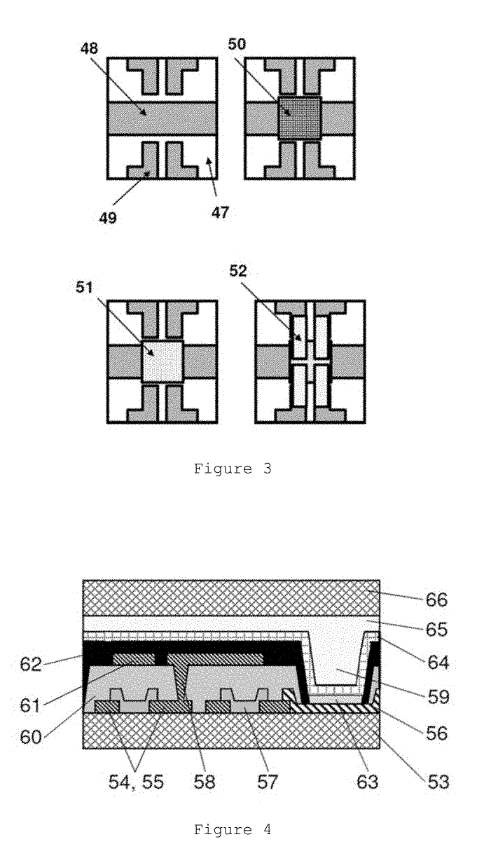

As a process that uses the negative photosensitive resin composition of the present invention, a process that uses a cured film of that composition as a light-blocking pixel-separating layer of a flexible organic EL display is illustrated in FIG. 3 and will be described as an example. First, (1) a polyimide (hereinafter referred to as “PI”) film substrate 35 is temporarily fixed on a glass substrate 34. Next, (2) an oxide TFT 36 is formed on the PI film substrate. A photosensitive material for a TFT planarization film is formed into a film, which is then pattern-processed by photolithography and subsequently thermally cured to form a cured film for TFT planarization 37. After that, (3) an alloy of magnesium and silver is sputtered to form a film, which is then pattern-processed by etching with photoresist to form a reflector electrode 38 as a first electrode. Next, (4) the negative photosensitive resin composition of the present invention is applied and prebaked to form a prebaked film 39a. Subsequently, (5) a chemical active ray 41 is applied via a mask 40 that has a desired pattern. After that, (6) after development and pattern processing, bleaching exposure and intermediate bake are performed as needed so as to carry out thermal cure. Thus, a cured pattern 39b having a desired pattern is formed as a flexible and light-blocking pixel-separating layer. Next, (7) an EL light-emitting material is subjected to vapor deposition via a mask to form a film. Thus, an EL light-emitting layer 42 is formed. ITO is sputtered to form a film, which is then pattern-processed by etching with photoresist to form a transparent electrode 43 as a second electrode. After that, (8) a photosensitive material for a planarization film is formed into a film, which is then pattern-processed by photolithography and subsequently thermally cured to form a cured film for planarization 44. Next, (9) a polyethylene terephthalate (hereinafter referred to as “PET”) film substrate 46 temporarily fixed to another glass substrate 45 is joined. After that, (10) the glass substrate 34 is peeled from the PI film substrate 35, and the glass substrate 45 is peeled from the PET film substrate 46, whereby a flexible organic EL display in which a flexible and light-blocking pixel-separating layer has the negative photosensitive resin composition of the present invention is obtained.

As described above, according to the production method for a flexible organic EL display that uses the negative photosensitive resin composition of the present invention, it is possible to obtain a light-blocking cured film having high heat resistance which has been pattern-processed and contains polyimide and/or polybenzoxazole, leading to improvement in the yield of the production of flexible organic EL displays and performance improvement and reliability improvement thereof.

Furthermore, the negative photosensitive resin composition of the present invention makes it possible to obtain high resolution and a low-taper pattern shape and obtain a cured film having flexibility. Thus, the cured film can be provided as a stacked structure on a flexible substrate, and it is suitable for uses in which a flexibility and a low-taper pattern shape are required, such as insulation films of pixel-separating layers and the like of flexible organic EL displays. In addition, since the cured film has high heat resistance, in uses in which problems attributable to heat resistance and pattern shape, such as defect or declined property of an element resulting from degassing due to thermal decomposition and a break of an electrode wiring due to a high-taper pattern shape, are assumed, the using of the cured film of the negative photosensitive resin composition of the present invention makes it possible to produce a highly reliable element with which the foregoing problems do not occur.

The flexible substrate is preferably a substrate mainly composed of carbon atoms. When the substrate is mainly composed of carbon atoms, flexibility can be imparted to the substrate. Since the cured film obtained from the negative photosensitive resin composition of the present invention is also mainly composed of carbon atoms, interaction of the cured film to the flexible substrate, which is the base substrate, is enhanced, and the adhesion with the substrate can be improved. In addition, it is possible to improve the flexibility of the cured film that follows the base substrate.

The content ratio of carbon atoms in the flexible substrate is preferably 20 mass % or more, more preferably 25 mass % or more, and further preferably 30 mass % or more. When the content ratio thereof is within the range mentioned above, the adhesion with the base substrate and the flexibility of the cured film can be improved. On the other hand, the content ratio thereof is preferably 100 mass % or less, more preferably 95 mass % or less, and further preferably 90 mass % or less. When the content ratio thereof is within the range mentioned above, the adhesion with the base substrate and the flexibility of the cured film can be improved.

<Step of Forming Film>

The production method for a display device which uses the negative photosensitive resin composition of the present invention includes (1) a step of forming a film of the resin composition on a substrate.

As a method for forming a film of the negative photosensitive resin composition of the present invention, for example, a method in which the film is formed by applying the resin composition on a substrate or a method in which the film is formed by applying the resin composition in a pattern on a substrate can be cited.

As the substrate, for example, a substrate in which an oxide having one or more species selected from indium, tin, zinc, aluminum, and gallium, a metal (molybdenum, silver, copper, aluminum, chromium, titanium, or the like), or CNT (Carbon Nano Tube) has been formed as an electrode or a wiring on glass, or the like can be used.

As the oxide having one or more species selected from indium, tin, zinc, aluminum, and gallium, for example, indium tin oxide (ITO), indium zinc oxide (IZO), aluminum zinc oxide (AZO), indium gallium zinc oxide (IGZO), or zinc oxide (ZnO) can be cited.

<Method in which Negative Photosensitive Resin Composition of Present Invention is Applied on Substrate>

As the method in which the negative photosensitive resin composition of the present invention is applied on a substrate, for example, micro gravure coating, spin coating, dip coating, curtain flow coating, roll coating, spraying coating, or slit coating can be cited. Although the coating film thickness varies depending on the coating method, the solid content concentration and viscosity of the resin composition, and the like, the resin composition is usually applied so that the film thickness subsequent to the application and the prebake is 0.1 to 30 μm.

It is preferable that after the negative photosensitive resin composition of the present invention is applied to a substrate, prebake be performed. The prebake may use an oven, a hot plate, infrared rays, a flash annealing apparatus, a laser annealing apparatus, or the like. It is preferable that the prebake temperature be 50 to 150° C. It is preferable that the prebake time be 30 seconds to several hours. It is also permissible to perform prebake in multiple steps of two or more steps, such as prebake at 80° C. for 2 minutes and then prebake at 120° C. for 2 minutes.

<Method in which Negative Photosensitive Resin Composition of Present Invention is Applied in Pattern Shape to Substrate>

As the method in which the negative photosensitive resin composition of the present invention is applied in a pattern shape on a substrate, for example, relief printing, intaglio printing, stencil printing, planographic printing, screen printing, ink jet printing, offset printing, or laser printing can be cited. Although the coating film thickness varies depending on the coating method, the solid content concentration or viscosity of the photosensitive resin composition of the present invention, and the like, the resin composition is usually applied so that the film thickness subsequent to the application and the prebake is 0.1 to 30 μm.

It is preferable that after the negative photosensitive resin composition of the present invention is applied in a pattern shape onto a substrate, prebake be performed. The prebake may use an oven, a hot plate, infrared rays, a flash annealing apparatus, a laser annealing apparatus, or the like. It is preferable that the prebake temperature be 50 to 150° C. It is preferable that the prebake time be 30 seconds to several hours. It is also permissible to perform prebake in multiple steps of two or more steps, such as prebake at 80° C. for 2 minutes and then prebake at 120° C. for 2 minutes.

<Step of Forming Pattern by Photolithography>

The production method for a display device which uses the negative photosensitive resin composition of the present invention includes (2) a step of applying a chemical active ray to the resin composition via a photomask and then forming a pattern of the composition by using an alkali solution.

As the method in which the negative photosensitive resin composition of the present invention which has been formed as a film on a substrate is pattern-processed, for example, a method in which the negative photosensitive resin composition is directly pattern-processed by photolithography or a method in which the negative photosensitive resin composition is pattern-processed by etching can be cited. From the viewpoint of reduction of the process time and improvement in productivity due to reduction of the number of steps, a method in which the coating film is directly pattern-processed by photolithography is preferable.

After the negative photosensitive resin composition of the present invention is applied on a substrate and formed as a film thereon by prebake, the film is exposed by using an exposure machine such as a stepper, a mirror projection mask aligner (MPA), or a parallel light mask aligner (PLA). The chemical active rays that are applied at the time of exposure, for example, ultraviolet rays, visible light rays, electron rays, X rays, KrF (248 nm wavelength) laser, ArF (193 nm wavelength) laser, or the like can be cited. It is preferable to use a j ray (313 nm wavelength), an i ray (365 nm wavelength), an h ray (405 nm wavelength), or a g ray (436 nm wavelength) of a mercury lamp. Furthermore, the amount of exposure is usually about 100 to 40,000 J/m² (10 to 4,000 mJ/cm²) (values from an i-ray illuminometer), and exposure can be carried out via a mask that has a desired pattern according to need.

After the exposure, post-exposure bake may be performed. By performing post-exposure bake, advantageous effects, such as improvement in post-development resolution or increase in the allowable range of development conditions, can be expected. The post-exposure bake can use an oven, a hot plate, infrared rays, a flash annealing apparatus, a laser annealing apparatus, or the like. The post-exposure bake temperature is preferably 50 to 180° C., and more preferably 60 to 150° C. The post-exposure bake time is preferably 10 seconds to several hours. When the post-exposure bake time is within the range mentioned above, reaction progresses favorably, so that the development time can sometimes be reduced.

After the exposure, development is carried out by using an automatic development device or the like. Since the negative photosensitive resin composition of the present invention has negative photosensitivity, unexposed portions, after development, are removed by the developing solution, so that a relief pattern can be obtained.

As the developing solution, an alkaline developer is commonly used. As the alkaline developer, for example, an organic alkali solution or an aqueous solution of a compound that exhibits alkalinity is preferable and, from the viewpoint of environmental aspects, an aqueous solution of a compound that exhibits alkalinity, that is, an alkali aqueous solution, is more preferable.

As the organic alkali solution or the compound that exhibits alkalinity, for example, 2-aminoethanol, 2-(dimethylamino) ethanol, 2-(diethylamino) ethanol, diethanol amine, methylamine, ethylamine, dimethylamine, diethylamine, triethylamine, (2-dimethylamino)ethyl acetate, (2-dimethylamino)ethyl (meth)acrylate, cyclohexylamine, ethylene diamine, hexamethylene diamine, ammonia, tetramethylammonium hydroxide, tetraethylammonium hydroxide, sodium hydroxide, potassium hydroxide, magnesium hydroxide, calcium hydroxide, barium hydroxide, sodium carbonate, or potassium carbonate can be cited.

As the developing solution, an organic solvent may be used. As the organic solvent, for example, the foregoing solvents, ethyl acetate, ethyl pyruvate, ethyl 3-methoxypropionate, ethyl 3-ethoxypropionate, N-methyl-2-pyrrolidone, dimethyl sulfoxide, or hexamethylphosphortriamide can be cited.

As the developing solution, a mixture solution containing both an organic solvent mentioned above and a poor solvent with respect to the negative photosensitive resin composition of the present invention may be used. As the poor solvent with respect to the negative photosensitive resin composition of the present invention, for example, water, methanol, ethanol, isopropyl alcohol, toluene, or xylene can be cited.

As the method for development, for example, methods in which a developing solution mentioned above is directly applied to the post-exposure film, or in which a developing solution mentioned above is radiated in the form of mist to the post-exposure film, or in which the post-exposure film is immersed in a developing solution mentioned above, or in which after being immersed in a developing solution mentioned above, the post-exposure film is irradiated with ultrasonic waves, or the like can be cited. It is preferable that the post-exposure film be kept in contact with the developing solution for 5 seconds to 10 minutes.

After development, it is preferable that the obtained relief pattern be washed with a rinse liquid. As the rinse liquid, water is preferable in the case where an alkali aqueous solution is used as the developing solution.

As the rinse liquid, it is permissible to use, for example, an aqueous solution of alcohol, such as ethanol or isopropyl alcohol, an aqueous solution of ester, such as propylene glycol monomethyl ether acetate, or an aqueous solution of a compound that exhibits acidity, such as carbonic acid gas, hydrochloric acid, or acetic acid.

As the rinse liquid, an organic solvent may be used. From the viewpoint of affinity with the developing solution, the organic solvent is preferably methanol, ethanol, isopropyl alcohol, ethyl acetate, ethyl lactate, ethyl pyruvate, propylene glycol monomethyl ether, propylene glycol monomethyl ether acetate, methyl 3-methoxypropionate, ethyl 3-ethoxypropionate, or 2-heptanone.

After a pattern of the negative photosensitive resin composition of the present invention is obtained by one or more kinds of methods selected from photolithography, etching, and film formation by coating in a pattern shape, bleaching exposure may be performed. By performing bleaching exposure, the post-thermosetting pattern shape can be arbitrarily controlled. Furthermore, the transparency of the cured film can be improved.

The bleaching exposure can use an exposure machine such as a stepper, a mirror projection mask aligner (MPA), or a parallel light mask aligner (PLA). As the chemical active rays applied at the time of bleaching exposure, for example, ultraviolet rays, visible light rays, electron rays, X rays, KrF (248 nm wavelength) laser, ArF (193 nm wavelength) laser, or the like can be cited. It is preferable to use a j ray (313 nm wavelength), an i ray (365 nm wavelength), an h ray (405 nm wavelength), or a g ray (436 nm wavelength) of a mercury lamp. Furthermore, the amount of exposure is usually about 500 to 500,000 J/m² (50 to 50,000 mJ/cm²) (values from an i-ray illuminometer). Exposure can be performed via a mask that has a desired pattern as needed.

After a pattern of the negative photosensitive resin composition of the present invention is obtained, intermediate bake may be performed. By performing intermediate bake, the post-thermosetting resolution will improve and the post-thermosetting pattern shape can be arbitrarily controlled. The intermediate bake can use an oven, a hot plate, infrared rays, a flash annealing apparatus, or a laser annealing apparatus. The intermediate bake temperature is preferably 50 to 250° C., and more preferably 70 to 220° C. The intermediate bake time is preferably 10 seconds to several hours. It is permissible to perform intermediate bake in multiple steps of two or more steps, such as intermediate bake at 100° C. for 5 minutes and then intermediate bake at 150° C. for 5 minutes.

<Step of Obtaining Cured Pattern by Thermosetting>

The production method for a display device that uses the negative photosensitive resin composition of the present invention includes (3) a step of obtaining a cured pattern of the composition by heating the pattern of the composition.

The thermosetting of the pattern of the negative photosensitive resin composition of the present invention formed as a film on a substrate can use an oven, a hot plate, infrared rays, a flash annealing apparatus, a laser annealing apparatus, or the like. By thermosetting the pattern of the negative photosensitive resin composition of the present invention by heating, the heat resistance of the cured film can be improved and a low-taper pattern shape can be obtained.

The thermosetting temperature is preferably 150° C. or greater, more preferably 200° C. or greater, and further preferably 250° C. or greater. When the thermosetting temperature is within the range mentioned above, the heat resistance of the cured film can be improved, and the post-thermosetting pattern shape can be made more of low taper. On the other hand, from the viewpoint of takt time reduction, the thermosetting temperature is preferably 500° C. or less, more preferably 450° C. or less, and further preferably 400° C. or less.

The thermosetting time is preferably 1 minute or longer, more preferably 5 minutes or longer, further preferably 10 minutes or longer, and particularly preferably 30 minutes or longer. When the thermosetting time is within the range mentioned above, the post-thermosetting pattern shape can be made more of low taper. On the other hand, from the viewpoint of takt time reduction, the thermosetting time is preferably 300 minutes or shorter, more preferably 250 minutes or shorter, further preferably 200 minutes or shorter, and particularly preferably 150 minutes or shorter. It is permissible to perform thermosetting in multiple steps of two or more steps, such as thermosetting at 150° C. for 30 minutes and then thermosetting at 250° C. for 30 minutes.

<Step of Pattern-Processing Transparent Electrode or Reflector Electrode>

The production method for a display device that uses the negative photosensitive resin composition of the present invention may include a step of pattern-processing a transparent electrode or a reflector electrode.

As the step of pattern-processing a transparent electrode or a reflector electrode, for example, a method in which pattern-processing is performed by etching can be cited.

After a transparent electrode or a reflector electrode is formed as a stacked structure on a substrate, photoresist is applied onto the electrode to form a film by the same method as described above. It is preferable that after being applied, the photoresist film be prebaked by the same method as described above.

By exposing and developing the photoresist in the same method after applying and prebaking the photoresist on the transparent electrode or the reflector electrode, a pattern of the photoresist can be formed on the electrode by photolithography.

After development, it is preferable that the obtained pattern be thermoset. By thermosetting the pattern, the chemical resistance and dry etching resistance of the cured film of the photoresist will improve, so that the pattern of the photoresist can be suitably used as an etching mask. The thermosetting can use an oven, a hot plate, infrared rays, a flash annealing apparatus, a laser annealing apparatus, or the like. It is preferable that the thermosetting temperature be 70 to 200° C. It is preferable that the thermosetting time be 30 seconds to several hours.

After the development and thermosetting, the transparent electrode or the reflector electrode, which is a layer below the pattern, is pattern-processed by etching with the pattern of the photoresist used as an etching mask.

As the method for etching, for example, wet etching that uses an etching liquid or dry etching that uses an etching gas can be cited. As the etching liquid, it is preferable to use an etching liquid or an organic solvent that is acid or alkaline.

<Method for Pattern-Processing by Wet Etching>

As the acid etching liquid, for example, a known etching liquid, such as a solution of a compound that exhibits acidity, such as hydrofluoric acid, hydrochloric acid, sulfuric acid, nitric acid, phosphoric acid, phosphorous acid, acetic acid, or oxalic acid, can be used.

As the alkaline etching liquid, an organic alkali solution or an aqueous solution of a compound that exhibits alkalinity is preferable.

As the organic alkali solution or the compound that exhibits alkalinity, for example, known solutions or compounds, such as 2-aminoethanol, 2-(diethylamino)ethanol, diethanol amine, triethylamine, ammonia, tetramethylammonium hydroxide, sodium hydroxide, potassium hydroxide, or potassium carbonate, can be used.

As the organic solvent, for example, known organic solvents, such as the foregoing solvents, diethylene glycol mono-n-butyl ether, ethyl 3-methoxypropionate, N-methyl-2-pyrrolidone, or isopropyl alcohol, can be used.

As the etching liquid, a mixture solution containing both an alkaline etching liquid and an organic solvent may be used.

As the method for wet etching, for example, methods in which the aforementioned etching liquid is directly applied to or the aforementioned etching liquid is radiated in the form of mist to a substrate in which a pattern of photoresist has been formed on a coating film of the photosensitive resin composition of the present invention, or in which a substrate in which a pattern of photoresist has been formed on a coating film of the photosensitive resin composition of the present invention is immersed in the aforementioned etching liquid, or in which a substrate in which a pattern of photoresist has been formed on a coating film of the photosensitive resin composition of the present invention is immersed in the aforementioned etching liquid and then irradiated with ultrasonic waves can be cited.

After wet etching, it is preferable that the transparent electrode or reflector electrode pattern-processed by wet etching be washed with a rinse liquid.

As the rinse liquid, for example, a known rinse liquid, such as water, methanol, ethanol, isopropyl alcohol, or ethyl lactate, can be used. In the case where an acidic etching liquid or an aqueous solution of a compound that exhibits alkalinity is used as the etching liquid, it is preferable that the rinse liquid be one that contains water.

<Method for Pattern-Processing by Dry Etching>

As the etching gas, for example, fluoromethane, difluoromethane, trifluoromethane, tetrafluoromethane, chlorofluoromethane, chlorodifluoromethane, chlorotrifluoromethane, dichlorofluoromethane, dichlorodifluoromethane, trichlorofluoromethane, sulfur hexafluoride, xenon difluoride, oxygen, ozone, argon, or fluorine can be cited.

As the method for dry etching, for example, reactive gas etching, in which a substrate in which a pattern of photoresist has been formed on a transparent electrode or a reflector electrode is exposed to the aforementioned etching gas, plasma etching, in which a substrate in which a pattern of photoresist has been formed on a transparent electrode or a reflector electrode is exposed to an etching gas ionized or radicalized by electromagnetic waves, reactive ion etching, in which a substrate in which a pattern of photoresist has been formed on a transparent electrode or a reflector electrode is subjected to collision with an etching gas ionized or radicalized by electromagnetic waves and accelerated by applying a bias, can be cited.

By removing the photoresist remaining on the transparent electrode or the reflector electrode after etching, a pattern of the transparent electrode or the reflector electrode can be obtained.

<Removal of Photoresist>

As the method for removing the photoresist, for example, removal with a resist stripping liquid or removal by ashing can be cited. As the resist stripping liquid, it is preferable that an organic solvent or a resist stripping liquid that is acid or alkaline be used, and known such solvents or liquids can be used. As the acidic resist stripping liquid, for example, an acidic solution or a mixture solution of an acidic solution and an oxidation agent can be cited, and known such liquids can be used. From the viewpoint of photoresist removing property, a mixture solution of an acidic solution and an oxidation agent is preferable.

As the gas for use for removal by ashing, a gas containing, as a component, one or more species selected from oxygen, ozone, argon, fluorine and chlorine can be cited. From the viewpoint of photoresist removing property, a gas containing oxygen or ozone as a component is preferable.

According to the negative photosensitive resin composition of the present invention, it becomes possible to prepare a coating liquid that makes it possible to obtain high resolution and a low-taper pattern shape, makes it possible to obtain a cured film excellent in heat resistance and light blocking property, and enables alkali development.

Furthermore, according to the negative photosensitive resin composition of the present invention, it becomes possible to obtain a cured film that can be suitably used for uses as a pixel-separating layer, a color filter, or a black matrix of a color filter in an organic EL display, a black column spacer in a liquid crystal display, a gate insulation film of a semiconductor, an interlayer insulation film of a semiconductor, a protection film for metal wiring, an insulation film for metal wiring, a planarization film for TFTs, and the like. Particularly, because of being excellent in light blocking property, the cured film is suitable as a pixel-separating layer and a black matrix of a color filter that have light blocking property in an organic EL display or a black column spacer in a liquid crystal display. Moreover, it becomes possible to obtain an element and a display device which include the foregoing cured film for the aforementioned uses.

Furthermore, according to the production method for a display device that uses the negative photosensitive resin composition of the present invention, it is possible to obtain a light-blocking cured film having high heat resistance which has been pattern-processed and contains polyimide and/or polybenzoxazole, leading to improvement in the yield of the production of organic EL displays and performance improvement and reliability improvement thereof. In addition, as compared with a method using a non-photosensitive colored resin composition containing a polyamic acid as a conventional polyimide precursor, the production method mentioned above is superior because direct pattern processing by photolithography is possible without photoresist. Therefore, in comparison with a conventional process, the number of steps can be reduced, so that improvement of productivity, process time reduction and takt time reduction can be achieved.

### EXAMPLES

The present invention will be described more concretely hereinafter with reference to examples and comparative examples. However, the present invention is not limited to scopes thereof. Incidentally, of the compounds used, those whose abbreviations are used will be named below.
4,4′-DAE: 4,4′-diaminodiphenyl ether
4-MOP: 4-methoxyphenol
6FDA: 3-(3,4-dicarboxyphenyl)hexafluoropropane dianhydride; 4,4′-hexafluoropropane-2,2-diyl-bis(1,2-phthalic anhydride)
6FDAc: 2,2-(3,4-dicarboxyphenyl)hexafluoropropane; 4,4′-hexafluoropropane-2,2-diyl-bis(1,2-phthalic acid)
AcrTMS: 3-acryloyloxypropyltrimethoxysilane
AIBN: 2,2′-azobis(isobutyronitrile)
BAHF: 2,2-bis(3-amino-4-hydroxyphenyl)hexafluoropropane
BAPF: 9,9-bis(3-amino-4-hydroxyphenyl)fluorene
BFE: 1,2-bis(4-formylphenyl)ethane
BGEF: 9,9-bis[4-(2-glycidoxyethoxy)phenyl]fluorene
BGPF: 9,9-bis(4-glycidoxyphenyl)fluorene
BHEF: 9,9-bis[4-(2-hydroxyethoxy)phenyl]fluorene
BHPF: 9,9-bis(4-hydroxyphenyl)fluorene
Bis-A-AF: 2,2-bis(4-aminophenyl)hexafluoropropane
Bk-S0084: “PALIOGEN” (registered trademark) BLACK S0084 (made by BASF, a perylene based black pigment having a primary particle diameter of 50 to 100 nm)
Bk-S0100CF: “IRGAPHOR” (registered trademark) BLACK S0100CF (made by BASF, a benzofuranone based black pigment having a primary particle diameter of 40 to 80 nm)
Bk-TH-807: “NUBIAN” (registered trademark) BLACK TH-807 (made by Orient Chemical Industries, Co., Ltd.; an azine-type black dye)
BnMA: benzyl methacrylate
BSAA: 3′-bis[4-(3,4-dicarboxyphenoxy)phenyl]propane dianhydride
BZAc: benzoic acid
cyEpoTMS: 2-(3,4-epoxycyclohexyl)ethyltrimethoxysilane
DBA: dibenzylamine
D.BYK-167: “DISPERBYK” (registered trademark)-167 (made by BYK Japan KK, a dispersant having an amine value)
D.Y.201: C. I. Disperse Yellow 201
DETX-S: “KAYACURE” (registered trademark) DETX-S(made by Nippon Kayaku Co., Ltd.; 2,4-diethylthioxanthone)
DFA: N,N-dimethylformamide dimethyl acetal
DMeDMS: dimethyldimethoxysilane
DMF: N,N-dimethylformamide
DPHA: “KAYARAD” (registered trademark) DPHA (made by Nippon Kayaku Co., Ltd.; dipentaerythritol hexaacrylate)
ED-900: “JEFFAMINE” (registered trademark) ED-900 (made by HUNTSMAN Corporation; a diamine having an oxyalkylene structure)
GMA: glycidyl methacrylate
HCl: hydrochloric acid
HFHA: N,N′-bis[5,5′-hexafluoropropan-2,2-diyl-bis(2-hydroxyphenyl)]bis(3-aminobenzoic acid amide)
ICl: iodine monochloride
IGZO: indium gallium zinc oxide
ITO: indium tin oxide
KOH: potassium hydroxide
KI: potassium iodide
MAA: methacrylic acid
MAP: 3-amino phenol; meta-aminophenol
MBA: 3-methoxy-n-butyl acetate
MeTMS: methyltrimethoxysilane
MgAg: magnesium silver
MT-PE1: “Karenz MT”-PE1 (made by Showa Denko K. K.; pentaerythritol tetrakis (3-mercaptobutyrate))
NA: 5-norbornene-2,3-dicarboxylic anhydride; nadic anhydride
NapTMS: 1-naphthyltrimethoxysilane
Na₂S203: thiosodium sulfate
NCI-831: “ADEKAARKLS” (registered trademark) NCI-831 (made by ADEKA Corporation;
1-(9-ethyl-6-nitro-9H-carbazol-3-yl)-1-[2-methyl-4-(1-methoxypropane-2-yloxy)phenyl]methanone-1-(O-acetyl)oxime)
NMP: N-methyl-2-pyrrolidone
ODPA: bis(3,4-dicarboxyphenyl)ether dianhydride; oxydiphthalic dianhydride
ODPAc: bis(3,4-dicarboxyphenyl)ether; oxydiphthalic acid
P.B.15:6: C.I. Pigment Blue 15:6
P.R.254: C.I. Pigment Red 254
P.Y.139: C.I. Pigment Yellow 139
PA-5600: “NUBIAN” (registered trademark) BLUE PA-5600 (made by Orient Chemical Industries, Co., Ltd.; a blue dye)
PET: polyethylene terephthalate
PGDA: propylene glycol diacetate
PGMEA: propylene glycol monomethyl ether acetate
PHA: phthalic anhydride
PhTMS: phenyltrimethoxysilane
PI: polyimide
S-20000: “SOLSPERSE” (registered trademark) 20000 (made by Lubrizol; a polyether based dispersant)
SiDA: 1,3-bis(3-aminopropyl)tetramethyl disiloxane
S.B.63: C. I. Solvent Blue 63
S.R.18: C. I. Solvent Red 18
STR: styrene
TCDM: tricyclo[5.2.1.0^{2,6}]decane-8-yl methacrylate; dimethylol-tricyclodecane dimethacrylate
TFEMA: (2,2,2-trifluoro)ethyl methacrylate
TFMB: 2,2′-bis(trifluoromethyl)-4,4′-diaminobiphenyl
TFPrTMS: 3,3,3-trifluoropropyltrimethoxysilane
THF: tetrahydrofuran
TMOS: tetramethoxysilane
TMSSucA: 3-trimethoxysilylpropyl succinic anhydride
TPK-1227: carbon black of which the surface is treated so as to introduce a sulfonic acid group thereto (made by CABOT Corporation)
TrisP-PA: 1-bis(4-hydroxyphenyl)-1-[4-[1-(4-hydroxyphenyl)-1-methyl ethyl]phenyl]ethane (made by Honshu Chemical Industry Co., Ltd.)

### Synthesis Example (A)

18.31 g (0.05 mol) of BAHF, 17.4 g (0.3 mol) of propylene oxide and 100 mL of acetone were weighed in a three-necked flask and were dissolved. A solution prepared by dissolving 20.41 g (0.11 mol) of 3-nitrobenzoyl chloride in 10 mL of acetone was dropped thereto. After completion of the dropping, the mixture was allowed to react at −15° C. for 4 hours, and then the temperature was returned to room temperature. A precipitated white solid was filtered and vacuum dried at 50° C. The obtained solid of 30 g was placed in a 300 mL stainless steel autoclave and dispersed in 250 mL of 2-methoxyethanol, and 2 g of 5% palladium-carbon was added. Hydrogen was introduced here with a balloon and reacted at room temperature for 2 hours. Two hours later, the fact that the balloon no longer shrank was confirmed. After the termination of the reaction, a palladium compound as a catalyst was removed by filtration, followed by vacuum distillation and concentration, affording a hydroxy group-containing diamine compound (HFHA) having the following structure.

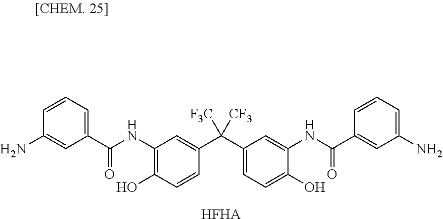 [SMILES: Nc1cccc(C(=O)Nc2cc(C(c3ccc(O)c(NC(=O)c4cccc(N)c4)c3)(C(F)(F)F)C(F)(F)F)ccc2O)c1 ; "HFHA"]

### Synthesis Example (B) Synthesis of Compound (QD-1) Having Naphthoquinone Diazide Structure Exceeding 0

In a dried nitrogen gas stream, 21.23 g (0.05 mol) of TrisP-PA and 37.62 g (0.14 mol) of 5-naphthoquinone diazide sulfonic acid chloride were weighed and dissolved in 450 g of 1,4-dioxane in a three-necked flask, and the temperature was adjusted to room temperature. A mixture solution of 50 g of 1,4-dioxane and 15.58 g (0.154 mol) of triethylamine was dropped into this while stirring was being performed so that the temperature in the system did not become 35° C. or greater. After the dropping, the mixture solution was stirred at 30° C. for 2 hours. After the stirring, the precipitated triethylamine salt was removed by filtration and then the filtrate was put into water and stirred. A precipitated solid precipitate was obtained by filtration. The obtained solid was dried by desiccation under reduced pressure to obtain a compound (QD-1) having a naphthoquinone diazide structure which was the following structure.

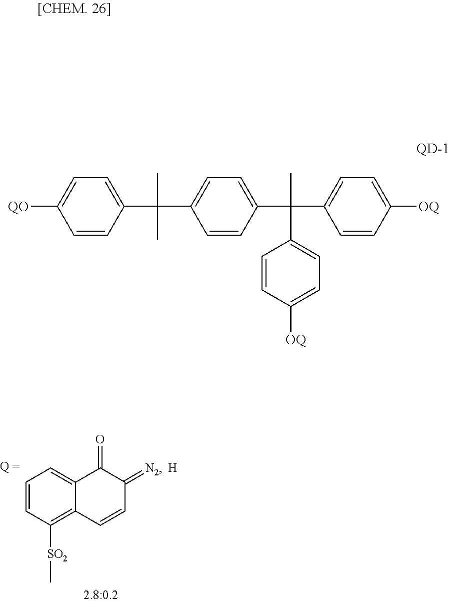

### Synthesis Example 1 Synthesis of Polyimide (PI-1)

In a dried nitrogen gas stream, 31.13 g (0.085 mol, i.e., 77.3 mol % relative to the structural unit originating from the entire amines and their derivatives) of BAHF, 6.21 g (0.0050 mol, i.e., 4.5 mol % relative to the structural unit originating from the entire amines and their derivatives) of SiDA, 2.18 g (0.020 mol, i.e., 9.5 mol % relative to the structural unit originating from the entire amines and their derivatives) of MAP as an end-capping agent, and 150.00 g of NMP were weighed and dissolved in a three-necked flask. Into this, a solution in which 31.02 g (0.10 mol, i.e., 100 mol % relative to the structural unit originating from the entire carboxylic acids and their derivatives) of ODPA was dissolved in 50.00 g of NMP was added. Then, stirring was performed at 20° C. for 1 hour and then stirring was performed at 50° C. for 4 hours. After that, 15 g of xylene was added, and stirring was performed at 150° C. for 5 hours while the azeotropy of water with xylene was allowed to occur. After the reaction ended, the reaction solution was put into 3L of water, and precipitated solid precipitate was obtained by filtration. The obtained solid was washed with water three times and then dried for 24 hours by a vacuum dryer at 80° C. to obtain a polyimide (PI-1)

### Synthesis Examples 2 to 11 Synthesis of Polyimides (PI-2) to (PI-11)

Polymerization was performed in the same manner as in Synthesis Example 1 at the ratio shown in Table 1 to obtain polyimide (PI-2) to polyimide (PI-11)

### Synthesis Example 12 Synthesis of Polybenzoxazole (PBO-1)

34.79 g (0.095 mol, i.e., 95.0 mol % relative to the structural unit originating from the entire amines and their derivatives) of BAHF, 1.24 g (0.0050 mol, i.e., 5.0 mol % relative to the structural unit originating from the entire amines and their derivatives) of SiDA, and 75.00 g of NMP were weighed and dissolved in a 500-mL round-bottom flask equipped with a toluene-filled Dean-Stark water separator and a cooling pipe. Into this, a solution in which 19.06 g (0.080 mol, i.e., 66.7 mol % of the structural unit originating from the entire carboxylic acids and their derivatives) of BFE and 6.57 g (0.040 mol, i.e., 33.3 mol % relative to the structural unit originating from the entire carboxylic acids and their derivatives) of NA as an end-capping agent were dissolved in 25.00 g of NMP was added. Then, stirring was performed at 20° C. for 1 hour and subsequently stirring was performed at 50° C. for 1 hour. After that, in a nitrogen atmosphere, heating and stirring was performed at 200° C. or higher for 10 hours, conducting dehydration reaction. After the reaction ended, the reaction solution was put into 3L of water, and precipitated solid precipitate was obtained by filtration. The obtained solid was washed with water three times and dried by a vacuum dryer at 80° C. for 24 hours and washed with water three times and dried by the vacuum dryer at 80° C. for 24 hours to obtain a polybenzoxazole (PBO-1).

### Synthesis Examples 13 and 14 Synthesis of Polybenzoxazole (PBO-2) and Polybenzoxazole (PBO-3)

Polymerization was performed in the same manner as in Synthesis Example 12 at the ratio shown in Table 2 to obtain polybenzoxazole (PBO-2) and polybenzoxazole (PBO-3).

### Synthesis Example 15 Synthesis of Polyimide Precursor (PIP-1)

In a dried nitrogen gas stream, 31.02 g (0.10 mol, i.e., 100 mol % relative to the structural unit originating from the entire carboxylic acids and their derivatives) of ODPA and 150 g of NMP were weighed and dissolved in a three-necked flask. Into this, a solution in which 25.64 g (0.070 mol, i.e., 56.0 mol % relative to the structural unit originating from the entire amines and their derivatives) of BAHF and 6.21 g (0.0050 mol, i.e., 4.0 mol % relative to the structural unit originating from the entire amines and their derivatives) of SiDA were dissolved in 50 g of NMP was added. Then, stirring was performed at 20° C. for 1 hour, and subsequently stirring was performed at 50° C. for 2 hours. Next, as an end-capping agent, a solution in which 5.46 g (0.050 mol, i.e., 40.0 mol % relative to the structural unit originating from the entire amines and their derivatives) of MAP was dissolved in 15 g of NMP was added. Then, stirring was performed at 50° C. for 2 hours. After that, a solution in which 23.83 g (0.20 mol) of DFA was dissolved in 15 g of NMP was dropped over a period of 10 minutes. After the dropping ended, stirring was performed at 50° C. for 3 hours. After the reaction ended, the reaction solution was cooled to room temperature. Then, the reaction solution was put into 3L of water, and precipitated solid precipitate was obtained by filtration. The obtained solid was washed with water three times and was dried by a vacuum dryer at 80° C. for 24 hours to obtain a polyimide precursor (PIP-1).

### Synthesis Examples 16 to 25 Synthesis of Polyimide Precursors (PIP-2) to (PIP-11)

Polymerization was performed in the same manner as in Synthesis Example 15 at the ratio shown in Table 3 to obtain a polyimide precursor (PIP-2) to a polyimide precursor (PIP-11).

### Synthesis Example 26 Synthesis of Polybenzoxazole Precursor (PBOP-1)

34.79 g (0.095 mol, i.e., 95.0 mol % relative to the structural unit originating from the entire amines and their derivatives) of BAHF, 1.24 g (0.0050 mol, i.e., 5.0 mol % relative to the structural unit originating from the entire amines and their derivatives) of SiDA, and 70.00 g of NMP were weighed and dissolved in a 500-mL round-bottom flask equipped with a toluene-filled Dean-Stark water separator and a cooling pipe. Into this, a solution in which 19.06 g (0.080 mol, i.e., 66.7 mol % relative to structural unit originating from the entire carboxylic acids and their derivatives) of BFE was dissolved in 20.00 g of NMP was added. Then, stirring was performed at 20° C. for 1 hour, and subsequently stirring was performed at 50° C. for 2 hours. Next, as an end-capping agent, a solution in which 6.57 g (0.040 mol, i.e., 33.3 mol % relative to the structural unit originating from the entire carboxylic acids and their derivatives) of NA was dissolved in 10 g of NMP was added. Then, stirring was performed at 50° C. for 2 hours. After that, stirring was performed at 100° C. for 2 hours in a nitrogen atmosphere. After the reaction ended, the reaction solution was put into 3L of water, and precipitated solid precipitate was obtained by filtration. The obtained solid was washed with water three times and dried by a vacuum dryer at 80° C. for 24 hours and washed with water three times and dried by the vacuum dryer at 80° C. for 24 hours to obtain a polybenzoxazole precursor (PBOP-1).

### Synthesis Examples 27 and 28 Synthesis of Polybenzoxazole Precursor (PBOP-2) and Polybenzoxazole Precursor (PBOP-3)

Polymerization was performed in the same manner as in Synthesis Example 12 at the ratio shown in Table 4 to obtain a polybenzoxazole precursor (PBOP-2) and a polybenzoxazole precursor (PBOP-3).

The compositions of Synthesis Examples 1 to 28 are collectively shown in Tables 1 to 4.

TABLE 1

| | | | | | | | | Structural unit | Structural unit |
|---|---|---|---|---|---|---|---|---|---|
| | | | | | | | | originating from | originating from |
| | | | | | | | | monomer having | monomer having |
| | | | | | | | | fluorine atom in | fluorine atom in |
| | | | | | | | | structural unit | structural unit |
| | | Monomer [molar ratio] | | | | | | originating from | originating from |
| | | | | | | | End- | entire carboxylic | entire amine |
| | | Tetracarboxylic acid | | | | | capping | acid derivatives | derivatives |
| | Polymer | and its derivative | | Diamine and its derivative | | | agent | [mol %] | [mol %] |
| Synthesis | Polyimide | ODPA | — | BAHF | — | SiDA | MAP | 0.0 | 77.3 |
| Example 1 | (PI-1) | (100) | | (85) | | (5) | (20) | | |
| Synthesis | Polyimide | ODPA | — | BAHF | HFHA | SiDA | MAP | 0.0 | 77.3 |
| Example 2 | (PI-2) | (100) | | (35) | (50) | (5) | (20) | | |
| Synthesis | Polyimide | ODPA | — | BAHF | Bis-A-AF | SiDA | MAP | 0.0 | 77.3 |
| Example 3 | (PI-3) | (100) | | (35) | (50) | (5) | (20) | | |
| Synthesis | Polyimide | ODPA | — | BAHF | TFMB | SiDA | MAP | 0.0 | 77.3 |
| Example 4 | (PI-4) | (100) | | (35) | (50) | (5) | (20) | | |
| Synthesis | Polyimide | ODPA | 6FDA | BAHF | — | SiDA | MAP | 40.0 | 77.3 |
| Example 5 | (PI-5) | (60) | (40) | (85) | | (5) | (20) | | |
| Synthesis | Polyimide | ODPA | 6FDA | BAHF | — | SiDA | MAP | 60.0 | 77.3 |
| Example 6 | (PI-6) | (40) | (60) | (85) | | (5) | (20) | | |
| Synthesis | Polyimide | — | 6FDA | BAHF | — | SiDA | MAP | 100.0 | 77.3 |
| Example 7 | (PI-7) | | (100) | (85) | | (5) | (20) | | |
| Synthesis | Polyimide | ODPA | — | BAHF | 4,4′-DAE | SiDA | MAP | 0.0 | 54.5 |
| Example 8 | (PI-8) | (100) | | (60) | (25) | (5) | (20) | | |
| Synthesis | Polyimide | ODPA | — | BAHF | ED-900 | SiDA | MAP | 0.0 | 54.5 |
| Example 9 | (PI-9) | (100) | | (60) | (25) | (5) | (20) | | |
| Synthesis | Polyimide | ODPA | — | BAHF | BAPF | SiDA | MAP | 0.0 | 36.4 |
| Example 10 | (PI-10) | (100) | | (40) | (45) | (5) | (20) | | |
| Synthesis | Polyimide | ODPA | BSAA | BAHF | — | SiDA | MAP | 0.0 | 77.3 |
| Example 11 | (PI-11) | (50) | (50) | (85) | | (5) | (20) | | |

TABLE 2

| | | | | | | | | Structural unit | Structural unit |
|---|---|---|---|---|---|---|---|---|---|
| | | | | | | | | originating from | originating from |
| | | Monomer [molar ratio] | | | | | | monomer having | monomer having |
| | | Dicarboxylic | | | | | | fluorine atom in | fluorine atom in |
| | | acid and | | | | | | structural unit | structural unit |
| | | its derivative | | Bisaminophenol compound and | | | | originating from | originating from |
| | | diformyl | | its derivative | | | End- | entire carboxylic | entire amine |
| | | compound and | | dihydroxydiamine and its | | | capping | acid derivatives | derivatives |
| | Polymer | its derivative | | derivative | | | agent | [mol %] | [mol %] |
| Synthesis | Polybenzoxazole | BFE | NA | BAHF | — | SiDA | — | 0.0 | 95.0 |
| Example 12 | (PBO-1) | (80) | (40) | (95) | | (5) | | | |
| Synthesis | Polybenzoxazole | BFE | NA | BAHF | BAPF | SiDA | — | 0.0 | 60.0 |
| Example 13 | (PBO-2) | (80) | (40) | (60) | (35) | (5) | | | |
| Synthesis | Polybenzoxazole | BFE | NA | BAHF | BAPF | SiDA | — | 0.0 | 40.0 |
| Example 14 | (PBO-3) | (80) | (40) | (40) | (55) | (5) | | | |

TABLE 3

| | | | | | | | | Structural unit | Structural unit |
|---|---|---|---|---|---|---|---|---|---|
| | | | | | | | | originating from | originating from |
| | | | | | | | | monomer having | monomer having |
| | | | | | | | | fluorine atom in | fluorine atom in |
| | | | | | | | | structural unit | structural unit |
| | | Monomer [molar ratio] | | | | | | originating from | originating from |
| | | | | | | | End- | entire carboxylic | entire amine |
| | | Tetracarboxylic acid | | | | | capping | acid derivatives | derivatives |
| | Polymer | and its derivative | | Diamine and its derivative | | | agent | [mol %] | [mol %] |
| Synthesis | Polyimide precursor | 6FDA | — | BAHF | — | SiDA | MAP | 100.0 | 56.0 |
| Example 15 | (PIP-1) | (100) | | (70) | | (5) | (50) | | |
| Synthesis | Polyimide precursor | 6FDA | — | BAHF | HFHA | SiDA | MAP | 100.0 | 56.0 |
| Example 16 | (PIP-2) | (100) | | (40) | (30) | (5) | (50) | | |
| Synthesis | Polyimide precursor | 6FDA | — | BAHF | Bis-A-AF | SiDA | MAP | 100.0 | 56.0 |
| Example 17 | (PIP-3) | (100) | | (40) | (30) | (5) | (50) | | |
| Synthesis | Polyimide precursor | 6FDA | — | BAHF | TFMB | SiDA | MAP | 100.0 | 56.0 |
| Example 18 | (PIP-4) | (100) | | (40) | (30) | (5) | (50) | | |
| Synthesis | Polyimide precursor | 6FDA | ODPA | BAHF | — | SiDA | MAP | 60.0 | 56.0 |
| Example 19 | (PIP-5) | (60) | (40) | (70) | | (5) | (50) | | |
| Synthesis | Polyimide precursor | 6FDA | ODPA | BAHF | — | SiDA | MAP | 40.0 | 56.0 |
| Example 20 | (PIP-6) | (40) | (60) | (70) | | (5) | (50) | | |
| Synthesis | Polyimide precursor | 6FDA | — | BAHF | — | SiDA | MAP | 100.0 | 77.3 |
| Example 21 | (PIP-7) | (100) | | (85) | | (5) | (20) | | |
| Synthesis | Polyimide precursor | 6FDA | — | BAHF | 4,4′-DAE | SiDA | MAP | 100.0 | 54.5 |
| Example 22 | (PIP-8) | (100) | | (60) | (25) | (5) | (20) | | |
| Synthesis | Polyimide precursor | 6FDA | — | BAHF | ED-900 | SiDA | MAP | 100.0 | 54.5 |
| Example 23 | (PIP-9) | (100) | | (60) | (25) | (5) | (20) | | |
| Synthesis | Polyimide precursor | 6FDA | — | BAHF | BAPF | SiDA | MAP | 100.0 | 36.4 |
| Example 24 | (PIP-10) | (100) | | (40) | (45) | (5) | (20) | | |
| Synthesis | Polyimide precursor | 6FDA | BSAA | BAHF | — | SiDA | MAP | 70.0 | 77.3 |
| Example 25 | (PIP-11) | (70) | (30) | (85) | | (5) | (20) | | |

TABLE 4

| | | | | | | | | Structural unit | Structural unit |
|---|---|---|---|---|---|---|---|---|---|
| | | | | | | | | originating from | originating from |
| | | | | | | | | monomer having | monomer having |
| | | | | | | | | fluorine atom in | fluorine atom in |
| | | Monomer [molar ratio] | | | | | | structural unit | structural unit |
| | | Dicarboxylic acid | | Bisaminophenol compound | | | | originating from | originating from |
| | | and its derivative | | and its derivative | | | End- | entire carboxylic | entire amine |
| | | diformyl compound | | dihydroxydiamine and its | | | capping | acid derivatives | derivatives |
| | Polymer | and its derivative | | derivative | | | agent | [mol %] | [mol %] |
| Synthesis | Polybenzoxazole | BFE | NA | BAHF | — | SiDA | — | 0.0 | 95.0 |
| Example 26 | precursor (PBOP-1) | (80) | (40) | (95) | | (5) | | | |
| Synthesis | Polybenzoxazole | BFE | NA | BAHF | BAPF | SiDA | — | 0.0 | 60.0 |
| Example 27 | precursor (PBOP-2) | (80) | (40) | (60) | (35) | (5) | | | |
| Synthesis | Polybenzoxazole | BFE | NA | BAHF | BAPF | SiDA | — | 0.0 | 40.0 |
| Example 28 | precursor (PBOP-3) | (80) | (40) | (40) | (55) | (5) | | | |

### Synthesis Example 46 Synthesis of Dispersant (DP1-1)

50 g of JEFFAMINE (registered trademark) M-2005 (made by Huntsman Corporation), 7 g of GIPE (made by Tokyo Chemical Industry Co., Ltd.) and 51 g of PMA-P (made by NH Neochem Co., Ltd.) were added to a round bottom flask and heated and stirred at 80° C. for 2 hours. The product obtained had an Mw of 2200 and an amine value of 26 mgKOH/g.

### Synthesis Example 47 Synthesis of Dispersant (DP1-2)

50 g of JEFFAMINE (registered trademark) M-2007 (made by Huntsman Corporation), 7 g of GIPE (made by Tokyo Chemical Industry Co., Ltd.) and 51 g of PMA-P (made by NH Neochem Co., Ltd.) were added to a round bottom flask and heated and stirred at 80° C. for 2 hours. The product obtained had an Mw of 2000 and an amine value of 29.

### Synthesis Example 48 Synthesis of Dispersant (DP1-3)

50 g of JEFFAMINE (registered trademark) D-4000 (made by Huntsman Corporation), 14 g of GIPE (made by Tokyo Chemical Industry Co., Ltd.) and 51 g of PMA-P (made by NH Neochem Co., Ltd.) were added to a round bottom flask and heated and stirred at 80° C. for 2 hours. The product obtained had an Mw of 4300 and an amine value of 13.

### Synthesis Example 49 Synthesis of Dispersant (DP1-4)

7 g of JEFFAMINE (registered trademark) EDR-148 (made by Huntsman Corporation), 23 g of GIPE (made by Tokyo Chemical Industry Co., Ltd.) and 30 g of PMA-P (made by NH Neochem Co., Ltd.) were added to a round bottom flask and heated and stirred at 80° C. for 2 hours. The product obtained had an Mw of 3800 and an amine value of 15.

### Preparation Example 1 Preparation of Pigment Dispersion Liquid (Bk-1)

184.0 g of a 30-mass % MBA solution of the polyimide (PI-1) obtained in Synthesis Example 1 as a resin, 653.2 g of MBA as a solvent, 82.8 g of Bk-S0100CF as a pigment, and g of DP1-1 as a dispersant were weighed and mixed, and then stirred for 20 minutes by using a high-speed disperser (Homodisper Model 2.5, made by PRIMIX Corporation) to obtain a tentative dispersion liquid. An Ultra Apex Mill (UAM-015, made by KOTOBUKI KOGYOU CO., LTD) having a centrifugal separation separator filled 75% with a Ø0.10-mm ground zirconia ball (Torayceram, made by Toray Industries, Inc.) as ceramic beads for pigment dispersion was supplied with the obtained tentative dispersion liquid, which was then processed at a rotor peripheral speed of 8.0 m/s for 3 hours to obtain a pigment dispersion liquid (Bk-1) with a solid content concentration of 15 mass % and a pigment/resin/dispersant=60/30/10 (mass ratio) The pigment in the obtained pigment dispersion liquid had a number average particle diameter of 50 nm.

BYK-9076 (amine value: 44 mgKOH/g, acid value: 38 mgKOH/g) was used as (DP2-1), and “DISPERBYK” (registered trademark)-2164 (amine value: 14 mgKOH/g) was used as (DP2-2)

Pigments were dispersed at the ratios mentioned in Table 5 in the same manner as in Preparation Example 1 to obtain pigment dispersion liquids (Bk-2) to (Bk-14) and pigment dispersion liquids (Bk-15) to (Bk-19).

The compositions of Preparation Examples 1 to 19 are collectively shown in Table 5.

TABLE 5

| | | Composition [wt %] | | | | | | |
|---|---|---|---|---|---|---|---|---|
| | | Solid content | | (B) Dispersant | | | | (C) Organic |
| | | concentration | (A) Alkali- | | | | (B1):(B2) | Pigment Having |
| | Dispersion liquid | (%) | soluble Resin | (B1) | (B2) | (B3) | or (B3) | Amide Structure |
| Preparation | Pigment dispersion | 15 | Polyimide (PI-1) (30) | DP1-1(5) | DP2-1 (5) | None | 5:5 | S0100CF(60) |
| Example 1 | liquid (Bk-1) | | | | | | | |
| Preparation | Pigment dispersion | 15 | Polyimide (PI-1) (30) | DP1-1(5) | None | DP2-2(5) | 5:5 | S0100CF(60) |
| Example 2 | liquid (Bk-2) | | | | | | | |
| Preparation | Pigment dispersion | 15 | Polyimide (PI-1) (30) | DP1-2(5) | None | DP2-2(5) | 5:5 | S0100CF(60) |
| Example 3 | liquid (Bk-3) | | | | | | | |
| Preparation | Pigment dispersion | 15 | Polyimide (PI-1) (30) | DP1-1(10) | None | None | 10:0 | S0100CF(60) |
| Example 4 | liquid (Bk-4) | | | | | | | |
| Preparation | Pigment dispersion | 15 | Polyimide precursor | DP1-1(10) | None | None | 10:0 | S0100CF(60) |
| Example 5 | liquid (Bk-5) | | (PIP-1) (30) | | | | | |
| Preparation | Pigment dispersion | 15 | Polybenzoxazole (PBO-1) | DP1-1(10) | None | None | 10:0 | S0100CF(60) |
| Example 6 | liquid (Bk-6) | | (30) | | | | | |
| Preparation | Pigment dispersion | 15 | Polybenzoxazole precursor | DP1-1(10) | None | None | 10:0 | S0100CF(60) |
| Example 7 | liquid (Bk-7) | | (PBPO-1) (30) | | | | | |
| Preparation | Pigment dispersion | 15 | Polyimide (PI-1) (30) | DP1-2(5) | DP2-1(5) | None | 5:5 | S0100CF(60) |
| Example 8 | liquid (Bk-8) | | | | | | | |
| Preparation | Pigment dispersion | 15 | Polyimide (PI-1) (30) | DP1-1(9) | DP2-1(1) | None | 9:1 | S0100CF(60) |
| Example 9 | liquid (Bk-9) | | | | | | | |
| Preparation | Pigment dispersion | 15 | Polyimide (PI-1) (30) | DP1-1(1) | DP2-1(9) | None | 1:9 | S0100CF(60) |
| Example 10 | liquid (Bk-10) | | | | | | | |
| Preparation | Pigment dispersion | 15 | Polyimide precursor | DP1-1(5) | DP2-1(5) | None | 5:5 | S0100CF(60) |
| Example 11 | liquid (Bk-11) | | (PIP-1) (30) | | | | | |
| Preparation | Pigment dispersion | 15 | Polybenzoxazole (PBO-1) | DP1-1(5) | DP2-1(5) | None | 5:5 | S0100CF(60) |
| Example 12 | liquid (Bk-12) | | (30) | | | | | |
| Preparation | Pigment dispersion | 15 | Polybenzoxazole precursor | DP1-1(5) | DP2-1(5) | None | 5:5 | S0100CF(60) |
| Example 13 | liquid (Bk-13) | | (PBPO-1) (30) | | | | | |
| Preparation | Pigment dispersion | 15 | Polysiloxane (PS-1) (30) | DP1-3(10) | None | None | 10:0 | S0100CF(60) |
| Example 14 | liquid (Bk-14) | | | | | | | |
| Preparation | Pigment dispersion | 15 | Cardo resin (CD-1) (30) | DP1-4(10) | None | None | 10:0 | S0100CF(60) |
| Example 15 | liquid (Bk-15) | | | | | | | |
| Preparation | Pigment dispersion | 15 | Polysiloxane (PS-1) (30) | DP1-1(5) | DP2-1(5) | None | 5:5 | S0100CF(60) |
| Example 16 | liquid (Bk-16) | | | | | | | |
| Preparation | Pigment dispersion | 15 | Cardo resin (CD-1) (30) | DP1-1(5) | DP2-1(5) | None | 5:5 | S0100CF(60) |
| Example 17 | liquid (Bk-17) | | | | | | | |
| Preparation | Pigment dispersion | 15 | Polyimide (PI-1) (30) | None | DP2-1(5) | None | 0:10 | S0100CF(60) |
| Example 18 | liquid (Bk-18) | | | | | | | |
| Preparation | Pigment dispersion | 15 | Polyimide (PI-1) (30) | None | None | DP2-2(5) | 0:10 | S0100CF(60) |
| Example 19 | liquid (Bk-19) | | | | | | | |

(1) Weight-Average Molecular Weight of Resin

Using a GPC analyzer apparatus (HLC-8220, made by Tosoh Corporation) and using THF, NMP, or chloroform as a fluid bed, the weight-average molecular weight in terms of polystyrene was measured and determined by a method near normal temperature on the basis of “JIS K7252-3:2008”.

(2) Alkali Dissolution Speed of Resin

A solution obtained by dissolving a resin in γ-butyrolactone was applied onto a Si wafer by spin coating at an arbitrary rotation speed, using a spin coater (MS-A100, made by Mikasa Co., Ltd.). Then, the composition was prebaked at 120° C. for 4 minutes by using a hot plate (SCW-636, made by DAINIPPON SCREEN MFG. CO., LTD.) to manufacture a prebaked film having a film thickness of 10.0 m±0.5 m.

A film thickness reduction value obtained by developing the prepared prebaked film for 60 seconds with a 2.38 mass % TMAH aqueous solution with the use of a small-size development device for photolithography (AC3000, made by TAKIZAWA SANGYO K. K.) and then rinsing the film with water for 30 seconds was calculated as the alkali dissolution speed (the unit being nm/min) according to the following formula.

Film thickness reduction value=film thickness value before development−film thickness value after development.

(3) Acid Value

Using an automatic potentiometric titrator (AT-510, made by Kyoto Electronics Manufacturing Co., Ltd.) and using a 0.1 mol/L NaOH/ethanol solution as a titration reagent and xylene/DMF=1/1 (mass ratio) as a titration solvent, an acid value (whose unit is mgKOH/g) was measured and determined by a potentiometric titration method on the basis of “JIS K2501:2003”.

(4) Amine Value

Using an automatic potentiometric titrator (AT-510, made by Kyoto Electronics Manufacturing Co., Ltd.) and using a 0.1 mol/L HCl aqueous solution as a titration reagent and THF as a titration solvent, an amine value (whose unit is mgKOH/g) was measured and determined by a potentiometric titration method on the basis of “Article 7: Potentiometric titration method (acid value)” of “JIS K2501:2003”.

(5) Double Bond Equivalent

Using an automatic potentiometric titrator (AT-510, made by Kyoto Electronics Manufacturing Co., Ltd.) and using an ICl solution (mixture solution of ICl₃=7.9 g, I₂=8.9 g, and AcOH=1,000 mL) as an iodine supply source, a 100 g/L KI aqueous solution as an aqueous solution for trapping unreacted iodine, and a 0.1 mol/L Na₂S₂O₃ aqueous solution as a titration reagent, the iodine value of the resin was measured by the Wijs method on the basis of “Article 6: Iodine Value” of “JIS K0070:1992”. From the numerical value of the measured iodine value (whose unit is gI/100 g), a double bond equivalent (whose unit is g/mol) was calculated.

(6) Storage Stability Evaluation of Dispersion Liquid

The viscosity of the obtained pigment dispersion liquid was measured using an E-type viscometer (R¹¹⁵ type; made by Toki Sangyo Co., Ltd.). The pigment dispersion liquid was filled in a light-blocking glass container and allowed to stand at 23° C. for 14 days in a sealed state, and then the viscosity was measured again using the E-type viscometer (made by Toki Sangyo Co., Ltd.). Then, the viscosity change rate over time of the viscosity after storage for 14 days against the viscosity immediately after preparation was calculated as follows.

[Viscosity change rate over time (%)]=[viscosity over time]/[initial viscosity]×100.

(7) Measurement of Number Average Particle Diameter of Pigments

Using a zeta potential/particle diameter/molecular weight measurement apparatus (Zetasizer Nano ZS, made by SYSMEX CORPORATION) and using PGMEA as a diluting solvent, a pigment dispersion liquid was diluted to a concentration of 1.0×10⁻⁵ to 40 vol %. The refractive index of PGMEA obtained by measurement by a prism coupler (Model 2010, made by Metricon, Inc.) and the refractive index of the measurement subject were set to 1.1 and 1.8. Then, laser light of 633 nm wavelength was applied to measure a number average particle diameter of the pigment in the pigment dispersion liquid.

(8) Pre-process of Substrate

A glass substrate (made by Geomatec Co., Ltd.; hereinafter referred to as “ITO substrate”) with ITO formed thereon by sputtering was used without being subjected to a pretreatment. Using a hot plate (HP-1SA; made by AS ONE Corporation), an Si wafer (made by ELECTRONICS AND MATERIALS CORPORATION LIMITED) was subjected to a dehydration baking treatment by heating at 130° C. for 2 minutes, and the Si wafer was used. “Kapton” (registered trademark)-150EN-C(made by DU PONT-TORAY CO., LTD; hereinafter referred to as “PI film substrate”) which was a polyimide film was used without being subjected to a pretreatment. Lumirror (registered trademark) U34 (made by Toray Industries, Inc.; hereinafter referred to as “PET film substrate”) which was a polyethylene terephthalate film was used without being subjected to a pretreatment.

(9) Using a film thickness measurement surface roughness/contour shape measuring machine (SURFCOM 1400D, made by TOKYO SEIMITSU CO., LTD.) with the measurement magnification set to 10,000 times, the measurement length set to 1.0 mm, and the measurement speed set to 0.30 mm/s, the post-prebake, post-development, and post-thermosetting film thicknesses were measured.

(10) Sensitivity

In a method described below in Example 1, a both-surface alignment one-side surface exposure apparatus (Mask Aligner PEM-6M, made by Union Optical Co., Ltd.) was used to perform patterning exposure to an i ray (365 nm wavelength), an h ray (405 nm wavelength), and a g ray (436 nm wavelength) of a super high pressure mercury lamp, via a gray scale mask for sensitivity measurement (MDRM MODEL 4000-5-FS, made by Opto-Line International). Then, development was performed by using a small-size development device for photolithography (AC3000, made by TAKIZAWA SANGYO K. K.), so that a post-development film of the composition was created.

Using an FPD inspection microscope (MX-61L, made by Olympus Corporation), the resolution pattern of the created post-development film was observed. An amount of exposure (value from an i-ray illuminometer) that formed a 20-μm line-and-space pattern with a 1-to-1 width was determined as the sensitivity.

(11) Manufacturing Method for Organic EL Display Device

FIG. 4 shows a schematic diagram of a substrate used. First, an ITO transparent conductive film of 10 nm was formed entirely over a non-alkali glass substrate 47 of 38×46 mm by sputtering, and etched to be a second electrode 48. Furthermore, an auxiliary electrode 49 for extracting a second electrode was simultaneously formed. The obtained substrate was ultrasonically washed for 10 minutes with “Semicoclean” (registered trademark) 56 (made by Furuuchi Chemical Corporation) and washed with ultrapure water. Next, on this substrate, the composition 2 was applied and prebaked by the method described above. The compositions were then subjected to patterning exposure via a photomask having a predetermined pattern, developed, and rinsed, and then was heated to be thermally cured. By the method described above, an insulation film 50 having a shape in which opening portions of 70 μm in width and 260 μm in length were arranged with a pitch of 155 μm in a width direction and a pitch of 465 μm in a length direction and in which the individual opening portions exposed the first electrodes was formed exclusively in a substrate effective area. Incidentally, the opening portions were to eventually become light-emitting pixels of organic EL display devices. Furthermore, the substrate effective area was 16 mm squares, and the insulation film 50 was formed to have a thickness of about 1.0 μm.

Next, using the substrate with the first electrodes, the auxiliary electrodes, and the insulation film formed thereon, an organic EL display device was manufactured. As a pre-process, a nitrogen plasma treatment was performed, followed by formation of an organic EL layer 51 that included a light-emitting layer by a vacuum deposition method. Incidentally, the degree of vacuum at the time of vapor deposition was 1×10⁻³ Pa or less, and the substrate was rotated relative to a vapor deposition source during the vapor deposition. First, a compound (HT-1) was vapor deposited to 10 nm as a positive hole injection layer, and a compound (HT-2) was vapor deposited to 50 nm as a positive hole transport layer. Next, on the light-emitting layer, a compound (GH-1) as a host material and a compound (GD-1) as a dopant material were vapor deposited to a thickness of 40 nm so that the dope concentration was 10%. After that, as electron transporting materials, a compound (ET-1) and a compound (LiQ) were stacked, with a volume ratio of 1:1, to a thickness of 40 nm. The structures of the compounds used for the organic EL layer are indicated below.

(12) Optical Density

The pigment dispersion liquid (Bk-1) was applied on a non-alkali glass substrate (AN100) with a spinner (1H-DS; made by Mikasa Co., Ltd.), and the coating film was dried at 100° C. for 2 minutes and then post-baked at 230° C. for 30 minutes to form a coating film having a film thickness of 1.0 μm. Using an optical densitometer (361TVisual; made by X-Rite Inc.), the coating film was measured for the intensities of incident light and transmitted light respectively to calculate a light-shielding OD value from the following formula (X).

OD value=log 10(I₀/I) Formula (X)

I₀: incident light intensity
I: Transmitted light intensity.

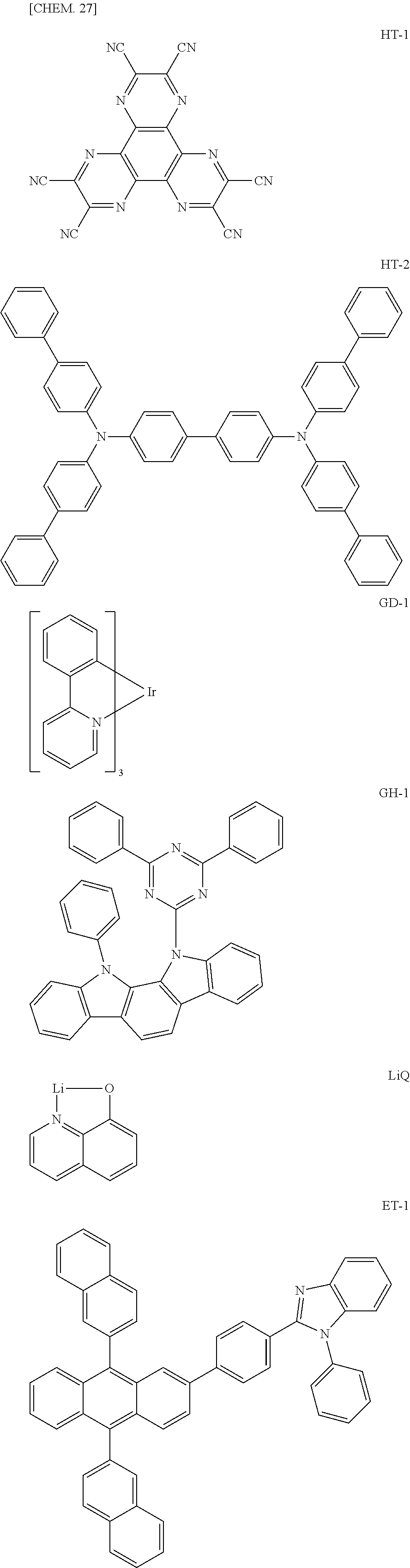

Next, a compound (LiQ) was vapor deposited to a 2 nm and then MgAg was vapor deposited, with a volume ratio of 10:1, to 10 nm to make a second electrode 52. After that, in a low-humidity nitrogen atmosphere, a cap-shaped glass sheet was adhered to achieve sealing by using an epoxy resin based adhesion agent. Thus, four organic EL display devices of 5 mm squares were manufactured on one substrate. Incidentally, the film thicknesses mentioned herein are crystal oscillation type film thickness monitor-displayed values.

(13) Light Emission Characteristics Evaluation

Organic EL display devices manufactured by the foregoing method were caused to emit light by direct-current drive at 10 mA/cm² to observe for non-light-emitting regions and luminance unevenness. Organic EL display devices manufactured were kept at 80° C. for 500 hours as a durability test. After the durability test, the organic EL display devices were caused to emit light by direct-current drive at 10 mA/cm² to observe for change in light emission characteristics.

### Example 1

Under a yellow lamp, 0.256 g of NCI-831 was weighed, 10.186 g of MBA was added, and dissolution was carried out by stirring. Next, 0.300 g of a 30 mass % MBA solution of the polyimide (PI-1) obtained in Synthesis Example 1 and 1.422 g of an 80 mass % MBA solution of DPHA were added, and stirring was performed to obtain a preparation liquid as a homogeneous solution. Next, 12.968 g of the pigment dispersion liquid (Bk-1) obtained in Preparation Example 1 was weighed. To this, 12.032 g of the preparation liquid obtained as described above was added, and stirring was performed to produce a homogeneous solution. After that, the obtained solution was filtered with a 00.45 m filter. Thus, a composition 1 was prepared. The storage stability of the composition 1 was evaluated.

The prepared composition 1 was applied onto an ITO substrate by spin coating at an arbitrary rotation speed, using a spin coater (MS-A100, made by Mikasa Co., Ltd.). Then, the composition 1 was prebaked at 100° C. for 120 seconds by using a hot plate (SCW-636, made by DAINIPPON SCREEN MFG. CO., LTD.) to manufacture a prebaked film having a film thickness of about 2.0 μm.

The manufactured prebaked film was subjected to patterning exposure to an i ray (365 nm wavelength), an h ray (405 nm wavelength), and a g ray (436 nm wavelength) of a super high pressure mercury lamp, by using a both-surface alignment one-side surface exposure apparatus (Mask Aligner PEM-6M, made by Union Optical Co., Ltd.), via a gray scale mask for sensitivity measurement (MDRM MODEL 4000-5-FS, made by Opto-Line International). After the exposure, the film was subjected to development with a 2.38 mass % TMAH aqueous solution for 55 seconds and rinsed with water for 30 seconds by using a small-size development device for photolithography (AC3000, made by TAKIZAWA SANGYO K. K.).

After the development, the film was thermoset at 230° C. by a High-Temperature Inert Gas Oven (INH-9CD-S, made by Koyo Thermo Systems Co., Ltd.) to create a cured film having a film thickness of about 1.6 μm. As for the thermosetting conditions, the thermosetting was performed at 230° C. for 60 minutes in a nitrogen atmosphere.

### Examples 2 to 3 and 8 to 13, Reference Examples 1 to 4, and Comparative Examples 1 to 6

Compositions 2 to 19 were prepared in the same manner as in Example 1 except that the dispersion liquid and the (A) alkali-soluble resin were changed as shown in Table 6 in the same manner as in Example 1, and the storage stability was evaluated. Using each of the obtained compositions, in the same manner as in Example 1, the composition was formed into a film on a substrate, and residues at the time of development (visual observation), sensitivity of the cured film, and light emission characteristics of the organic EL display device were evaluated. In addition, the number average particle diameter and the optical density of the pigment dispersion liquid of each composition were measured. The evaluation results of them are collectively shown in Table 6.

TABLE 6

| | | | (A) Alkali-soluble resin contained in | Storage stability |
|---|---|---|---|---|
| Examples | Composition | Dispersion liquid | composition | evaluation (%) |
| Example 1 | Composition 1 | Pigment dispersion liquid (Bk-1) | Polyimide (PI-1) (30) | 1.0% |
| Example 2 | Composition 2 | Pigment dispersion liquid (Bk-2) | Polyimide (PI-1) (30) | 2.0% |
| Example 3 | Composition 3 | Pigment dispersion liquid (Bk-3) | Polyimide (PI-1) (30) | 1.5% |
| Reference Example 1 | Composition 4 | Pigment dispersion liquid (Bk-4) | Polyimide (PI-1) (30) | 1.1% |
| Reference Example 2 | Composition 5 | Pigment dispersion liquid (Bk-5) | Polyimide precursor (PIP-1) (30) | 2.0% |
| Reference Example 3 | Composition 6 | Pigment dispersion liquid (Bk-6) | Polybenzoxazole (PBO-1) (30) | 2.0% |
| Reference Example 4 | Composition 7 | Pigment dispersion liquid (Bk-7) | Polybenzoxazole precursor (PBPO-1) (30) | 2.0% |
| Example 8 | Composition 8 | Pigment dispersion liquid (Bk-8) | Polyimide (PI-1) (30) | 2.0% |
| Example 9 | Composition 9 | Pigment dispersion liquid (Bk-9) | Polyimide (PI-1) (30) | 2.0% |
| Example 10 | Composition 10 | Pigment dispersion liquid (Bk-10) | Polyimide (PI-1) (30) | 3.0% |
| Example 11 | Composition 11 | Pigment dispersion liquid (Bk-11) | Polyimide precursor (PIP-1) (30) | 1.1% |
| Example 12 | Composition 12 | Pigment dispersion liquid (Bk-12) | Polybenzoxazole (PBO-1) (30) | 2.0% |
| Example 13 | Composition 13 | Pigment dispersion liquid (Bk-13) | Polybenzoxazole precursor (PBPO-1) (30) | 2.0% |
| Comparative Example 1 | Composition 14 | Pigment dispersion liquid (Bk-14) | Polysiloxane (PS-1) (30) | 20.0% |
| Comparative Example 2 | Composition 15 | Pigment dispersion liquid (Bk-15) | Cardo resin (CD-1) (30) | 15.0% |
| Comparative Example 3 | Composition 16 | Pigment dispersion liquid (Bk-16) | Polysiloxane (PS-1) (30) | 20.0% |
| Comparative Example 4 | Composition 17 | Pigment dispersion liquid (Bk-17) | Cardo resin (CD-1) (30) | 22.0% |
| Comparative Example 5 | Composition 18 | Pigment dispersion liquid (Bk-18) | Polyimide (PI-1) (30) | 22.0% |
| Comparative Example 6 | Composition 19 | Pigment dispersion liquid (Bk-19) | Polyimide (PI-1) (30) | 22.0% |

| | | | | | | Pigment number | |
|---|---|---|---|---|---|---|---|
| | | | | | | average particle | |
| | Development | | | Light emission characteristics of | | diameter of | |
| | residues | Development | | organic EL display device | | dispersion | Optical |
| | Visual | time | Sensitivity | | Characteristics after | liquid | Density |
| Examples | observation | Seconds | mJ | Initial characteristics | durability test | nm | OD |
| Example 1 | None | 55 | 45 | Good | Good | 50 | 1.0 |
| Example 2 | None | 53 | 46 | Good | Good | 50 | 1.0 |
| Example 3 | None | 60 | 46 | Good | Good | 50 | 1.0 |
| Reference Example 1 | None | 31 | 70 | Good | Good | 50 | 1.0 |
| Reference Example 2 | None | 15 | 70 | Good | Good | 50 | 1.0 |
| Reference Example 3 | None | 15 | 70 | Good | Good | 50 | 1.0 |
| Reference Example 4 | None | 15 | 70 | Good | Good | 50 | 1.0 |
| Example 8 | None | 51 | 70 | Good | Good | 50 | 1.0 |
| Example 9 | None | 45 | 70 | Good | Good | 50 | 1.0 |
| Example 10 | None | 70 | 46 | Good | Good | 50 | 1.0 |
| Example 11 | None | 50 | 55 | Good | Good | 50 | 1.0 |
| Example 12 | None | 55 | 30 | Good | Good | 50 | 1.0 |
| Example 13 | None | 55 | 45 | Good | Good | 50 | 1.0 |
| Comparative Example 1 | Presence | 31 | 100 | With non-lighting site | With luminance unevenness | 100 | 1.0 |
| Comparative Example 2 | Presence | 31 | 90 | With non-lighting site | With luminance unevenness | 100 | 1.0 |
| Comparative Example 3 | Presence | 60 | 95 | With non-lighting site | With luminance unevenness | 100 | 1.0 |
| Comparative Example 4 | Presence | 62 | 95 | With non-lighting site | With luminance unevenness | 100 | 1.0 |
| Comparative Example 5 | Presence | 100 | 70 | With non-lighting site | With luminance unevenness | 50 | 1.0 |
| Comparative Example 6 | Presence | 110 | 72 | With non-lighting site | With luminance unevenness | 50 | 1.0 |

### DESCRIPTION OF REFERENCE SIGNS

1: Glass substrate
2: TFT
3: Cured film for TFT planarization
4: Reflector electrode
5a: Prebaked film
5b: Cured pattern
6: Mask
7: Chemical active ray
8: EL light-emitting layer
9: Transparent electrode
10: Cured film for planarization
11: Cover glass
34: Glass substrate
35: PI film substrate
36: Oxide TFT
37: Cured film for TFT planarization
38: Reflector electrode
39a: Prebaked film
39b: Cured pattern
40: Mask
41: Chemical active ray
42: EL light-emitting layer
43: Transparent electrode
44: Cured film for planarization
45: Glass substrate
46: PET film substrate
47: Non-alkali glass substrate
48: First electrode
49: Auxiliary electrode
50: Insulation film
51: Organic EL layer
52: Second electrode
53: Non-alkali glass substrate
54: Source electrode
55: Drain electrode
56: Reflector electrode
57: Oxide semiconductor layer
58: Via hole
59: Pixel region
60: Gate insulating layer
61: Gate electrode
62: TFT protective layer/pixel-separating layer
63: Organic EL light-emitting layer
64: Transparent pixel electrode
65: Sealing film
66: Non-alkali glass substrate

1. A negative photosensitive resin composition comprising
an (A) alkali-soluble resin,
a (B) dispersant having an amine value exceeding 0,
a (C) benzofuranone based organic pigment having an amide structure,
a (D) radical polymerizable compound, and
a (E) photoinitiator,
the negative photosensitive resin composition being characterized in that the (A) alkali-soluble resin contains one or more selected from the group consisting of a (A1) polyimide, a (A2) polyimide precursor, a (A3) polybenzoxazole, and a (A4) polybenzoxazole precursor, and
the (B) dispersant having an amine value exceeding 0 contains a (B1) dispersant including a repeating unit represented by general formula (2) and a repeating unit represented by general formula (3) and a (B2) dispersant that is an acrylic block copolymer having an amine value of 15 to 60 mgKOH/g and/or a (B3) dispersant having a urethane bond; 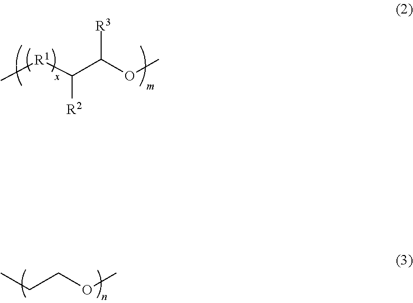
wherein in general formula (2), R¹ represents an alkylene group. R² and R³, which may be the same or different, each represents hydrogen, an alkyl group or a hydroxyl group. x represents an integer of 0 to 20. However, when x is 0, at least one of R² and R³ is an alkyl group. m represents an integer of 1 to 100. In general formula (3), n represents an integer of 1 to 100.

2. The negative photosensitive resin composition according to claim 1, wherein the (C) benzofuranone based organic pigment having an amide structure is a compound represented by the following general formula (1): 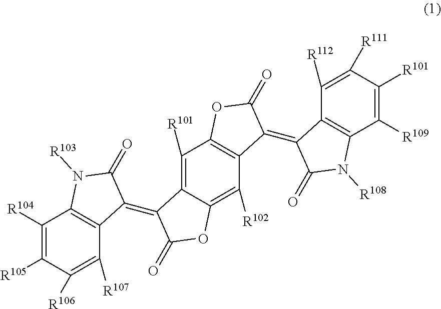
wherein in general formula (1), R¹⁰¹ and R¹⁰² each independently represent hydrogen, a halogen atom, an alkyl group having a carbon number of 1 to 10, or an alkyl group having a carbon number of 1 to 10 and having 1 to 20 fluorine atoms. R¹⁰⁴ to R¹⁰⁷ and R¹⁰⁹ to R¹¹² each independently represent hydrogen, a halogen atom, an alkyl group having a carbon number of 1 to 10, a carboxy group, a sulfonic acid group, an amino group or a nitro group. R¹⁰³ and R¹⁰⁸ each independently represent hydrogen, an alkyl group having a carbon number of 1 to 10, or an aryl group having a carbon number of 6 to 15.

3. The negative photosensitive resin composition according to claim 1, wherein m in the general formula (2) is an integer of 10 to 30, n in the general formula (3) is an integer of 5 to 15, and m and n satisfy a relationship of m≥n.

4. The negative photosensitive resin composition according to claim 1, wherein the total amount of the (B2) dispersant and the (B3) dispersant is 10 to 100 mass parts based on 100 mass parts of the (B1) dispersant.

5. The negative photosensitive resin composition according to claim 1, wherein the (A) alkali-soluble resin is the (A1) polyimide.

6. The negative photosensitive resin composition according to claim 1, wherein the content of the (C) benzofuranone based organic pigment having an amide structure is 5 to 70 mass % in the solid content.

7. A cured film comprising a cured product of the negative photosensitive resin composition according to claim 1.

8. The cured film according to claim 7, wherein an optical density per 1 μm of film thickness is 0.3 to 4.0.

9. An element comprising the cured film according to claim 7.

10. A display device comprising the element according to claim 9.

11. An organic EL display comprising, in a light-emitting element, an insulation film on a planarization film including the cured film according to claim 7.

12. The negative photosensitive resin composition according to claim 2, wherein m in the general formula (2) is an integer of 10 to 30, n in the general formula (3) is an integer of 5 to 15, and m and n satisfy a relationship of m≥n.

13. The negative photosensitive resin composition according to claim 2, wherein the total amount of the (B2) dispersant and the (B3) dispersant is 10 to 100 mass parts based on 100 mass parts of the (B1) dispersant.

14. The negative photosensitive resin composition according to claim 3, wherein the total amount of the (B2) dispersant and the (B3) dispersant is 10 to 100 mass parts based on 100 mass parts of the (B1) dispersant.

15. The negative photosensitive resin composition according to claim 2, wherein the (A) alkali-soluble resin is the (A1) polyimide.

16. The negative photosensitive resin composition according to claim 3, wherein the (A) alkali-soluble resin is the (A1) polyimide.

17. The negative photosensitive resin composition according to claim 4, wherein the (A) alkali-soluble resin is the (A1) polyimide.

18. The negative photosensitive resin composition according to claim 2, wherein the content of the (C) benzofuranone based organic pigment having an amide structure is 5 to 70 mass % in the solid content.

19. The negative photosensitive resin composition according to claim 3, wherein the content of the (C) benzofuranone based organic pigment having an amide structure is 5 to 70 mass % in the solid content.

20. The negative photosensitive resin composition according to claim 4, wherein the content of the (C) benzofuranone based organic pigment having an amide structure is 5 to 70 mass % in the solid content.
